(19) United States
(12) Patent Application Publication
(10) Pub. No.: US 2025/0185301 A1
(43) Pub. Date: Jun. 5, 2025

(54) SEMICONDUCTOR DEVICE AND METHOD FOR FABRICATING THE SAME

(71) Applicant: SK hynix Inc.

(72) Inventors: Jeong Hoon KWON, Gyeonggi-do (KR); Dong Il SONG, Gyeonggi-do (KR); Kang Sik CHOI, Gyeonggi-do (KR)

(21) Appl. No.: 18/964,679

(22) Filed: Dec. 2, 2024

(30) Foreign Application Priority Data
Dec. 1, 2023 (KR) 10-2023-0172410
Nov. 29, 2024 (KR) 10-2024- 0174313

(51) Int. Cl. H10D 30/67; H01L 23/522; H10B 12/00; H10D 30/01; H10D 62/10; H10D 64/01; H10D 84/01; H10D 84/83

(52) U.S. Cl. CPC H10D 30/6735; H01L 23/5223; H10B 12/315; H10B 12/50; H10D 30/014; H10D 30/6757; H10D 62/121; H10D 64/015; H10D 64/021; H10D 64/031; H10D 84/0147; H10D 84/8316

(57) ABSTRACT

A semiconductor device includes switches including nano sheets and horizontal conductive lines surrounding the nano sheets. The semiconductor device includes first contact nodes formed on first edges of the nano sheets, and vertical conductive lines including pyramid portions surrounding the first contact nodes. Each of the vertical conductive lines is coupled to a corresponding one of the nano sheets. The semiconductor device includes data storage devices each coupled to a corresponding one of second edges of the nano sheets. The semiconductor device includes a supporter surrounding the vertical conductive lines.

### CROSS-REFERENCE TO RELATED APPLICATIONS

The present application claims priority under 35 U.S.C 119(a) to Korean Patent Application No. 10-2023-0172410, and No. 10-2024-0174313, respectively filed on Dec. 1, 2023, and Nov. 29, 2024, in the Korean Intellectual Property Office, which is incorporated herein by reference in its entirety.

### BACKGROUND

### 1. Field

Various embodiments of the present disclosure relate to a semiconductor device, and more particularly, to a semiconductor device including three-dimensional (3D) memory cells, and a method for fabricating the semiconductor device.

### 2. Description of the Related Art

Recently, in order to satisfy the demand for large capacity and miniaturized memory devices, a three-dimensional (3D) memory device has been proposed in which a plurality of memory cells are arranged in a stacked configuration.

### SUMMARY

Embodiments of the present disclosure are directed to a semiconductor device including high-integrated memory cells, and a method for fabricating the semiconductor device.

In accordance with an embodiment of the present disclosure, a semiconductor device may include: a horizontal arrangement of switching elements including nano sheets and horizontal conductive lines surrounding the nano sheets; pyramid-shaped first contact nodes formed on first edges of the nano sheets in the horizontal arrangement; vertical conductive lines including pyramid portions surrounding the first contact nodes and each coupled to a different one of the nano sheets in the horizontal arrangement; data storage elements each coupled to a different one of second edges of the nano sheets in the horizontal arrangement; and a supporter.

In accordance with an embodiment of the present disclosure, a method for fabricating a semiconductor device may include: forming a stopper layer over a substrate; forming horizontal and vertical arrangements of narrow sheets over the stopper layer; forming a supporter including supporter recesses that simultaneously expose edges of the narrow sheets in the vertical arrangement and expose the edges of the narrow sheets, respectively, in the horizontal arrangement; forming horizontal and vertical arrangements of first contact nodes each coupled to a different one of the edges of the narrow sheets in the horizontal and vertical arrangements; and forming vertical conductive lines coupled in common to the first contact nodes in the vertical arrangement, each coupled to a different one of the first contact nodes in the horizontal arrangement and disposed in the supporter recesses.

In accordance with an embodiment of the present disclosure, a semiconductor device may include: a substrate; a memory cell array including horizontal and vertical arrangements of nano sheet transistors and vertical conductive lines each coupled to a different one of the nano sheet transistors in the horizontal arrangement and coupled in common to the nano sheet transistors in the vertical arrangement; a stopper layer formed between the memory cell array and the substrate; and a supporter supporting the vertical conductive lines.

### BRIEF DESCRIPTION OF THE DRAWINGS

FIG. 1A is a schematic perspective view illustrating a memory cell in accordance with an embodiment of the present disclosure.

FIG. 1B is a schematic cross-sectional view of the memory cell taken along line X1-X1′ illustrated in FIG. 1A.

FIG. 2A is a schematic perspective view illustrating a semiconductor device in accordance with an embodiment of the present disclosure.

FIG. 2B is a partial perspective view illustrating a second tier illustrated in FIG. 2A according to an embodiment.

FIG. 2C is a partial perspective view illustrating a second conductive line illustrated in FIG. 2B according to an embodiment.

FIG. 2D is a partial perspective view illustrating a first spacer illustrated in FIG. 2B according to an embodiment.

FIG. 2E is a partial perspective view illustrating a second spacer and an etch stop spacer illustrated in FIG. 2B according to an embodiment.

FIG. 3A is a schematic perspective view illustrating a semiconductor device in accordance with an embodiment of the present disclosure.

FIG. 3B is a schematic plan view illustrating a semiconductor device in accordance with an embodiment of the present disclosure.

FIG. 4A is a schematic cross-sectional view of the semiconductor device taken along line A-A′ illustrated in FIG. 3B according to an embodiment.

FIG. 4B is a schematic cross-sectional view of the semiconductor device taken along line B-B′ illustrated in FIG. 3B according to an embodiment.

FIG. 4C is a schematic cross-sectional view of the semiconductor device taken along line A1-A1′ illustrated in FIG. 3B according to an embodiment.

FIGS. 5A to 34B illustrate operations included in a method for fabricating a semiconductor device in accordance with an embodiment of the present disclosure.

FIGS. 35A and 35B are schematic cross-sectional views of a semiconductor device in accordance with embodiments of the present disclosure.

FIGS. 36A and 36B illustrate various views illustrating a stack assembly in accordance with embodiments of the present disclosure.

### DETAILED DESCRIPTION

Various embodiments of the present disclosure may be described herein with reference to cross-sectional views, plan views and block diagrams, which are ideal schematic views of a semiconductor device. It is noted that the structures of the drawings may be modified by fabricating techniques and/or tolerances. The embodiments of the present disclosure are not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the embodiments of the present disclosure.

The following embodiment relates to three-dimensional (3D) memory cells with memory cells vertically stacked for increasing the memory cell density and reducing parasitic capacitance.

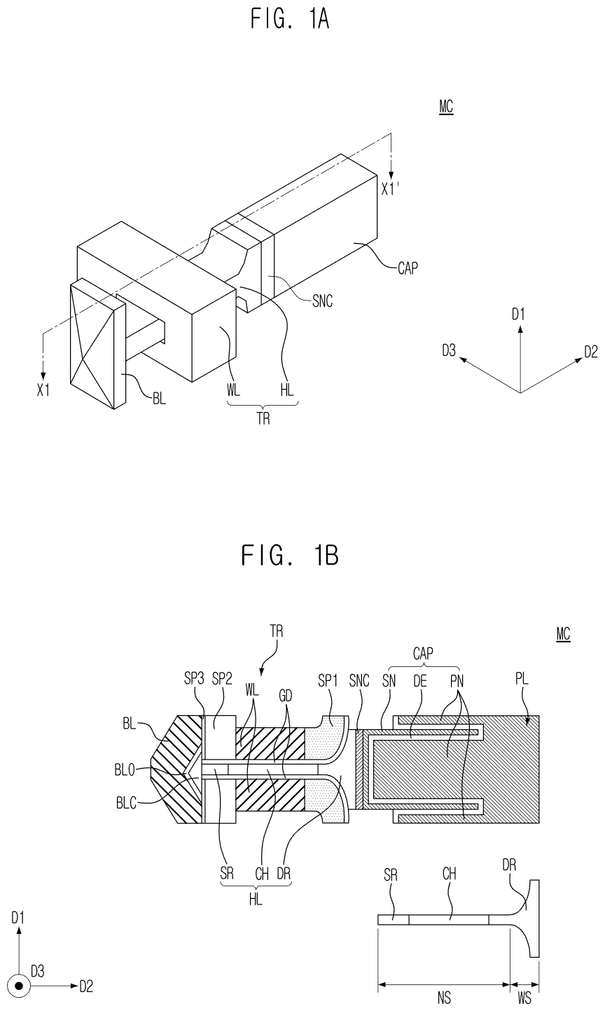

FIG. 1A is a schematic perspective view illustrating a memory cell MC in accordance with an embodiment of the present disclosure. FIG. 1B is a schematic cross-sectional view of the memory cell MC taken along line X1-X1′ illustrated in FIG. 1A according to an embodiment.

Referring to FIGS. 1A and 1B, the memory cell MC may include a first conductive

line BL, a switching element (or switch) TR, and a data storage element (or data storage device) CAP.

The first conductive line BL may be vertically oriented in a first direction D1. The first conductive line BL may include a bit line. The first conductive line BL may, for example, be referred to as a “vertical conductive line”, a “vertically-oriented bit line”, a “vertically-extending bit line”, or a “pillar-shaped bit line”. The first conductive line BL may include a conductive material. The first conductive line BL may include a silicon-based material, a metal-based material, or a combination thereof. The first conductive line BL may include polysilicon, metal, metal nitride, metal silicide, or a combination thereof. The first conductive line BL may include polysilicon, titanium nitride, tungsten, or a combination thereof. For example, the first conductive line BL may include a titanium nitride/tungsten (TiN/W) stack in which titanium nitride and tungsten are sequentially stacked.

The switching element TR performs a function of controlling voltage or current supply to the data storage element CAP during a data write operation and a data read operation, performed on the data storage element CAP. The switching element TR may include a nano sheet HL, a nano sheet dielectric layer GD, and a second conductive line WL. The second conductive line WL may include a horizontal conductive line or a horizontal word line, and the nano sheet HL may include an active layer. The switching element TR may include a transistor, and in this case, the second conductive line WL may serve as a gate electrode that surrounds a channel region of the nano sheet HL. Thus, in one embodiment, the switching element TR may be said to have a gate-all-around (GAA) structure. The switching element TR may also be referred to as a “nano sheet transistor”, an “access element” or a “selection element”. The second conductive line WL may be referred to as a “horizontal gate electrode” or a “horizontal word line”.

The nano sheet HL may extend in a second direction D2 that intersects with the first direction D1. The second conductive line WL may extend in a third direction D3 that intersects with the first direction D1 and the second direction D2. The first direction D1 may be a vertical direction, the second direction D2 may be a first horizontal direction, and the third direction D3 may be a second horizontal direction. The nano sheet HL may extend in the first horizontal direction (i.e., the second direction D2), and the second conductive line WL may extend in the second horizontal direction, i.e., the third direction D3. The nano sheet HL may be referred to as a “horizontal layer”.

The nano sheet HL may include a channel CH, a first doped region SR between the channel CH and the first conductive line BL, and a second doped region DR between the channel CH and the data storage element CAP. The first doped region SR may be electrically coupled to the first conductive line BL, and the second doped region DR may be electrically coupled to the data storage element CAP. The channel CH may have a substantially constant thickness. A height of at least a portion of the second doped region DR in the first direction D1 may be greater than a height of the channel CH in the first direction D1. A length of the second doped region DR in the second direction D2 may be less than a length of the channel CH in the second direction D2. In one embodiment, lengths of the first doped region SR, the channel CH and the second doped region DR in the third direction D3 may be equal to one another. Furthermore, the cross-sectional shape of the first doped region SR and be different from a cross-sectional shape of the second doped region DR.

The nano sheet HL may include a first region NS and a second region WS that are horizontally disposed in the second direction D2. The second region WS may extend from the first region NS. The second region WS may have a diverging upper and lower surfaces, and thickness that gradually increases in the second direction D2 from the first region NS toward the data storage element CAP, between the first region NS and the data storage element CAP. An average vertical height or thickness of the second region WS in the first direction D1 may be greater than an average vertical height or thickness of the first region NS. Hereinafter, the first region NS is referred to as a “narrow sheet”, and the second region WS is referred to as a “wide sheet”.

The narrow sheet NS may have a flat plate shape. The wide sheet WS may have a fan-like shape. The wide sheet WS may have a thickness that gradually increases in the second direction D2. The narrow sheet NS may be referred to as a “flat plate-shaped sheet”, and the wide sheet WS may be referred to as a “fan-like shaped sheet”. A boundary portion between the narrow sheet NS and the wide sheet WS may have a curvature.

The first doped region SR and the channel CH may be disposed in the narrow sheet NS, and the second doped region DR may at least partially be disposed in the wide sheet WS. The channel CH formed in the narrow sheet NS may be referred to as a “narrow channel” or a “flat channel”. A portion of the second doped region DR may extend to be disposed in the narrow sheet NS. The second doped region DR may include a thick portion disposed in the wide sheet WS and a thinner portion disposed in the narrow sheet NS. One side of the wide sheet WS and one side of the second doped region DR, which contact the data storage element CAP, may each have a flat side shape.

A horizontal length of the wide sheet WS in the second direction D2 may be less than a horizontal length of the narrow sheet NS. The narrow sheet NS may be referred to as a “long sheet”, and the wide sheet WS may be referred to as a “short sheet”.

The nano sheet HL may include a semiconductive material. For example, the nano sheet HL may include polysilicon, monocrystalline silicon, germanium, or silicon-germanium. In some embodiments, the nano sheet HL may include an oxide semiconductor material. For example, the oxide semiconductor material may include indium gallium zinc oxide (IGZO), InSnZnO, ZnSnO, or a combination thereof. In some embodiments, the nano sheet HL may include conductive metal oxide. In some embodiments, the nano sheet HL may include a two-dimensional material, for example, MoS₂, WS₂, or MoSe₂.

When the nano sheet HL is formed of the oxide semiconductor material, the channel CH may also be formed of oxide semiconductor material, and the first and second doped regions SR and DR may be omitted. The nano sheet HL may also be referred to as an “active layer” or a “thin body”.

The first doped region SR and the second doped region DR may be doped with the same conductivity type of an impurity. Each of the first doped region SR and the second doped region DR may be doped with an N-type conductive impurity or a P-type conductive impurity. The first doped region SR and the second doped region DR may include at least one impurity selected from among arsenic (As), phosphorus (P), boron (B), indium (In), and combinations thereof. The first doped region SR may be coupled to the first conductive (bit) line BL, and the second doped region DR may be coupled to the data storage element CAP. The first and second doped regions SR and DR may be referred to as “first and second source/drain regions,” i.e., one of the first and second doped regions SR and DR may be a source and the other of the first and second doped regions SR and DR may be a drain.

The nano sheet HL may be horizontally oriented in the second direction D2 from the first conductive line BL.

The second conductive line WL may have a gate-all-around (GAA) structure. For example, the second conductive line WL may surround the nano sheet HL and extend in the third direction D3. The nano sheet dielectric layer GD may be formed between the nano sheet HL and the second conductive line WL. The nano sheet dielectric layer GD may surround the nano sheet HL. The second conductive line WL may surround the nano sheet HL on the nano sheet dielectric layer GD.

The second conductive line WL may include a metal-based material, a semiconductive material, or a combination thereof. The second conductive line WL may include molybdenum, molybdenum nitride, ruthenium, titanium nitride, tungsten, polysilicon, or a combination thereof. For example, the second conductive line WL may include a TiN/W stack in which titanium nitride and tungsten are sequentially stacked. The second conductive line WL may include an N-type work function material or a P-type work function material. The N-type work function material may have a low work function of approximately 4.5 eV or less, and the P-type work function material may have a high work function of approximately 4.5 eV or greater. The second conductive line WL may include a stack of the low work function material and the high work function material.

The nano sheet dielectric layer GD may be disposed between the nano sheet HL and the second conductive line WL. The nano sheet dielectric layer GD may be referred to as a “gate dielectric layer” or a “channel-side dielectric layer”. The nano sheet dielectric layer GD may include silicon oxide, silicon nitride, metal oxide, metal oxide nitride, metal silicate, a high-k material, a ferroelectric material, an anti-ferroelectric material, or a combination thereof. The nano sheet dielectric layer GD may include SiO₂, Si₃N₄, HfO₂, Al₂O₃, ZrO₂, AlON, HfON, HfSiO, HfSiON, HfZrO, or a combination thereof. The nano sheet dielectric layer GD may be formed by thermal oxidation of a semiconductive material.

The data storage element CAP may include a memory element such as a capacitor. The data storage element CAP may be horizontally disposed in the second direction D2 from the switching element TR. The data storage element CAP may include a first electrode SN, a second electrode PN on the first electrode SN, and a dielectric layer DE between the first electrode SN and the second electrode PN. The first electrode SN may horizontally extend from the nano sheet HL in the second direction D2. The first electrode SN, the dielectric layer DE and the second electrode PN may be horizontally disposed in the second direction D2.

The first electrode SN may have a different shape or configuration than the second electrode PN. For example, the first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces. The vertical outer surface of the first electrode SN may vertically extend in the first direction D1, and the horizontal outer surfaces of the first electrode SN may horizontally extend in the second direction D2 or the third direction D3. The inner space of the first electrode SN may be a three-dimensional space. The dielectric layer DE may conformally cover the inner surfaces of the first electrode SN. The second electrode PN may be disposed in the inner space of the first electrode SN on the dielectric layer DE. Some of the outer surfaces of the first electrode SN may be electrically coupled to the second doped region DR of the nano sheet HL. The second electrode PN of the data storage element CAP may be coupled to a common plate PL.

The data storage element CAP may have a three-dimensional structure. The first

electrode SN may have a three-dimensional structure, which may have a three-dimensional structure that is horizontally oriented in the second direction D2. In an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically coupled to the second doped region DR of the nano sheet HL. The dielectric layer DE and the second electrode PN may be disposed on the cylindrical inner surfaces of the first electrode SN.

In some embodiments, the first electrode SN may have a pillar shape or a pylinder shape. The pylinder shape may refer to a structure in which a pillar shape and a cylindrical shape are merged.

The first electrode SN and the second electrode PN may include metal, noble metal, metal nitride, conductive metal oxide, conductive noble metal oxide, metal carbide, metal silicide, or a combination thereof. For example, the first electrode SN and the second electrode PN may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum nitride (MoN), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium nitride/titanium silicon nitride (TiN/TiSiN) stack, or a combination thereof. The second electrode PN may also include a combination of a metal-based material and a silicon-based material. For example, the second electrode PN may be a titanium nitride/silicon germanium/tungsten nitride (TiN/SiGe/WN) stack. In the titanium nitride/silicon germanium/tungsten nitride (TiN/SiGe/WN) stack, silicon germanium may be a gap-fill material that fills the inside of the first electrode SN, titanium nitride (TiN) may serve as the second electrode PN of the data storage element CAP, and tungsten nitride may be a low-resistance material.

The dielectric layer DE may be referred to as a “capacitor dielectric layer” or a “memory layer”. The dielectric layer DE may include silicon oxide, silicon nitride, a high-k material, a perovskite material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). In some embodiments, the dielectric layer DE may be formed of a composite layer including two or more layers of the above-described high-k material.

The dielectric layer DE may be formed of zirconium (Zr)-based oxide. The dielectric layer DE may have a stack structure containing zirconium oxide (ZrO2). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃) and zirconium oxide (ZrO₂) are sequentially stacked. Each of the ZA stack and the ZAZ stack may be referred to as a “zirconium oxide (ZrO₂)-based layer”. In some embodiments, the dielectric layer DE may be formed of hafnium (Hf)-based oxide. The dielectric layer DE may have a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃) and hafnium oxide (HfO₂) are sequentially stacked. Each of the HA stack and the HAH stack may be referred to as a “hafnium oxide (HfO₂)-based layer”.

In the ZA stack, the ZAZ stack, the HA stack and the HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material having a greater band gap energy than the high-k material.

The dielectric layer DE may include silicon oxide (SiO₂) as a high band gap material other than aluminum oxide (Al₂O₃). Because the dielectric layer DE includes a high band gap material, leakage current may be suppressed. The high band gap material may be thinner than the high-k material. In some embodiments, the dielectric layer DE may include a stack structure in which a high-k material and a high band gap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA(HfO₂/Al₂O₃/HfO₂/Al₂O₃) stack, a HAHAH(HfO₂/Al₂O₃/HfO₂/Al₂O₃/HfO₂) stack, a HZAZH(HfO₂/ZrO₂/Al₂O₃/ZrO₂/HfO₂) stack, a ZHZAZHZ(ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA(Al₂O₃/HfO₂/ZrO₂/Al₂O₃/ZrO₂/HfO₂/Al₂O₃) stack. In the above-described stack structures, aluminum oxide (Al₂O₃) may be thinner than zirconium oxide (ZrO₂) and hafnium oxide (HfO₂).

In some embodiments, the dielectric layer DE may include a high-k material and a high band gap material. Specifically, the dielectric layer DE may have a laminated structure or an intermixed structure. According to the laminated structure, a plurality of high-k materials and a plurality of high band gap materials are stacked. According to the intermixed structure, a high-k material and a high band gap material are intermixed.

In some embodiments, the dielectric layer DE may include a ferroelectric material, an anti-ferroelectric material, or a combination thereof. For example, the dielectric layer DE may include HfZrO.

In some embodiments, the dielectric layer DE may include a combination of a high-k material and a ferroelectric material, a combination of a high-k material and an anti-ferroelectric material, or a combination of a high-k material or a ferroelectric material and an anti-ferroelectric material.

In some embodiments, an interface control layer may be further formed between the first electrode SN and the dielectric layer DE to alleviate leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced with another type of data storage element or material. An example of another type of data storage element (or data storage device) may include a thyristor. An example of another type of data storage materials may include a phase-change material, a Magnetic Tunnel Junction (MTJ), or a variable resistance material.

The memory cell MC may further include a first contact node BLC and a second contact node SNC. The first contact node BLC may be disposed between the first conductive line BL and the nano sheet HL. In some embodiments, the first contact node BLC may be at least partially surrounded by or in an overlapping relationship with the first conductive line BL in the first direction D1. The first contact node BLC may include a metal-based material or a semiconductive material. For example, the first contact node BLC may include titanium, titanium nitride, tungsten, or a combination thereof. In addition, the first contact node BLC may include doped polysilicon, and the first doped region SR may include an impurity diffused from the first contact node BLC.

The second contact node SNC may be disposed between the nano sheet HL and the first electrode SN. The second contact node SNC may have, for example, a vertical plate shape. The second contact node SNC may include a metal-based material or a semiconductive material. For example, the second contact node SNC may include titanium, titanium nitride, tungsten, or a combination thereof. In addition, the second contact node SNC may include doped silicon, and the second doped region DR may include an impurity diffused from the second contact node SNC.

In one embodiment, the first contact node BLC may have a different shape than the second contact node SNC. For example, the first contact node may have angled sides, e.g., may have an arrowhead cross-sectional shape that is coupled to the nano sheet HL. This differs from the vertical plate shape of the second contact node SNC.

A height of the first contact node BLC in the first direction D1 may be less than a height of the second contact node SNC in the first direction D1. The height of the first contact node BLC in the first direction D1 may be greater than a height of the channel CH in the first direction D1. The first and second contact nodes BLC and SNC may each include, for example, phosphorus-doped polysilicon or arsenic-doped polysilicon.

The first contact node BLC may be selectively grown from the narrow sheet NS of the nano sheet HL. The first contact node BLC may be formed by the selective epitaxial growth (SEG). For example, the first contact node BLC may be a silicon epitaxial layer formed by the selective epitaxial growth (SEG). The first contact node BLC may be a doped silicon epitaxial layer. The second contact node SNC may be selectively grown from the wide sheet WS of the nano sheet HL. The second contact node SNC may be formed by the selective epitaxial growth (SEG). For example, the second contact node SNC may be a silicon epitaxial layer formed by the selective epitaxial growth (SEG). The second contact node SNC may be a doped silicon epitaxial layer. The first contact node BLC may be a phosphorus-doped silicon epitaxial layer.

The first contact node BLC may be a narrow sheet-side contact node, and the second contact node SNC may be a wide sheet-side contact node.

The nano sheet HL may include a first edge and a second edge. The first edge may correspond to a portion of the first doped region SR electrically coupled to the first conductive line BL, and the second edge may correspond to a portion of the second doped region DR electrically coupled to the first electrode SN of the data storage element CAP.

The memory cell MC may further include an ohmic contact layer BLO between the first contact node BLC and the first conductive line BL. The ohmic contact layer BLO may include a low resistance material that allows charge to easily flow between the first contact node BLC and the first conductive line BL. The ohmic contact layer BLO may include, for example, metal silicide, such as titanium silicide or molybdenum silicide.

The memory cell MC may further include a first spacer SP1, a second spacer SP2, and an etch stop spacer SP3. The first spacer SP1 may be disposed between the second conductive line WL and the second doped region DR, with the nano sheet dielectric layer GD interposed therebetween. The second spacer SP2 may be disposed between the first conductive line BL and the second conductive line WL. The etch stop spacer SP3 may be disposed between the first conductive line BL and the second spacer SP2. The etch stop spacer SP3 may partially overlap the first contact node BLC in the second direction D2.

The first and second spacers SP1 and SP2 may each include a dielectric material. For example, the first and second spacers SP1 and SP2 may each include silicon oxide, silicon nitride, or a combination thereof. The first and second spacers SP1 and SP2 may each include silicon nitride. The etch stop spacer SP3 may include a different material from the first and second spacers SP1 and SP2. The etch stop spacer SP3 may have an etch selectivity with respect to the first and second spacers SP1 and SP2. The etch stop spacer SP3 may be a material selectively grown from the second spacer SP2. The etch stop spacer SP3 may include silicon carbon oxide (SiOC). The silicon carbon oxide may be selectively grown from a surface of the silicon nitride.

The first spacer SP1 may surround a first portion of the nano sheet HL including, for example, a portion of the channel CH and an adjacent portion of the second doped region DR in the first direction D1. The second conductive line WL may surround a second portion of the nano sheet HL including all or a portion of the channel CH. The second spacer SP2 may surround a third portion of the nano sheet HL including, for example, a portion of the channel CH and the first doped region SR. The first portion, the second portion and the third portion of the nano sheet HL may be defined in the narrow sheet NS.

The first contact node BLC may have a predetermined shape with, for example, angled sides. For example, the first contact node BLC may have a pyramid shape, and the ohmic contact layer BLO and the first conductive line BL may each have angled sides in a pyramid shape covering the first contact node BLC. For example, the first contact node BLC, the ohmic contact layer BLO and the first conductive line BL may be a quadrangular pyramid shape, respectively. The first contact node BLC may be a phosphorus-doped silicon epitaxial layer, and the phosphorus-doped silicon epitaxial layer may be grown to have a pyramid shape. Contact resistance may be improved by controlling the size of the first contact node BLC.

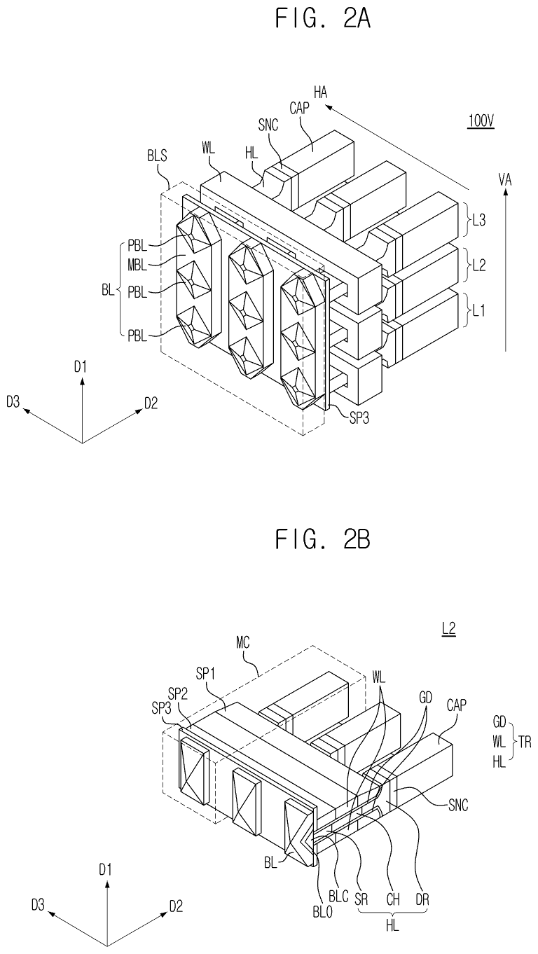

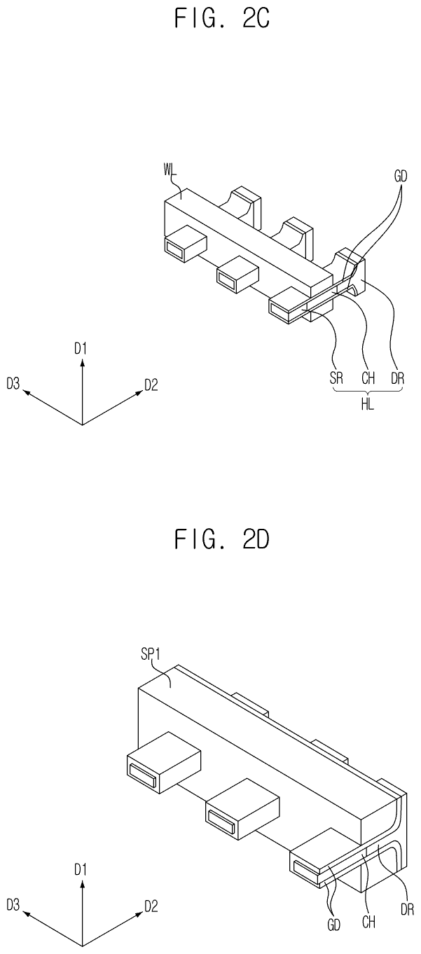

FIG. 2A is a schematic perspective view illustrating a semiconductor device 100V in accordance with an embodiment of the present disclosure. FIG. 2B is a partial perspective view illustrating a second tier L2 illustrated in FIG. 2A. FIG. 2C is a partial perspective view illustrating a second conductive line WL illustrated in FIG. 2B. FIG. 2D is a partial perspective view illustrating a first spacer SP1 illustrated in FIG. 2B. FIG. 2E is a partial perspective view illustrating a second spacer SP2 and etch stop spacer SP3 illustrated in FIG. 2B.

Referring to FIGS. 2A to 2E, the semiconductor device 100V may include a three-dimensional array of memory cells MC, where each memory cell MC has a structure as shown in FIGS. 1A and 1B, a detailed description of which is provided above.

The semiconductor device 100V may include horizontal arrangements HA and vertical arrangements VA of the memory cells MC. The memory cells MC in each of the horizontal arrangements HA may be horizontally spaced apart in a third direction D3 by a first predetermined spacing. The memory cells MC in each of the vertical arrangements VA may be vertically stacked in a first direction D1 by a second predetermined spacing. The first predetermined spacing may be different from (e.g., greater than) the second predetermined spacing.

The memory cells MC in the horizontal arrangements HA may be vertically stacked in the first direction D1. A stack of the horizontal arrangements HA may include a stack of the vertical arrangements VA. The memory cells MC in each of the horizontal arrangements HA may be coupled to different first conductive lines BL and share one second conductive line WL. The memory cells MC in each of the vertical arrangements VA may share different second conductive lines WL and be coupled to one first conductive line BL. Each first conductive line BL may include a body portion MBL extending around and between a plurality of pyramid portions PBL. The body portion MBL may therefore correspond to a portion where the pyramid portions PBL are interconnected.

Each of the vertical arrangements VA may consist of a plurality of tiers L1, L2 and L3. For example, the vertical arrangement VA of the semiconductor devices 100V may have a first tier L1, a second tier L2 and a third tier L3 that are sequentially and vertically stacked.

Each of the memory cells MC may include the first conductive line BL having a pyramid shape, a nano sheet HL, and a data storage element CAP, as described, for example, with reference to FIGS. 1A and 1B. That is, the nano sheet HL may include a first doped region SR, a channel CH, and a second doped region DR. A first contact node BLC and an ohmic contact layer BLO may be formed between the first doped region SR of the nano sheet HL and the first conductive line BL. A second contact node SNC may be formed between the second doped region DR of the nano sheet HL and the data storage element CAP. The nano sheet HL may be surrounded by a nano sheet dielectric layer GD. The second conductive line WL may extend in the third direction D3 while surrounding the channel CH of the nano sheet HL on the nano sheet dielectric layer GD. The memory cells MC may further include a first spacer SP1, a second spacer SP2, and an etch stop spacer SP3.

The first spacer SP1 may surround first portions of the nano sheets HL in the horizontal arrangement HA, the second conductive line WL may surround second portions of the nano sheets HL in the horizontal arrangement HA, and the second spacer SP2 may surround third portions of the nano sheets HL in the horizontal arrangement HA. The etch stop spacer SP3 may surround fourth portions of the nano sheets HL in the horizontal arrangement HA.

More specifically, the first, second and etch stop spacers SP1, SP2 and SP3 may extend in the third direction D3 while surrounding the nano sheets HL in the horizontal arrangement HA. For example, the first spacer SP1 may extend in the third direction D3 while surrounding the second doped regions DR in the horizontal arrangement HA. The second and etch stop spacers SP2 and SP3 may extend in the third direction D3 while surrounding the first doped regions SR in the horizontal arrangement HA. The second conductive lines WL may extend in the third direction D3 while surrounding the channels CH of the nano sheets HL in the horizontal arrangement HA. In this way, the second conductive lines WL, the first spacers SP1, the second spacers SP2 and the etch stop spacers SP3 may surround the nano sheets HL disposed at the same horizontal level.

The semiconductor device 100V may further include a supporter BLS (shown by the dashed line in FIG. 2A), and the supporter BLS may include supporter recesses for horizontal arrangement of the first conductive lines BL. The first conductive lines BL may be disposed in the supporter recesses. The supporter BLS may contact the etch stop spacer SP3 in the second direction D2. The first conductive lines BL may be supported by the supporter BLS. The supporter BLS may vertically extend in the first direction D1. The supporter BLS may include a dielectric material. The first conductive lines BL may be formed to be self-aligned with the supporter recesses of the supporter BLS. The supporter BLS may include a low-k material, silicon carbon oxide, silicon nitride, an air gap, or a combination thereof.

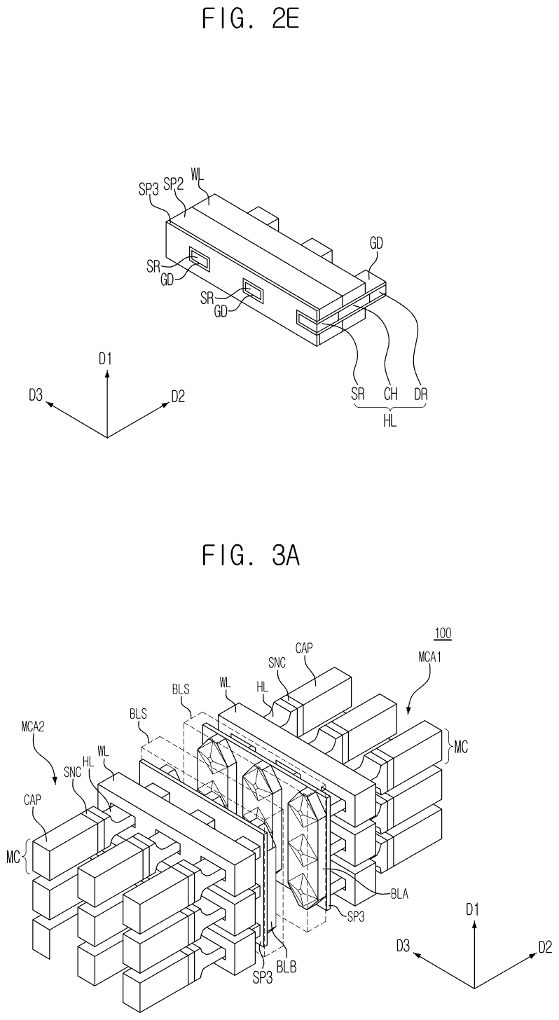

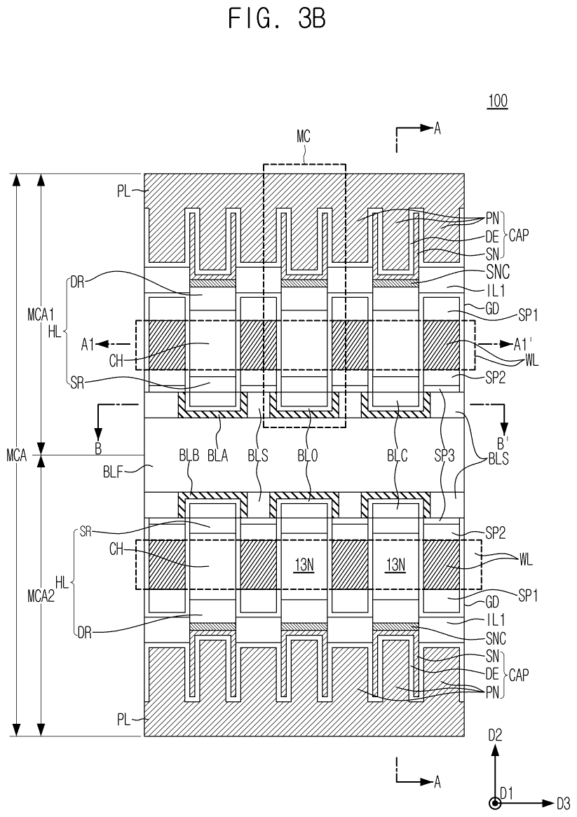

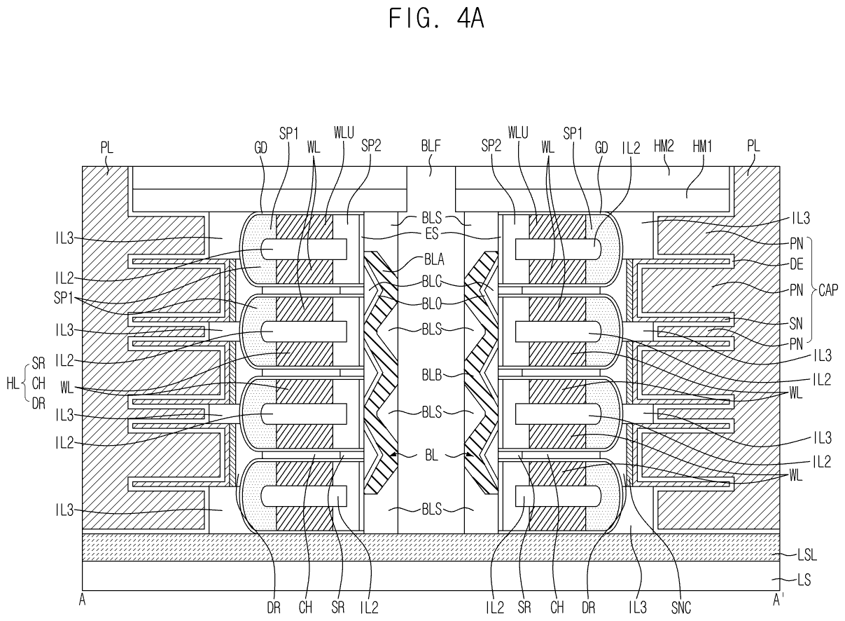

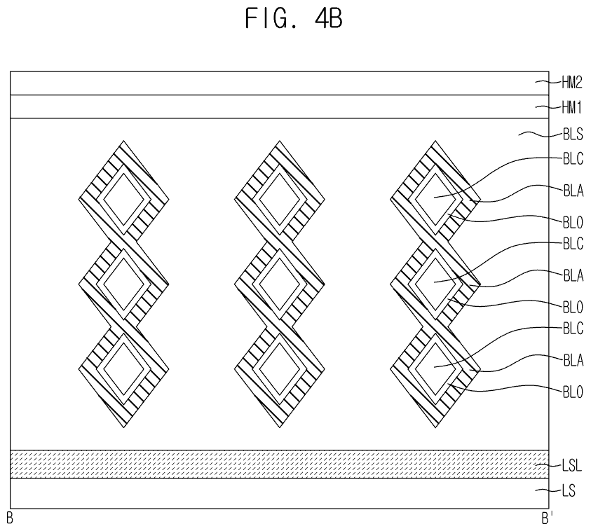

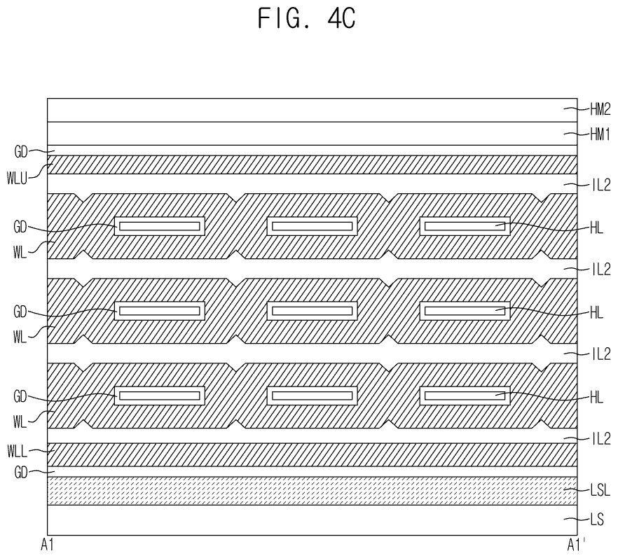

FIG. 3A is a schematic perspective view illustrating a semiconductor device 100 in accordance with an embodiment of the present disclosure. FIG. 3B is a schematic plan view illustrating a horizontal section of the semiconductor device 100 in accordance with an embodiment of the present disclosure. FIG. 4A is a schematic cross-sectional view of the semiconductor device 100 taken along line A-A′ illustrated in FIG. 3B. FIG. 4B is a schematic cross-sectional view of the semiconductor device 100 taken along line B-B′ illustrated in FIG. 3B. FIG. 4C is a schematic cross-sectional view of the semiconductor device 100 taken along line Al-Al′ illustrated in FIG. 3B. Detailed descriptions of overlapping components below are provided above with reference to FIGS. 1A to 2E.

Referring to FIGS. 3A to 4C, the semiconductor device 100 may include a memory cell array MCA. The memory cell array MCA may include a three-dimensional array of memory cells MC arranged in sub-cell arrays, as shown, for example, in FIG. 2A. Each of the memory cells MC may include a first conductive line BL, a switching element TR, and a data storage element CAP, and the switching element TR may include a second conductive line WL, a nano sheet dielectric layer GD, and a nano sheet HL.

In the example embodiment shown in FIG. 3A, the memory cell array MCA may include at least a first sub-cell array MCA1 and a second sub-cell array MCA2. The first sub-cell array MCA1 and the second sub-cell array MCA2 may each include a three-dimensional array of the memory cells MC. The memory cells MC in the first sub-cell array MCA1 may share a first vertical conductive line BLA, and the memory cells MC in the second sub-cell array MCA2 may share a second vertical conductive line BLB. The first and second vertical conductive lines BLA and BLB may each have a shape with angled sides, e.g., angled sides of a pyramid shape. A bottom portion of the first vertical conductive line BLA and a bottom portion of the second vertical conductive line BLB may be electrically isolated from each other.

The first sub-cell array MCA1 may include a horizontal arrangement and a vertical arrangement of the memory cells MC. Each of the memory cells MC of the first sub-cell array MCA1 may include the first vertical conductive line BLA, a switching element TR, and a data storage element CAP. The switching element TR may include a second conductive line WL and a nano sheet HL. The switching elements TR of the memory cells MC may be nano sheet transistors. The first sub-cell array MCA1 may include a horizontal arrangement and a vertical arrangement of the nano sheet transistors having a structure as shown, for example, in FIGS. 1A and 1B. The first sub-cell array MCA1 may include a horizontal arrangement of the first vertical conductive lines BLA. The first sub-cell array MCA1 may include a horizontal arrangement and a vertical arrangement of the second conductive lines WL. The first sub-cell array MCA1 may include a horizontal arrangement and a vertical arrangement of the data storage elements CAP.

The second sub-cell array MCA2 may include a horizontal arrangement and a vertical arrangement of the memory cells MC. Each of the memory cells MC of the second sub-cell array MCA2 may include the second vertical conductive line BLB, a switching element TR, and a data storage element CAP. The switching element TR may include a second conductive line WL and a nano sheet HL. The switching elements TR of the memory cells MC may be nano sheet transistors. The second sub-cell array MCA2 may include a horizontal arrangement and a vertical arrangement of the nano sheet transistors. The second sub-cell array MCA2 may include a horizontal arrangement of the second vertical conductive lines BLB. The second sub-cell array MCA2 may include a horizontal arrangement and a vertical arrangement of the second conductive lines WL. The second sub-cell array MCA2 may include a horizontal arrangement and a vertical arrangement of the data storage elements CAP.

The first conductive line BL may vertically extend in a first direction D1, the nano sheet HL may extend in a second direction D2, and the second conductive line WL may horizontally extend in a third direction D3.

A first inter-cell dielectric layer IL1 may be disposed between the data storage elements CAP disposed adjacent to each other in the third direction D3 (e.g., see FIG. 3B). A second inter-cell dielectric layer IL2 may be disposed between the second conductive lines WL vertically stacked in the first direction D1 (e.g., see FIG. 4A). A third inter-cell dielectric layer IL3 may be disposed between first electrodes SN of the data storage elements CAP vertically stacked in the first direction D1. The first to third inter-cell dielectric layers IL1, IL2 and IL3 may each include, for example, silicon oxide, silicon carbon oxide (SiCO), silicon nitride, or a combination thereof. The first inter-cell dielectric layer IL1 may be referred to as a “device isolation layer”.

Each of the memory cells MC may further include a first contact node BLC and a second contact node SNC. The first contact node BLC may be disposed between the first and second vertical conductive lines (BLA and BLB) and the nano sheet HL. The first contact node BLC may include a metal-based material or a semiconductive material. For example, the first contact node BLC may include titanium, titanium nitride, tungsten, or a combination thereof. In addition, the first contact node BLC may include doped polysilicon, and a first doped region SR may include an impurity diffused from the first contact node BLC.

The second contact node SNC may be disposed between the nano sheet HL and the first electrode SN. The second contact node SNC may include a metal-based material or a semiconductive material. For example, the second contact node SNC may include titanium, titanium nitride, tungsten, or a combination thereof. In addition, the second contact node SNC may include doped polysilicon, and a second doped region DR may include an impurity diffused from the second contact node SNC. A height of the first contact node BLC in the first direction D1 may be less than a height of the second contact node SNC in the first direction D1. A height of the first contact node BLC in the first direction D1 may be greater than a height of a channel CH in the first direction D1, as shown, for example, in FIG. 1B. Each of the first and second contact nodes BLC and SNC may include phosphorus-doped polysilicon or arsenic-doped polysilicon.

Each of the memory cells MC may further include an ohmic contact layer BLO between the first contact node BLC and the first conductive line BL. The ohmic contact layer BLO may include, for example, a metal silicide such as, but not limited to, titanium silicide or molybdenum silicide.

The first contact node BLC may be selectively grown from the nano sheet HL. The first contact node BLC may be formed by the selective epitaxial growth (SEG). For example, the first contact node BLC may be a silicon epitaxial layer formed by the selective epitaxial growth (SEG). The first contact node BLC may be a doped silicon epitaxial layer. The second contact node SNC may be selectively grown from the nano sheet HL. The second contact node SNC may be formed by the selective epitaxial growth (SEG). For example, the second contact node SNC may be a silicon epitaxial layer formed by the selective epitaxial growth (SEG). The second contact node SNC may be a doped silicon epitaxial layer. The first contact node BLC may be a phosphorus-doped silicon epitaxial layer.

Each of the memory cells MC may further include a first spacer SP1, a second spacer SP2, and an etch stop spacer SP3 (see, e.g., FIG. 1B and 3B). The first spacer SP1 may be disposed between the second conductive line WL and the second doped region DR. The second spacer SP2 may be disposed between the first conductive line BL and the second conductive line WL. The etch stop spacer SP3 may be disposed between the first conductive line BL and the second spacer SP2. The first and second spacers SP1 and SP2 may each include a dielectric material. The first and second spacers SP1 and SP2 may each include silicon oxide, silicon nitride, or a combination thereof. The first and second spacers SP1 and SP2 may each include silicon nitride. The etch stop spacer SP3 may include a different material from the first and second spacers SP1 and SP2. The etch stop spacer SP3 may have an etch selectivity with respect to the first and second spacers SP1 and SP2. The etch stop spacer SP3 may be a material selectively grown from the second spacer SP2. The etch stop spacer SP3 may include silicon carbon oxide (SiOC). The silicon carbon oxide may be selectively grown from a surface of the silicon nitride. The first spacer SP1 may surround a first portion of the nano sheet HL, the second conductive line WL may surround a second portion of the nano sheet HL, and the second spacer SP2 may surround a third portion of the nano sheet HL. The first portion, the second portion and the third portion of the nano sheet HL may be defined in a narrow sheet NS.

The first contact node BLC may have a pyramid shape, and the ohmic contact layer BLO and the first conductive line BL may be conformally provided relative to the first contact node BLC, e.g., each may have a pyramid shape covering the first contact node BLC. The first contact node BLC may be a phosphorus-doped silicon epitaxial layer, and the phosphorus-doped silicon epitaxial layer may be grown to have a pyramid shape. Contact resistance may be improved by controlling the size of the first contact node BLC.

The memory cell array MCA may include a plurality of second conductive lines WL vertically stacked in the first direction D1. The memory cell array MCA may include a plurality of nano sheets HL vertically stacked in the first direction D1. The memory cell array MCA may include a plurality of data storage elements CAP vertically stacked in the first direction D1. The memory cell array MCA may include a plurality of first conductive lines BLA and BLB spaced apart in the third direction D3. The memory cell array MCA may include dummy second conductive lines WLU and WLL disposed at a level higher than an uppermost-level second conductive line WL and at a level lower than a lowermost-level second conductive line WL, respectively (e.g., see FIGS. 4A and 4C). The dummy second conductive lines WLU and WLL may each have a linear shape extending horizontally.

The memory cell array MCA may include a stack of a plurality of hard mask layers HM1 and HM2 disposed at a level higher than the uppermost-level second conductive line WL.

A lower structure LS and a stopper layer LSL may be disposed below the memory cell array MCA. The stopper layer LSL may prevent electrical contact between the first and second vertical conductive lines BLA and BLB and the lower structure LS. The stopper layer LSL may prevent electrical contact between the data storage element CAP and the lower structure LS. The stopper layer LSL may include a dielectric material. The lower structure LS may be a material suitable for semiconductor processing. The lower structure LS may include one or more of a conductive material, a dielectric material and a semiconductive material. The lower structure LS may include silicon, monocrystalline silicon, polysilicon, amorphous silicon, silicon germanium, monocrystalline silicon germanium, polycrystalline silicon germanium, carbon-doped silicon, a combination thereof, or multilayers thereof. The lower structure LS may also include another semiconductive material such as germanium. The lower structure LS may also include a III-V group semiconductor substrate, for example, a compound semiconductor substrate such as GaAs.

An inter-array dielectric layer BLF may be disposed between the first vertical conductive line BLA and the second vertical conductive line BLB (e.g., see FIG. 4A). The inter-array dielectric layer BLF may include a dielectric material. For example, the inter-array dielectric layer BLF may include silicon oxide with an air gap embedded therein.

The first and second vertical conductive lines BLA and BLB may be formed to be self-aligned with supporters BLS. The first vertical conductive lines BLA disposed adjacent to each other in the third direction D3 may be isolated from each other by the supporters BLS. The second vertical conductive lines BLB disposed adjacent to each other in the third direction D3 may be isolated from each other by the supporters BLS. The first vertical conductive lines BLA and the second vertical conductive lines BLB disposed adjacent to each other in the second direction D2 may be isolated from each other by the inter-array dielectric layer BLF.

The nano sheets HL of the switching elements TR horizontally disposed in the third direction D3 may share one second conductive line WL. The nano sheets HL of the switching elements TR horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line WL.

Second electrodes PN of the data storage elements CAP may be coupled to a common plate PL.

Referring to FIG. 4B, the memory cell array MCA may include a vertical arrangement of the second conductive lines WL and a vertical arrangement of the second inter-cell dielectric layers IL2. Each of the second inter-cell dielectric layers IL2 may be disposed between the second conductive lines WL. The memory cell array MCA may include the dummy second conductive lines WLU and WLL disposed at a level higher than the uppermost-level second conductive line WL and at a level lower than the lowermost-level second conductive line WL, respectively. The dummy second conductive lines WLU and WLL may each have a linear shape extending horizontally.

The nano sheet dielectric layers GD may surround the nano sheets HL, and the second conductive lines WL may surround the nano sheets HL on the nano sheet dielectric layers GD.

The semiconductor device 100 may further include the supporter BLS, and the supporter BLS may include supporter recesses for horizontal arrangement of the first and second vertical conductive lines BLA and BLB. The first and second vertical conductive lines BLA and BLB may be disposed in the supporter recesses. The supporter BLS may contact the etch stop spacer SP3. The first and second vertical conductive lines BLA and BLB may be supported by the supporter BLS. The supporter BLS may vertically extend in the first direction D1. The supporter BLS may include a dielectric material. The first and second vertical conductive lines BLA and BLB may be formed to be self-aligned with the supporter recesses of the supporter BLS. The supporter BLS may include a low-k material, silicon carbon oxide, silicon nitride, an air gap, or a combination thereof.

According to FIGS. 1A to 4C, the semiconductor device 100 may include a horizontal arrangement of the switching elements TR. Each of the switching elements TR may include the nano sheet HL and the second conductive line WL surrounding the nano sheet HL. The semiconductor device 100 may include the first vertical conductive lines BLA, each of which has a pyramid shape and is coupled to a corresponding one of first edges of the nano sheets HL in the horizontal arrangement. The semiconductor device 100 may include the data storage elements CAP each coupled to a corresponding one of second edges of the nano sheets HL in the horizontal arrangement. The semiconductor device 100 may include the supporter BLS including the supporter recesses, in which the first vertical conductive lines BLA are filled. The semiconductor device 100 may include the first spacer SP1, which is disposed between the data storage elements CAP and the second conductive line WL and surrounds the nano sheets HL. The semiconductor device 100 may include the second spacer SP2, which is disposed between the first vertical conductive lines BLA and the second conductive line WL and surrounds the nano sheets HL. The semiconductor device 100 may include the etch stop spacer SP3 disposed between the second spacer SP2 and the first vertical conductive lines BLA. The first vertical conductive lines BLA may be formed to be self-aligned in the supporter recesses of the supporter BLS. The etch stop spacer SP3 may have an etch selectivity with respect to the first and second spacers SP1 and SP2.

According to FIGS. 1A to 4C, the semiconductor device 100 may include a horizontal arrangement of the switching elements TR. Each of the switching elements TR may include the nano sheet HL and the second conductive line WL surrounding the nano sheet HL. The semiconductor device 100 may include the second vertical conductive lines BLB, each of which has a pyramid shape and is coupled to a corresponding one of first edges of the nano sheets HL in the horizontal arrangement. The semiconductor device 100 may include the data storage elements CAP each coupled to a corresponding one of second edges of the nano sheets HL in the horizontal arrangement. The semiconductor device 100 may include the supporter BLS including the supporter recesses, in which the second vertical conductive lines BLB are filled. The semiconductor device 100 may include the first spacer SP1, which is disposed between the data storage elements CAP and the second conductive line WL and surrounds the nano sheets HL. The semiconductor device 100 may include the second spacer SP2, which is disposed between the second vertical conductive lines BLB and the second conductive line WL and surrounds the nano sheets HL. The semiconductor device 100 may include the etch stop spacer SP3 disposed between the second spacer SP2 and the second vertical conductive lines BLB. The second vertical conductive lines BLB may be formed to be self-aligned in the supporter recesses of the supporter BLS. The etch stop spacer SP3 may have an etch selectivity with respect to the first and second spacers SP1 and SP2.

According to FIGS. 1A to 4C, the semiconductor device 100 may include the first sub-cell array MCA1 including the horizontal arrangement of the first vertical conductive lines BLA each having a pyramid shape. The semiconductor device 100 may include the second sub-cell array MCA2 including the horizontal arrangement of the second vertical conductive lines BLB each having a pyramid shape. The semiconductor device 100 may include the inter-array dielectric layer BLF between the first sub-cell array MCA1 and the second sub-cell array MCA2. The semiconductor device 100 may include the supporters including the supporter recesses, in which the horizontal arrangement of the first vertical conductive lines BLA and the horizontal arrangement of the second vertical conductive lines BLB are filled. Each of the first and second sub-cell arrays MCA1 and MCA2 may include a three-dimensional array of the memory cells MC. Each of the memory cells MC may include a horizontal arrangement of the switching elements TR each including the nano sheet HL and the second conductive line WL surrounding the nano sheet HL. The nano sheet HL may include a narrow sheet NS and a wide sheet WS, as shown, for example, in FIG. 1B. Each of the memory cells MC may further include the first contact node BLC, the ohmic contact layer BLO, the second contact node SNC, and the data storage element CAP.

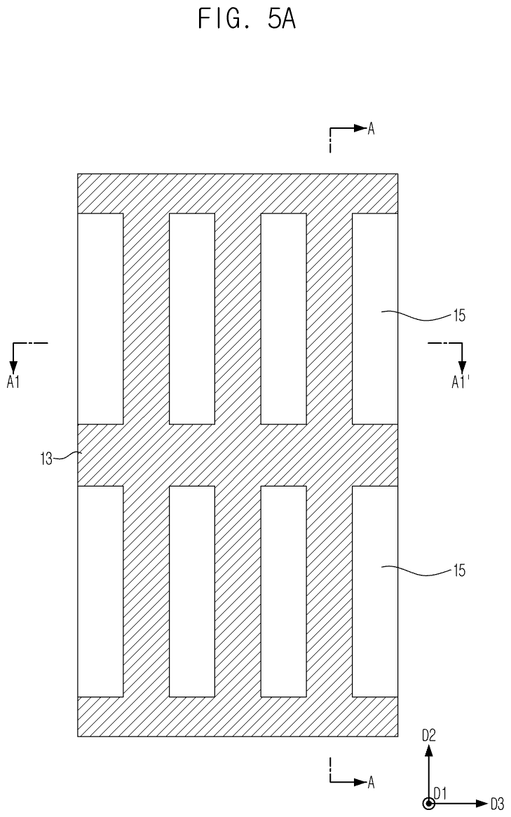

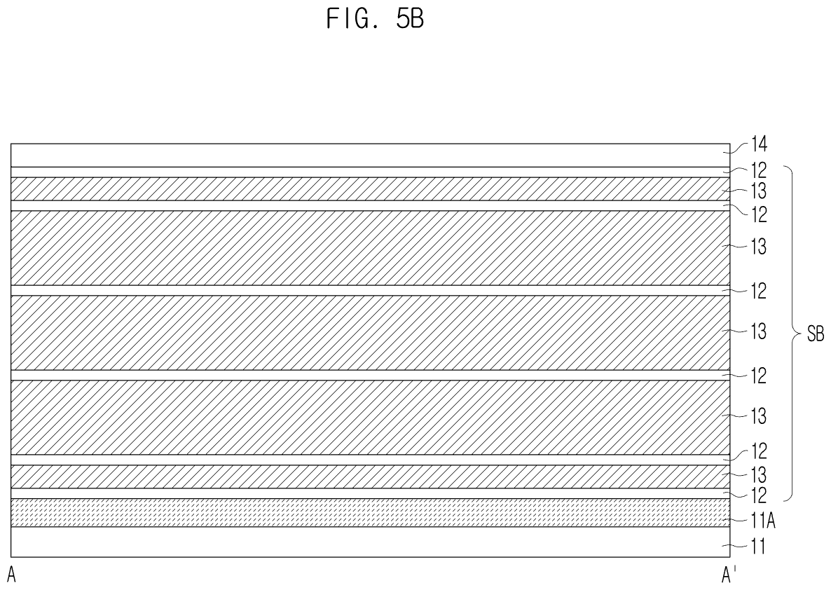

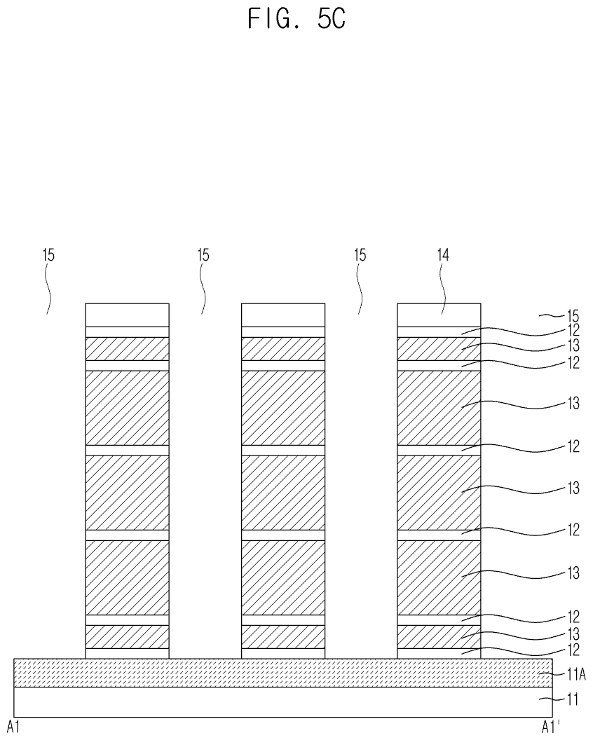

FIGS. 5A to 34B illustrate various operations included in a method for fabricating the semiconductor device in accordance with an embodiment of the present disclosure.

FIG. 5A is a plan view illustrating a structure at a second mold layer level to describe a method for forming a mold stack SB. FIG. 5B is a cross-sectional view of the structure taken along line A-A′ illustrated in FIG. 5A. FIG. 5C is a cross-sectional view of the structure taken along line Al-Al' illustrated in FIG. 5A.

Referring to FIGS. 5A to 5C, a stopper layer 11A may be formed on a substrate 11, and the mold stack SB may be formed over the stopper layer 11A. The substrate 11 may be a material suitable for semiconductor processing. The substrate 11 may include one or more of a conductive material, a dielectric material or a semiconductive material. The substrate 11 may include silicon, monocrystalline silicon, polysilicon, amorphous silicon, silicon germanium, monocrystalline silicon germanium, polycrystalline silicon germanium, carbon-doped silicon, a combination thereof, or multilayers thereof. The substrate 11 may also include another semiconductive material such as germanium. The substrate 11 may also include a Group III-V semiconductor substrate, for example, a compound semiconductor substrate such as GaAs.

The stopper layer 11A may include a dielectric material. The stopper layer 11A may include silicon oxide, silicon carbon oxide, or a combination thereof. The mold stack SB may include an alternating stack of first mold layers 12 and second mold layers 13. The number of alternating first mold layers 12 and second mold layers 13 is shown to be five, but may be a different number of first mold layers 12 and second mold layers 13 in other embodiments. In addition, each of the first mold layers 12 may have a substantially constant thickness, but one or more of the second mold layers 13 may have a thickness different from other ones of the second mold layers 13. The second mold layers 13 may be thicker than the first mold layers 12.

The first mold layers 12 may be alternately stacked with the second mold layers 13. The first mold layers 12 and the second mold layers 13 may be epitaxially grown multiple times to form the mold stack SB. The first mold layer 12 may be disposed at the top of the mold stack SB.

The first mold layers 12 and the second mold layers 13 may be different semiconductive materials. For example, the first mold layers 12 may include silicon germanium or monocrystalline silicon germanium, and the second mold layers 13 may include monocrystalline silicon. The first mold layers 12 and the second mold layers 13 may be formed by an epitaxial growth process. A lowermost first mold layer 12 may serve as a seed layer during the epitaxial growth process. Each of the first mold layers 12 may be thinner than each of the second mold layers 13. The first mold layers 12 may include first epitaxially grown layers, and the second mold layers 13 may include second epitaxially grown layers.

In an embodiment, a plurality of monocrystalline silicon germanium layers may be alternately stacked with a plurality of monocrystalline silicon layers in the mold stack SB. For example, the first mold layers 12 may be the monocrystalline silicon germanium layers, and the second mold layers 13 may be the monocrystalline silicon layers. A stack of a monocrystalline silicon germanium layer and a monocrystalline silicon layer (a SiGe/Si stack) may be stacked multiple times. The first mold layers 12 may be referred to as “sacrificial layers”, and the second mold layers 13 may be referred to as “nano sheet target layers” or “recess target layers”.

The mold stack SB may be referred to as a “vertical stack”. The mold stack SB may be formed by alternately stacking a plurality of sacrificial layers and a plurality of nano sheet target layers. For example, the sacrificial layers may be monocrystalline silicon germanium layers, and the nano sheet target layers may be monocrystalline silicon layers.

A thickness ratio of the first mold layers 12 and the second mold layers 13 in the mold stack SB may be variously modified. For example, the thickness of each of the first mold layers 12 may be approximately 5 to 20 nm, and the thickness of each of the second mold layers 13 may be approximately 50 to 80 nm. A quantity of the first mold layers 12 and a quantity of the second mold layers 13 in the mold stack SB may be variously modified. In some embodiments, a triple stack including the first mold layer 12, the second mold layer 13, and the first mold layer 12 may be defined at lowermost and uppermost portions of the mold stack SB. The second mold layer 13 of the triple stack may have a thickness less than the second mold layer 13 of the mold stack SB.

A first hard mask layer 14 may be formed on an upper portion of the mold stack SB. The first hard mask layer 14 may include a dielectric material such as, but not limited to, an oxide-based material, a nitride-based material, a carbon-based material, or a combination thereof. For example, the first hard mask layer 14 may include SiO₂, Si₃N₄, amorphous carbon, or a combination thereof.

Subsequently, some portions of the mold stack SB may be etched using the first hard mask layer 14 as a barrier, and a plurality of sacrificial isolation openings 15 may be formed (e.g., see FIG. 5C). The sacrificial isolation openings 15 may be initial openings for cell isolation. From the perspective of a top view, cross-sections of the sacrificial isolation openings 15 may each have a rectangular shape (e.g., see FIG. 5A). In some embodiments, the cross-sections of the sacrificial isolation openings 15 may each have a different shape, e.g., a circular shape or an oval shape. In some embodiments, the sacrificial isolation openings 15 may be referred to as “sacrificial isolation trenches”. The sacrificial isolation openings 15 may vertically extend in a first direction D1 and extend lengthwise in a second direction D2. The sacrificial isolation openings 15 may be disposed at a predetermined interval in a third direction D3. An etch process for forming the sacrificial isolation openings 15 may stop at the stopper layer 11A.

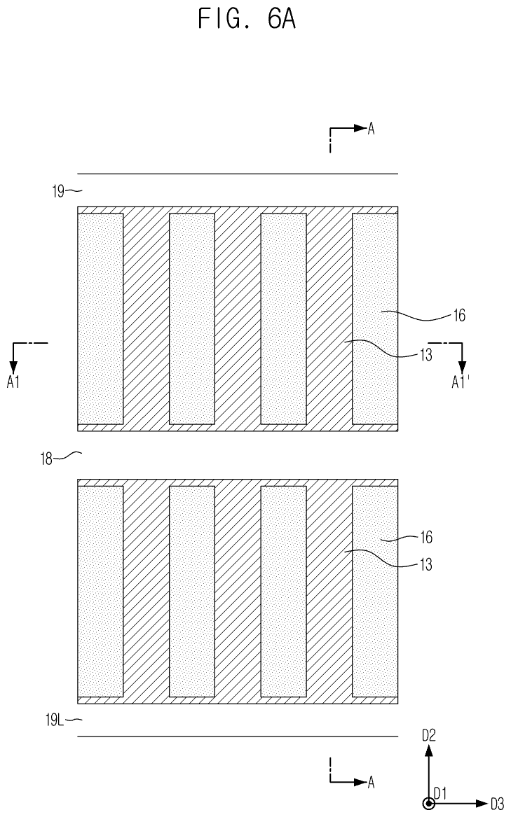

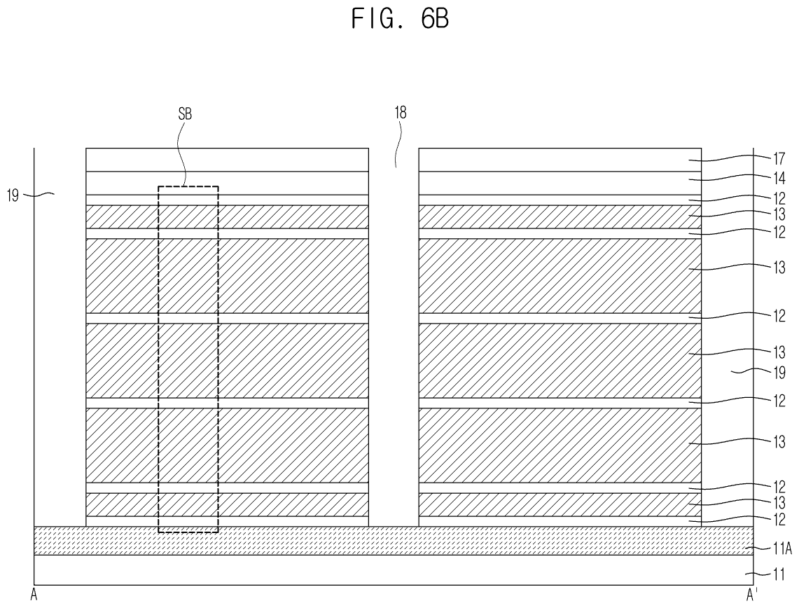

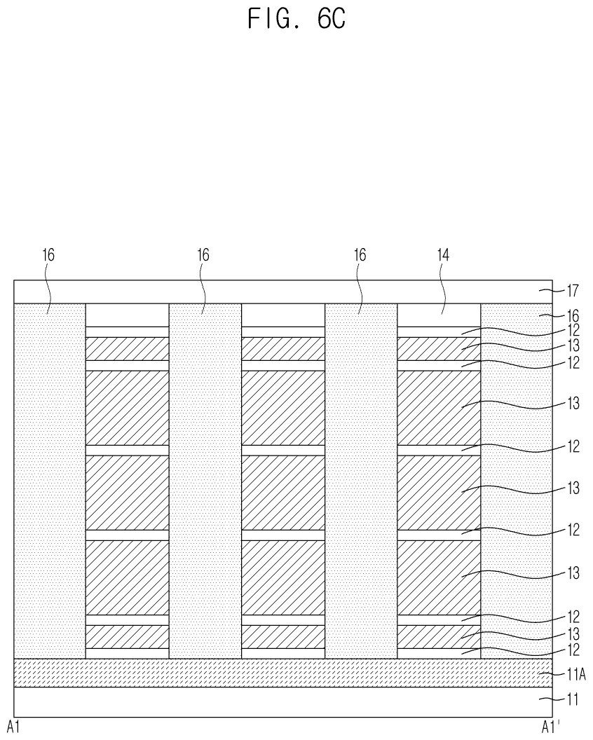

FIG. 6A is a plan view illustrating the structure at the second mold layer level to describe a method for forming sacrificial linear openings 18 and 19. FIG. 6B is a cross-sectional view of the structure taken along line A-A′ illustrated in FIG. 6A. FIG. 6C is a cross-sectional view of the structure taken along line Al-Al′ illustrated in FIG. 6A.

Referring to FIGS. 6A to 6C, sacrificial isolation layers 16 may be formed to fill the sacrificial isolation openings 15. The sacrificial isolation layers 16 may include the same material. The sacrificial isolation layers 16 may be formed of a dielectric material. The sacrificial isolation layers 16 may have an etch selectivity with respect to the mold stack SB. For example, the sacrificial isolation layers 16 may each include silicon oxide, silicon nitride, silicon carbon oxide, silicon carbon nitride, or a combination thereof. Forming the sacrificial isolation layers 16 may include forming sacrificial isolation materials on the mold stack SB to fill the sacrificial isolation openings 15 and planarizing the sacrificial isolation materials so that a surface of the first hard mask layer 14 is exposed.

The sacrificial isolation layers 16 may vertically extend in the first direction D1 and extend lengthwise in the second direction D2. The sacrificial isolation layers 16 may be disposed at a predetermined interval in the third direction D3 depending, for example, on the widths of the second mold layers 13. Each of the sacrificial isolation layers 16 may include a stack of a first sacrificial sub-spacer layer and a first sacrificial gap-fill layer. The first sacrificial sub-spacer layer may be silicon nitride, and the first sacrificial gap-fill layer may be silicon oxide. The sacrificial isolation layers 16 may penetrate the mold stack SB in the first direction D1.

Subsequently, a second hard mask layer 17 may be formed on an upper portion of the mold stack SB and the sacrificial isolation layers 16. The second hard mask layer 17 may include, for example, silicon nitride. The second hard mask layer 17 may be formed by etching a second hard mask material using a mask layer such as photoresist. The second hard mask layer 17 may have a plurality of line-shaped openings defined therein.

Some portions of the mold stack SB may be etched using the second hard mask layer 17 as an etch barrier. Accordingly, a plurality of sacrificial linear openings 18 and 19 may be formed between the sacrificial isolation layers 16 (e.g., see FIG. 6B). The sacrificial linear openings may include a first sacrificial linear opening 18 and a second sacrificial linear opening 19. From the perspective of a top view, the first sacrificial linear opening 18 and the second sacrificial linear opening 19 may be line-shaped openings extending in the third direction D3. The first sacrificial linear opening 18 and the second sacrificial linear opening 19 may vertically extend in the first direction D1. The sacrificial isolation layers 16 may be disposed between the first sacrificial linear opening 18 and the second sacrificial linear opening 19 in the second direction D2. From the perspective of a top view, cross sections of the first and second sacrificial linear openings 18 and 19 may each have a rectangular shape. In some embodiments, the cross sections of the first and second sacrificial linear openings 18 and 19 may each have a different shape, e.g., a circular shape or an oval shape. The first and second sacrificial linear openings 18 and 19 may each have a width in the second direction D2 less than a width in the third direction D3. The first and second sacrificial linear openings 18 and 19 may be referred to as “sacrificial linear trenches”. The sacrificial isolation layers 16 may not contact the first and second sacrificial linear openings 18 and 19.

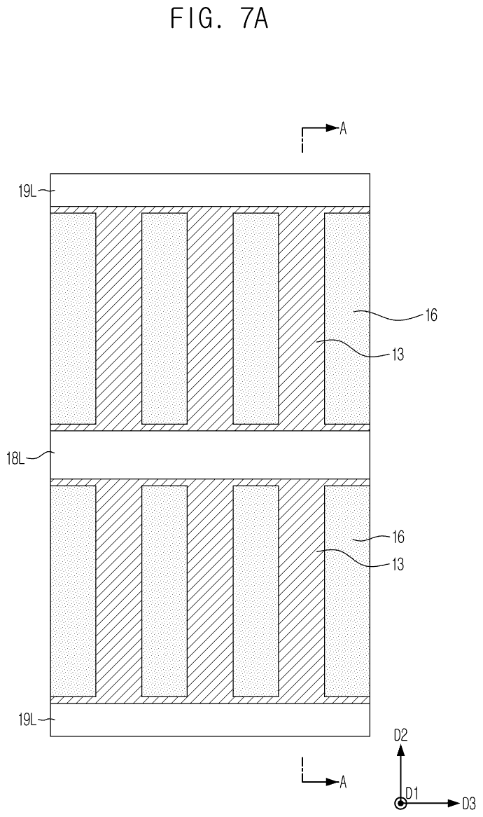

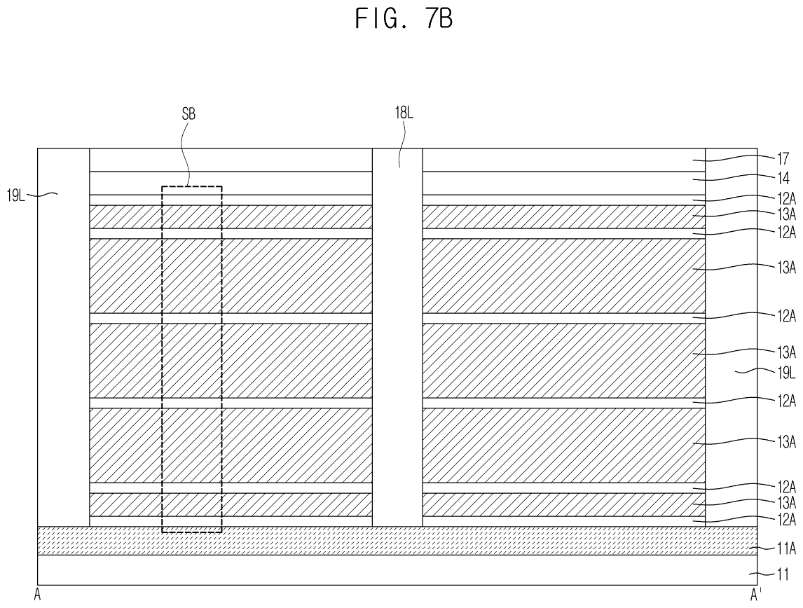

FIG. 7A is a plan view illustrating the structure at the second mold layer level to describe a method for forming linear sacrificial layers 18L and 19L, and FIG. 7B is a cross-sectional view of the structure taken along line A-A′ illustrated in FIG. 7A.

Referring to FIGS. 7A and 7B, the linear sacrificial layers 18L and 19L may be formed to fill the first and second sacrificial linear openings 18 and 19. The linear sacrificial layers may include a first linear sacrificial layer 18L and a second linear sacrificial layer 19L. From the perspective of a top view, the first linear sacrificial layer 18L and the second linear sacrificial layer 19L may have line shapes extending in the third direction D3. The first linear sacrificial layer 18L and the second linear sacrificial layer 19L may vertically extend in the first direction D1. The sacrificial isolation layers 16 may be disposed between the first linear sacrificial layer 18L and the second linear sacrificial layer 19L in the second direction D2. From the perspective of a top view, cross sections of the first and second linear sacrificial layers 18L and 19L may each have a rectangular shape. In some embodiments, the cross-sections of the first and second linear sacrificial layers 18L and 19L may each have a different shape, e.g., a circular shape or an oval shape. The first and second linear sacrificial layers 18L and 19L may include the same material. The first and second linear sacrificial layers 18L and 19L may be formed of a dielectric material. For example, the first and second linear sacrificial layers 18L and 19L may each include silicon oxide, silicon nitride, silicon carbon oxide, silicon carbon nitride, or a combination thereof. The sacrificial isolation layers 16 may not contact (may be spaced from) the first and second linear sacrificial layers 18L and 19L.

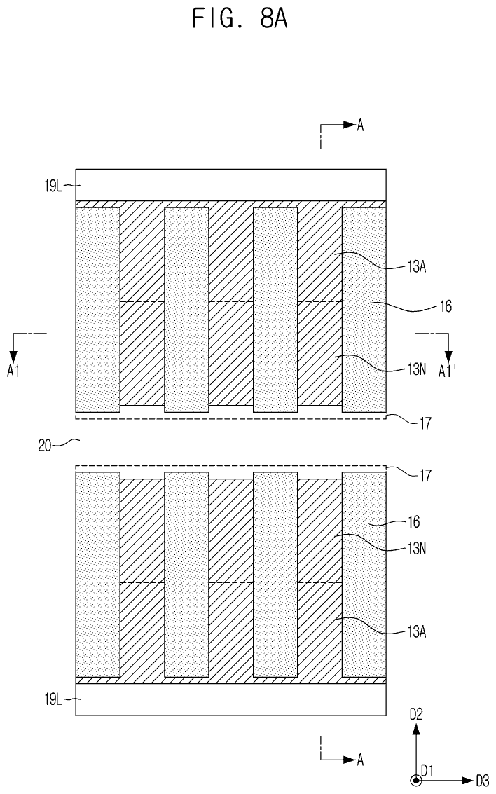

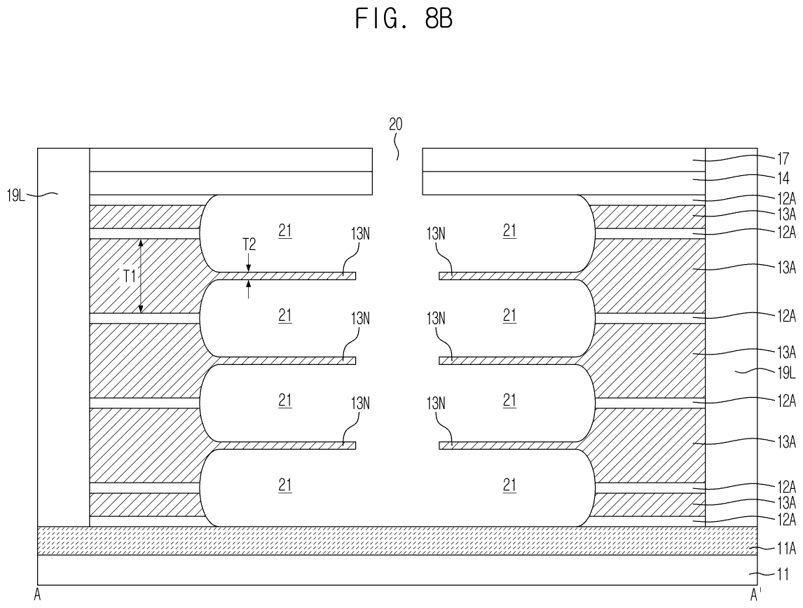

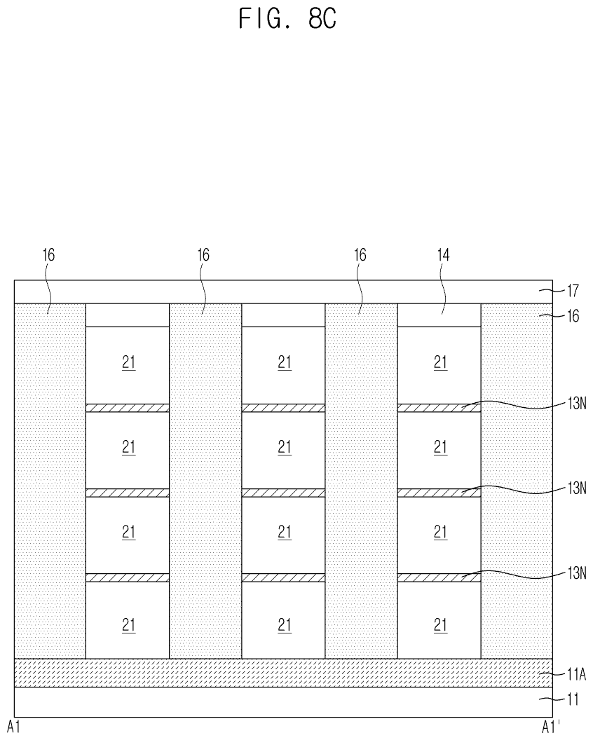

FIG. 8A is a plan view illustrating the structure at the second mold layer level to describe recessing of the second mold layers 12. FIG. 8B is a cross-sectional view of the structure taken along line A-A′ illustrated in FIG. 8A. FIG. 8C is a cross-sectional view of the structure taken along line Al-Al′ illustrated in FIG. 8A.

Referring to FIGS. 8A to 8C, among the first linear sacrificial layer 18L and the second linear sacrificial layer 19L, the first linear sacrificial layer 18L may be selectively removed. The second hard mask layer 17 may be used as an etch barrier to remove the first linear sacrificial layer 18L. Accordingly, a first linear opening 20 may be formed. From the perspective of a top view, the first linear opening 20 may be disposed horizontally spaced apart from the second linear sacrificial layer 19L in the second direction D2.

An etch process for forming the first linear opening 20 may stop at the stopper layer 11A.

Subsequently, the first mold layers 12 and the second mold layers 13 may be selectively recessed through the first linear openings 20.

A difference in etch selectivity between the first mold layers 12 and the second mold layers 13 may be used to selectively recess the first mold layers 12.

The first mold layers 12 may be removed using a wet etch process or a dry etch process. For example, when the first mold layers 12 include silicon germanium layers, and the second mold layers 13 include monocrystalline silicon layers, the silicon germanium layers may be etched using an etchant or etch gas having a selectivity with respect to the monocrystalline silicon layers. The first mold layers each having an original thickness may remain as indicated by reference numeral “12A”.

Subsequently, a portion (a first portion) of each of the second mold layers 13 may be recessed to form a narrow sheet 13N. The wet etch process or dry etch process may be used to recess the second mold layers 13. The original body portion 13A and the narrow sheet 13N may be formed by the partial recessing of each of the second mold layers 13. The original body portion 13A may maintain an original thickness T1, and the narrow sheet 13N may have a thickness T2 less than the original thickness T1. A horizontal length of the original body portion 13A in the second direction D2 may be equal to or different from a horizontal length of the narrow sheet 13N in the second direction D2. A combination of the original body portion 13A and the narrow sheet 13N may be referred to as a “preliminary active layer”. The narrow sheet 13N may be referred to as a “flat plate-shaped sheet” or a “protruding narrow sheet”.

A recess process for forming the narrow sheet 13N may be referred to as a “thinning process” or “trimming process” of the second mold layer 13. To form the narrow sheet 13N, an upper surface, lower surface and side surface of the second mold layer 13 may be recessed. The narrow sheet 13N may be referred to as a “thin-body active layer”. The narrow sheet 13N may include a monocrystalline silicon layer. The recess process for forming the narrow sheet 13N may use, for example, Hot SC-1 (HSC1). The HSC1 may include a solution in which ammonium hydroxide (NH₄OH), hydrogen peroxide (H₂O₂) and water (H₂O) are mixed in a ratio of 1:4:20. Using the HSC1, the second mold layers 13 may be selectively etched.

The narrow sheets 13N may be formed by the partial recess process for the second mold layers 13 as described above. An inter-nano sheet recess 21 may be formed between adjacent ones of the narrow sheets 13N that are vertically disposed. Upper and lower surfaces of the narrow sheets 13N may each include a flat surface. A boundary portion between the original body portion 13A and the narrow sheet 13N may be vertical or have a curvature. Each of the first mold layers 12A may be disposed between the original body portions 13A that are vertically stacked. A horizontal arrangement and a vertical arrangement of the narrow sheets 13N may be formed over the stopper layer 11A.

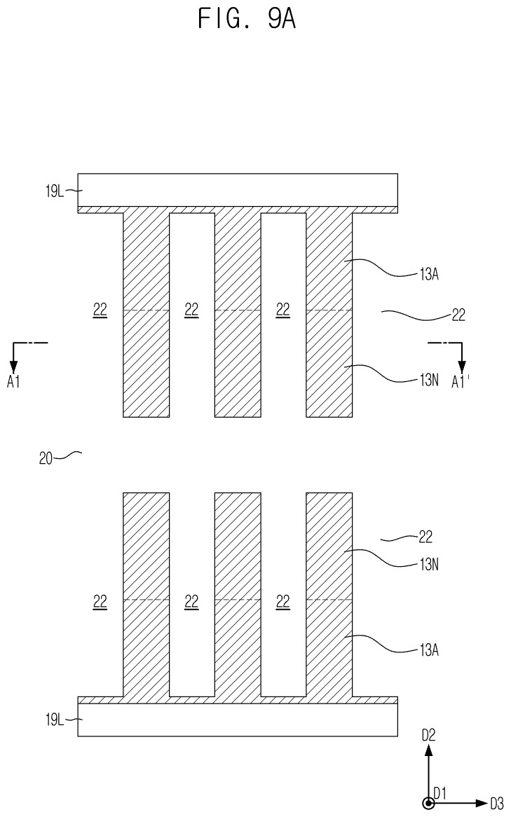

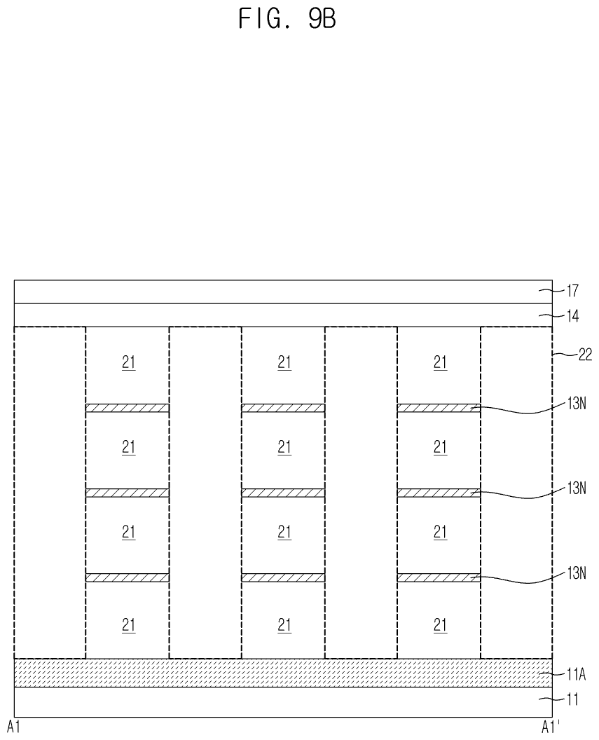

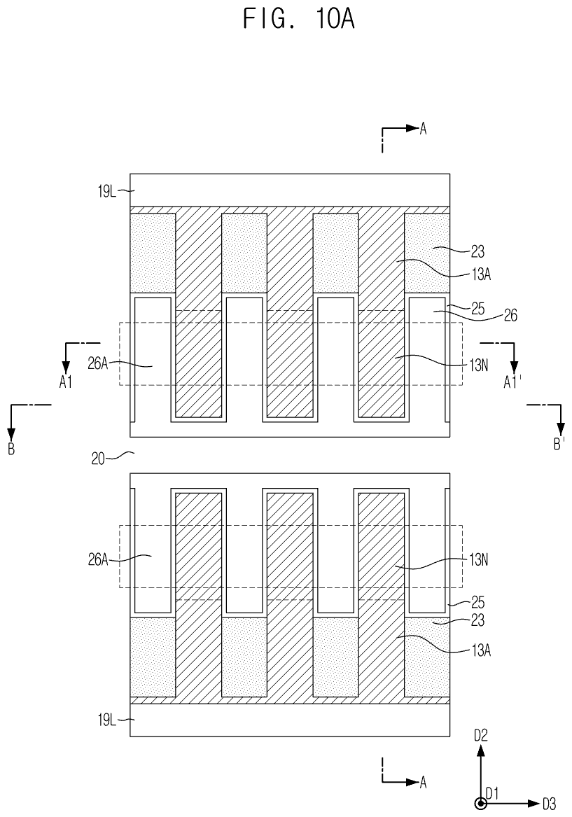

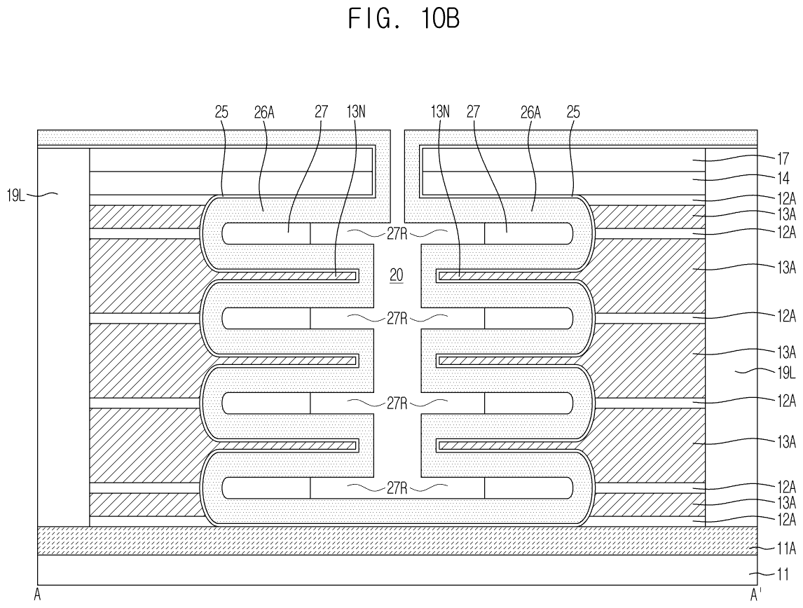

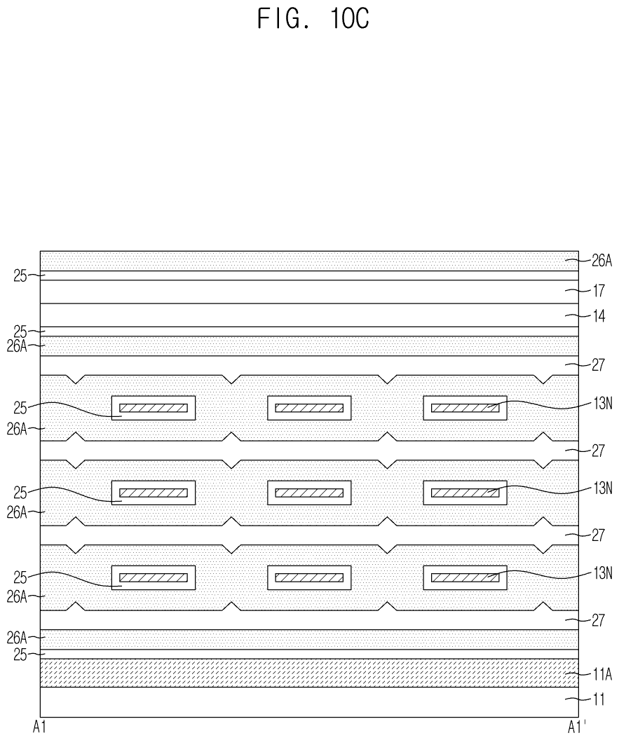

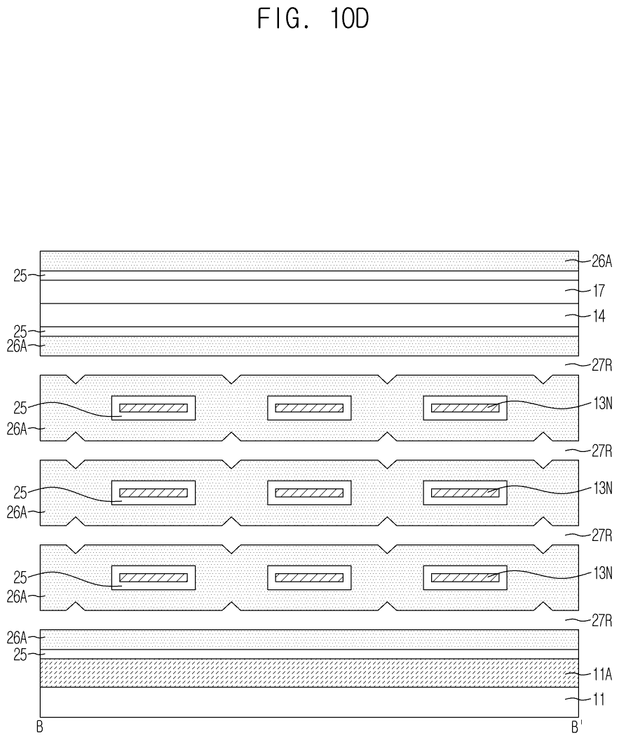

FIG. 9A is a plan view illustrating the structure at a narrow sheet level to describe a method for forming sacrificial isolation layer-level openings 22. FIG. 9B is a cross- sectional view of the structure taken along line A-A′ illustrated in FIG. 9A.

Referring to FIGS. 9A and 9B, the sacrificial isolation layers 16 may be selectively stripped through the inter-nano sheet recesses 21. Accordingly, each of the sacrificial isolation layer-level openings 22 may be formed between the original body portions 13A in the third direction D3. Side surfaces of the first mold layers 12A, side surfaces of the original body portions 13A and side surfaces of the narrow sheets 13N may be exposed in the third direction D3 by the sacrificial isolation layer-level openings 22.

FIG. 10A is a plan view illustrating the structure at the narrow sheet level to describe a method for forming first inter-cell dielectric layers 23, a first spacer layer 26A and a second inter-cell dielectric layer 27. FIG. 10B is a cross-sectional view of the structure taken along line A-A′ illustrated in FIG. 10A. FIG. 10C is a cross-sectional view of the structure taken along line Al-Al′ illustrated in FIG. 10A. FIG. 10D is a cross-sectional view of the structure taken along line B-B′ illustrated in FIG. 10A.

Referring to FIGS. 10A to 10D, the first inter-cell dielectric layers 23 may be formed in the sacrificial isolation layer-level openings 22. The first inter-cell dielectric layers 23 may each include a dielectric material. The first inter-cell dielectric layers 23 may each include silicon oxide, silicon nitride, silicon carbon oxide, or a combination thereof. Forming the first inter-cell dielectric layers 23 may include forming a dielectric material that fills the sacrificial isolation layer-level openings 22 and performing an etch-back process on the dielectric material.

The first inter-cell dielectric layers 23 may fill portions of the sacrificial isolation layer-level openings 22. The side surfaces of the first mold layers 12A and the side surfaces of the original body portions 13A may be covered by the first inter-cell dielectric layers 23 in the third direction D3. The first inter-cell dielectric layers 23 may expose the side surfaces of the narrow sheets 13N. The other portions of the sacrificial isolation layer-level openings 22, i.e., non-gap-filled portions, may expose the side surfaces of the narrow sheets 13N.

Subsequently, a nano sheet dielectric layer 25 may be formed on the exposed portions of the narrow sheets 13N. The nano sheet dielectric layer 25 may be referred to as a “gate dielectric layer,” e.g., corresponding to nano sheet dielectric layer GD shown in FIG. 1B.

The nano sheet dielectric layer 25 may be formed by oxidizing the surfaces of the narrow sheets 13N. In some embodiments, the nano sheet dielectric layer 25 may be formed by a deposition process and an oxidation process of silicon oxide. The nano sheet dielectric layer 25 may include silicon oxide, silicon nitride, metal oxide, metal oxide nitride, metal silicate, a high-k material, a ferroelectric material, an anti-ferroelectric material, or a combination thereof. The nano sheet dielectric layer 25 may include SiO₂, Si₃N₄, HfO₂, Al₂O₃, ZrO₂, AlON, HfON, HfSiO, HfSiON, or a combination thereof. The nano sheet dielectric layer 25 may be formed on all surfaces of the narrow sheets 13N.

The first spacer layer 26A may be formed on the nano sheet dielectric layer 25. The first spacer layer 26A may include silicon nitride. The first spacer layer 26A may surround and cover the narrow sheets 13N on the nano sheet dielectric layer 25. The first spacer layer 26A may be thicker than the nano sheet dielectric layer 25.

The second inter-cell dielectric layer 27 may be formed on the first spacer layer 26A. The second inter-cell dielectric layer 27 may include silicon oxide. Deposition and etch-back processes of silicon oxide may be performed to form the second inter-cell dielectric layer 27. The second inter-cell dielectric layer 27 may be disposed in the inter-nano sheet recesses 21 on the first spacer layer 26A. The second inter-cell dielectric layer 27 may not be disposed in the first linear opening 20. Non-gap-fill spaces 27R may be defined on side surfaces of the second inter-cell dielectric layer 27.

The nano sheet dielectric layer 25 and the first spacer layer 26A may also be formed on the surface of the stopper layer 11A. As described above, the first spacer layer 26A may be disposed between the narrow sheets 13N in the third direction D3.

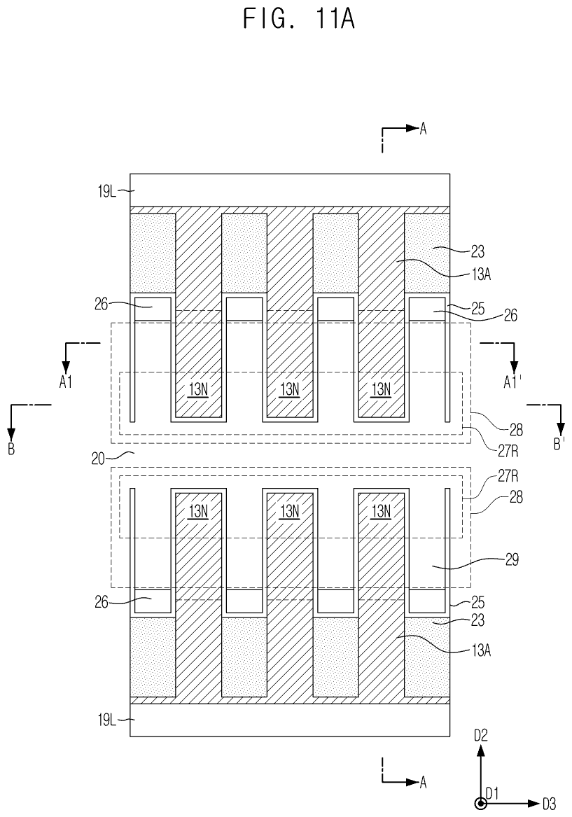

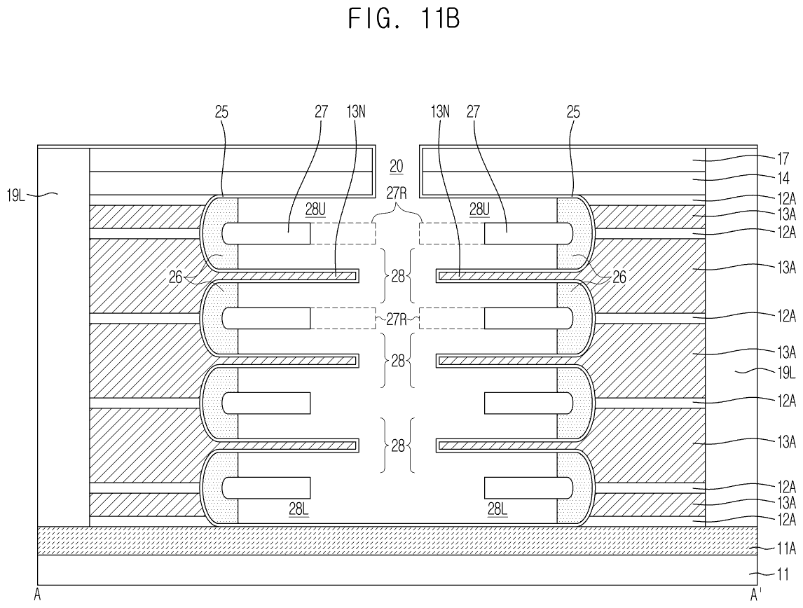

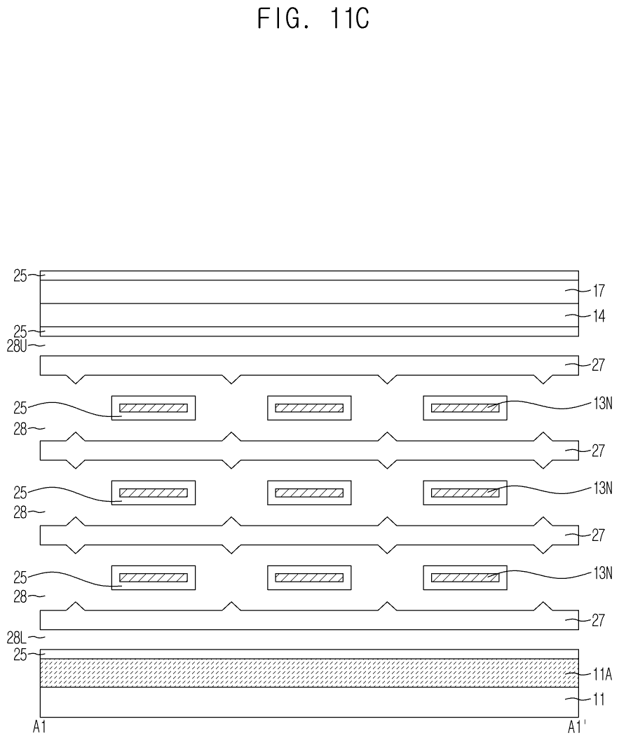

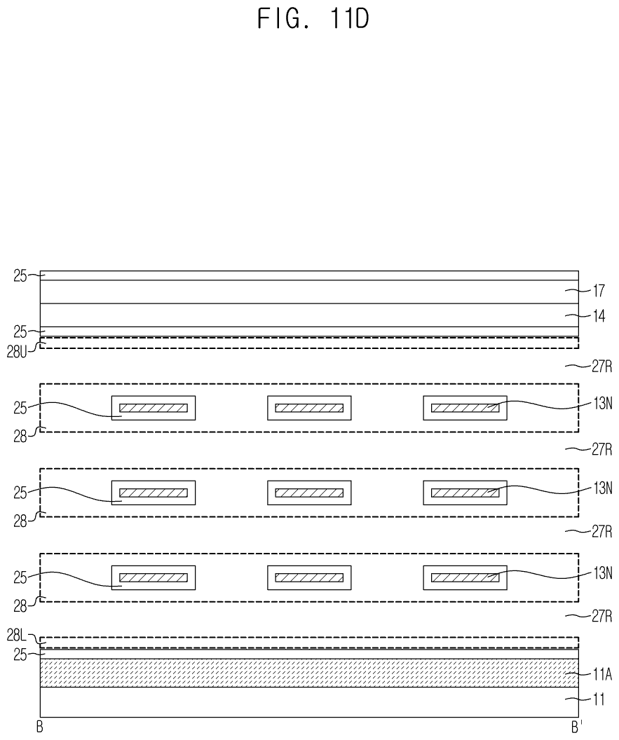

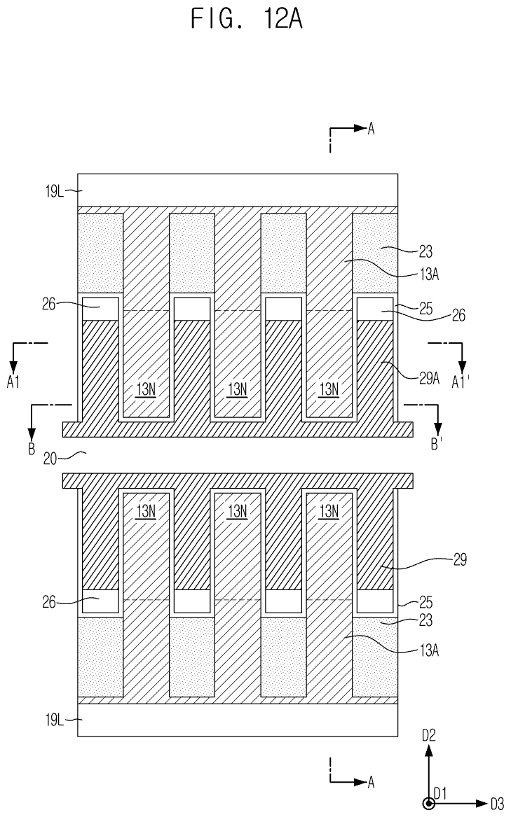

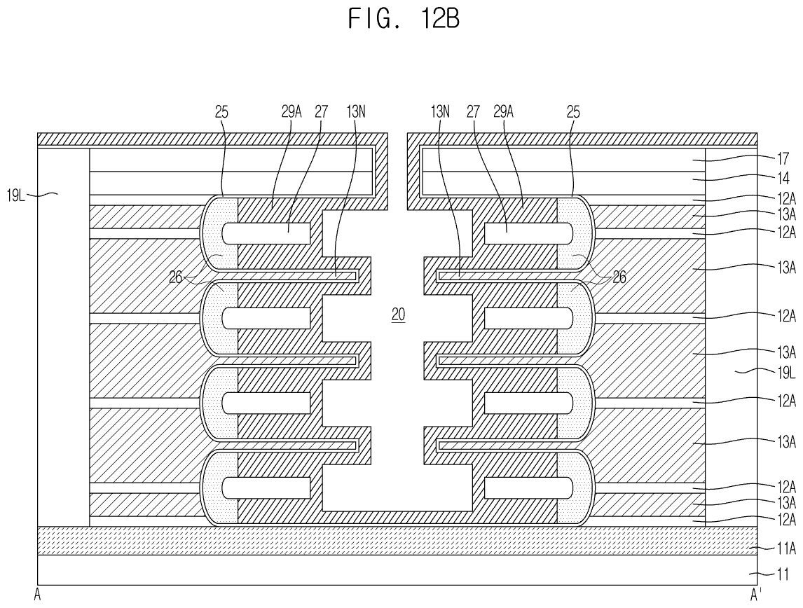

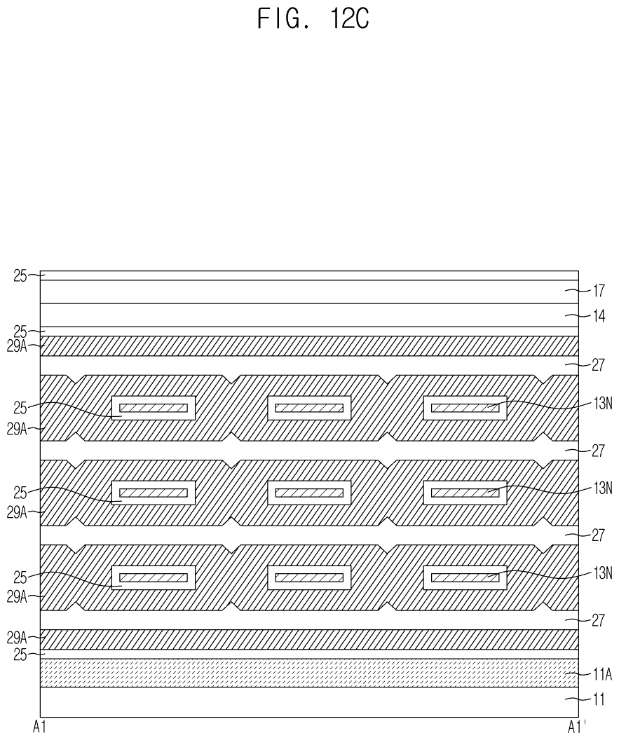

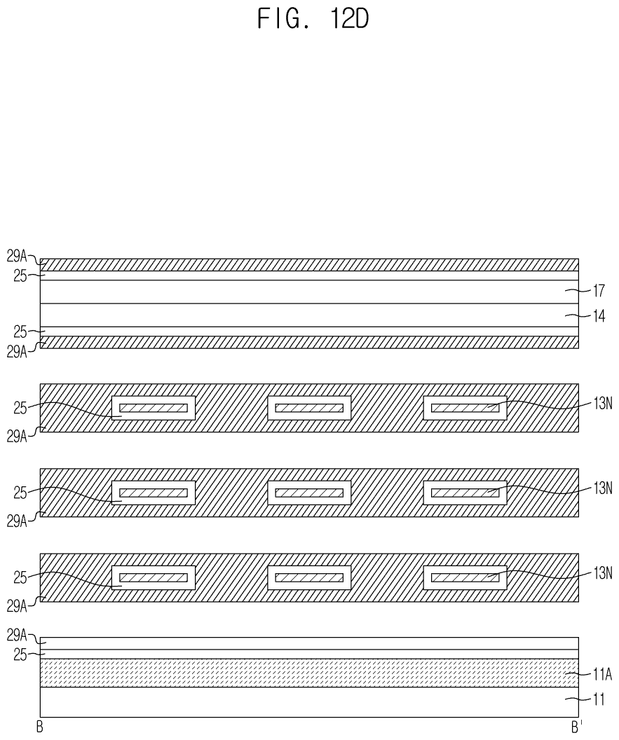

FIG. 11A is a plan view illustrating the structure at the narrow sheet level to describe a method for forming first spacers 26. FIG. 11B is a cross-sectional view of the structure taken along line A-A′ illustrated in FIG. 11A. FIG. 11C is a cross-sectional view of the structure taken along line Al-Al′ illustrated in FIG. 11A. FIG. 11D is a cross-sectional view of the structure taken along line B-B′ illustrated in FIG. 11A.

Referring to FIGS. 11A to 11D, the first spacer layer 26A may be selectively recessed through the first linear opening 20. The remaining first spacer layers may become the first spacers 26.

As the first spacers 26 are formed, first linear surrounding recesses 28 surrounding the narrow sheets 13N may be formed on the nano sheet dielectric layer 25. Each of the second inter-cell dielectric layers 27 may be disposed between the first linear surrounding recesses 28 that are vertically disposed. An upper-level dummy horizontal recess 28U may be formed on an uppermost second inter-cell dielectric layer 27, and a lower-level dummy horizontal recess 28L may be formed below a lowermost second inter-cell dielectric layer 27L. The upper-level and lower-level dummy horizontal recesses 28U and 28L may each have a non-surrounding shape, i.e., a flat shape.

The first spacers 26 may surround first portions of the narrow sheets 13N at the same horizontal level on the nano sheet dielectric layer 25.

FIG. 12A is a plan view illustrating the structure at the narrow sheet level to

describe a method for forming a horizontal conductive line layer 29A. FIG. 12B is a cross-sectional view of the structure taken along line A-A′ illustrated in FIG. 12A. FIG. 12C is a cross-sectional view of the structure taken along line Al-Al′ illustrated in FIG. 12A. FIG. 12D is a cross-sectional view of the structure taken along line B-B′ illustrated in FIG. 12A.

Referring to FIGS. 12A to 12D, the horizontal conductive line layer 29A filling the linear surrounding recesses 28 may be formed.

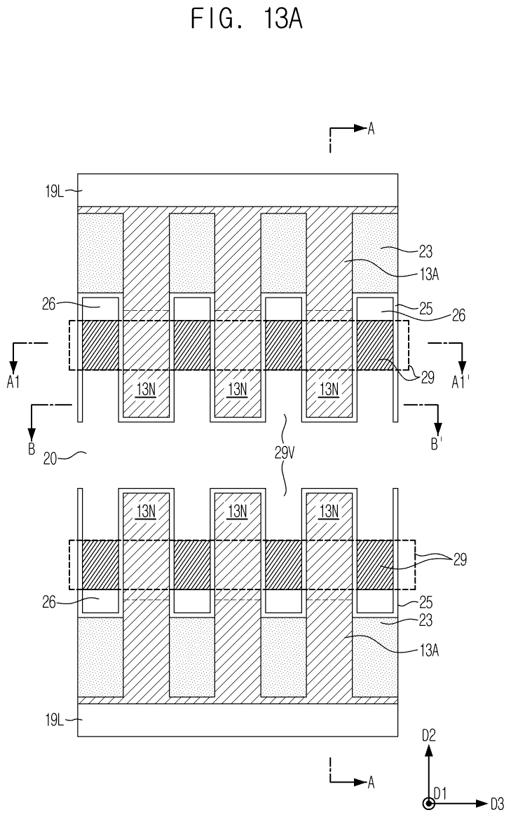

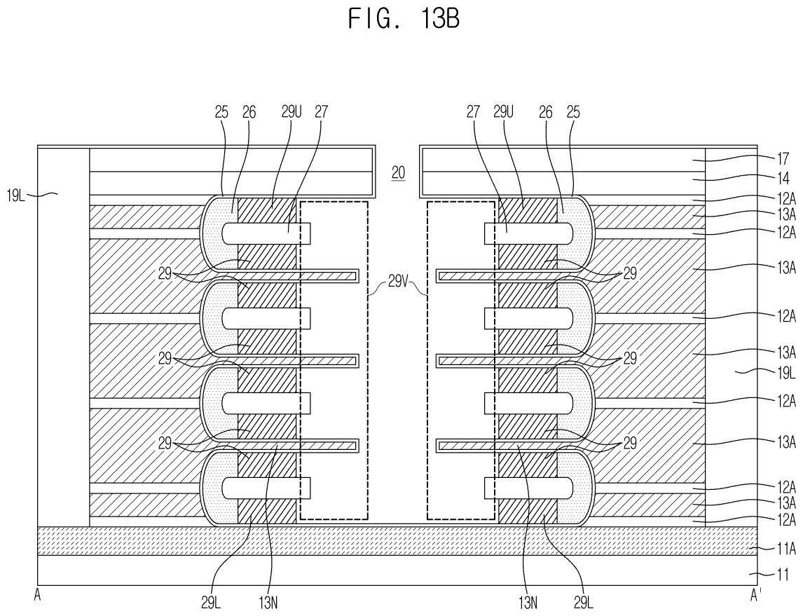

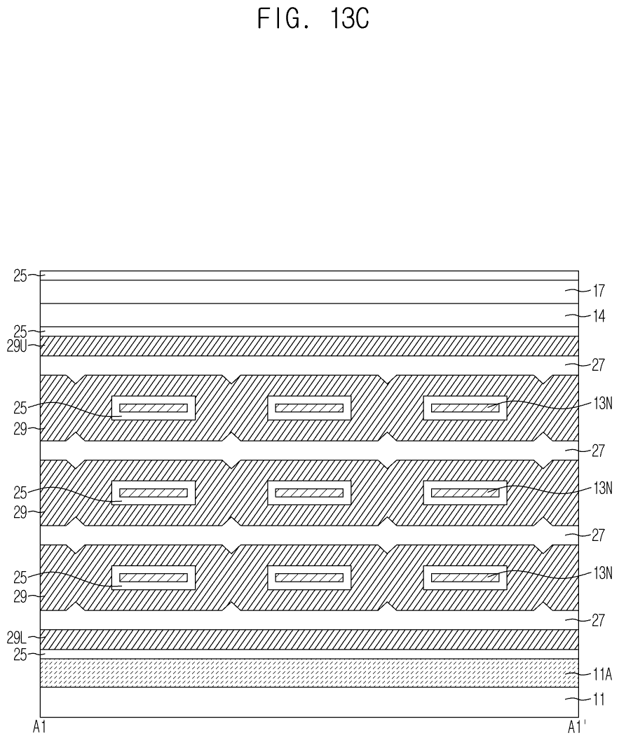

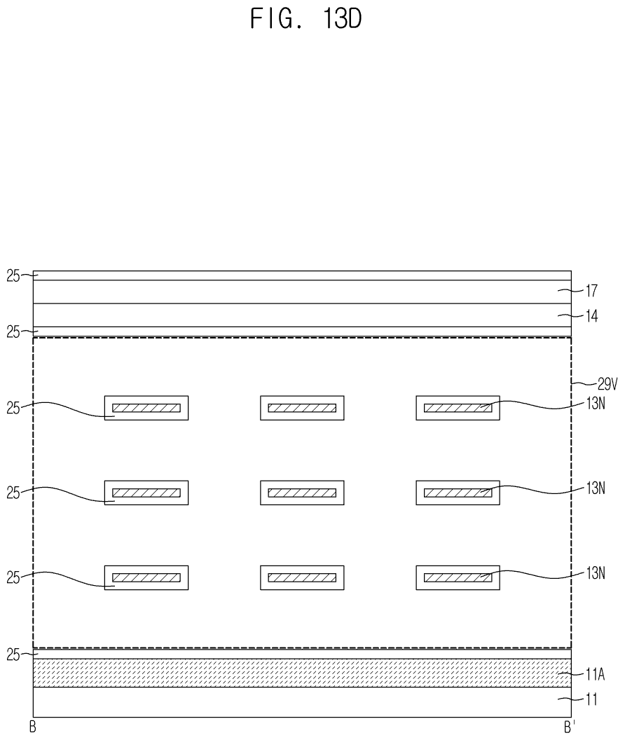

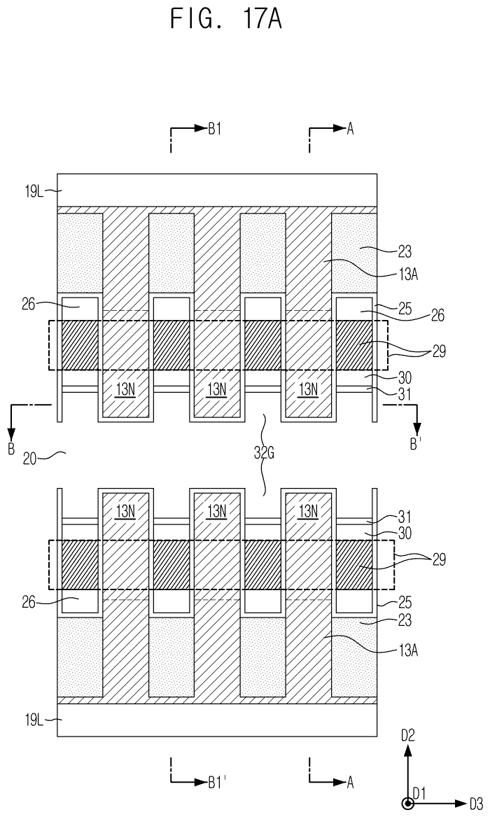

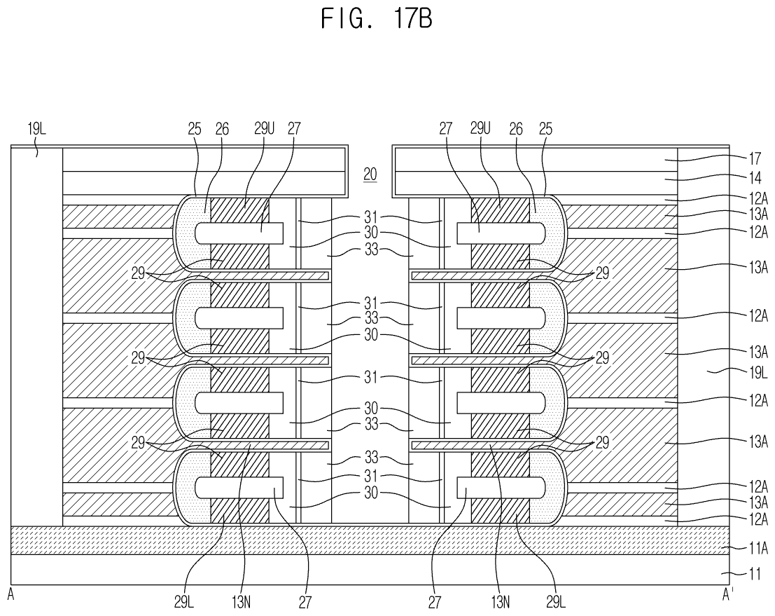

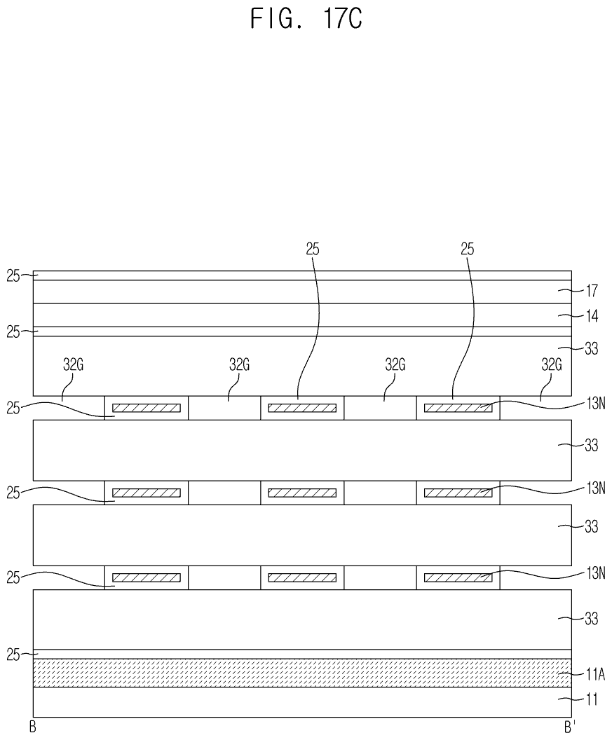

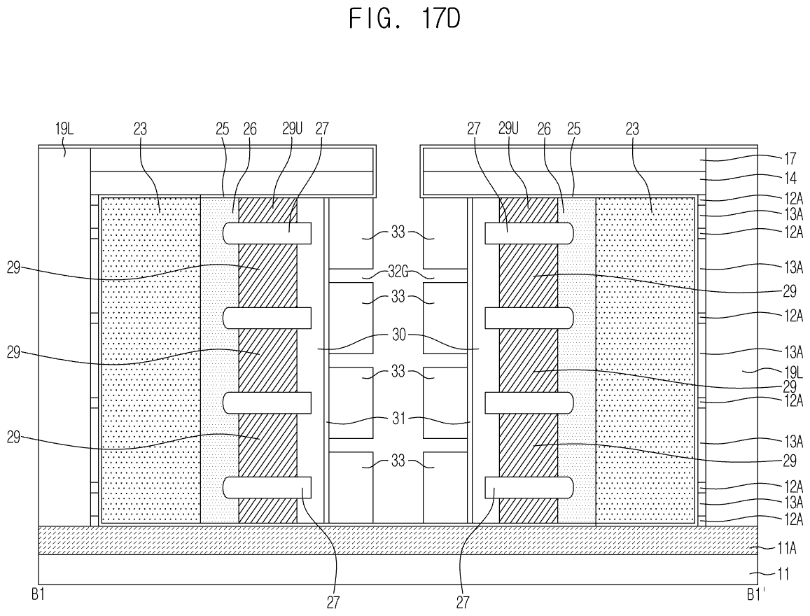

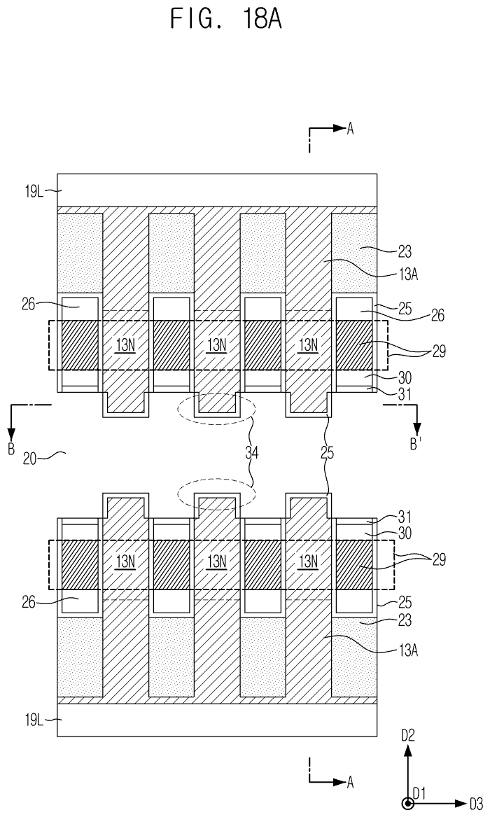

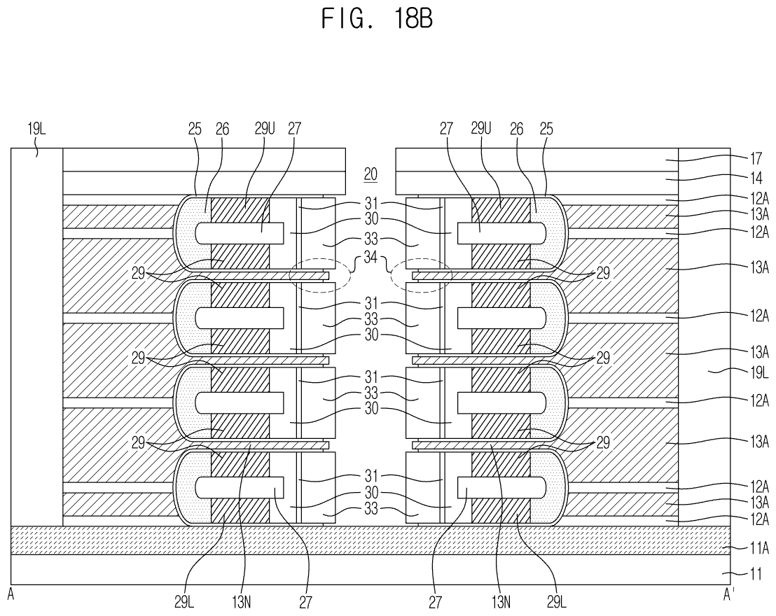

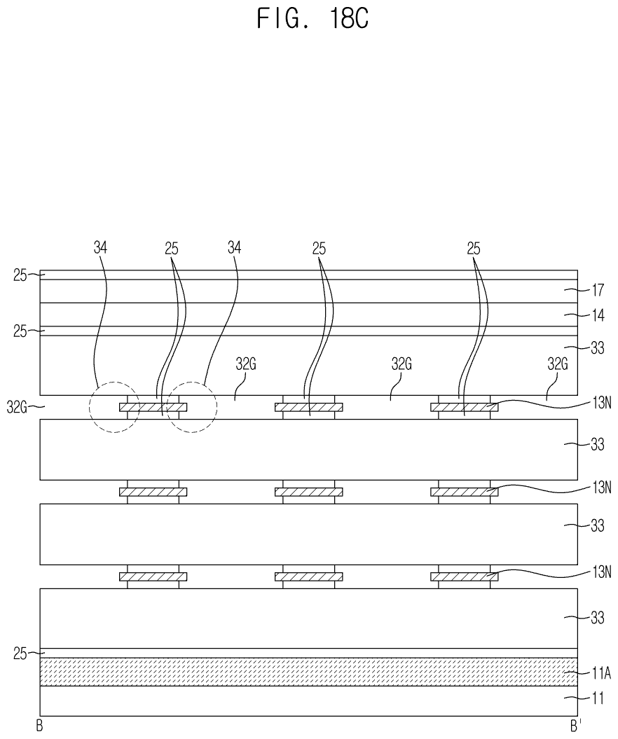

FIG. 13A is a plan view illustrating the structure at the narrow sheet level to describe a method for forming horizontal conductive lines 29. FIG. 13B is a cross-sectional view of the structure taken along line A-A′ illustrated in FIG. 17A. FIG. 13C is a cross-sectional view of the structure taken along line Al-Al′ illustrated in FIG. 13A. FIG. 13D is a cross-sectional view of the structure taken along line B-B′ illustrated in FIG. 13A.

Referring to FIGS. 13A to 13D, the horizontal conductive lines 29 filling the first linear surrounding recesses 28 may be formed. The horizontal conductive lines 29 may horizontally extend in the third direction D3.

Forming the horizontal conductive lines 29 may include performing a horizontal etch-back process on the horizontal conductive line layer 29A. Each of the horizontal conductive lines 29 may simultaneously surround the narrow sheets 13N at the same level. The horizontal conductive lines 29 may each include a metal-based material, a semiconductive material, or a combination thereof. The horizontal conductive lines 29 may each include molybdenum, molybdenum nitride, ruthenium, titanium nitride, tungsten, polysilicon, or a combination thereof. For example, the horizontal conductive lines 29 may each include a titanium nitride and tungsten (TiN/W) stack in which titanium nitride and tungsten are sequentially stacked. The horizontal conductive lines 29 may each include an N-type work function material or a P-type work function material. The N-type work function material may have a low work function of approximately 4.5 eV or less, and the P-type work function material may have a high work function of approximately 4.5 eV or greater. Each of the second inter-cell dielectric layers 27 may be disposed between a plurality of horizontal conductive lines 29 in the first direction D1. The horizontal conductive lines 29 surrounding the narrow sheets 13N may be referred to as “gate-all-around (GAA) electrodes”. The narrow sheets 13N may be referred to as “nano sheet channels”, “nano wires” or “nano wire channels”.

A lower-level dummy horizontal electrode 29L may be formed on the stopper layer 11A. One of the nano sheet dielectric layers 25 may be interposed between the dummy horizontal electrode 29L and the stopper layer 11A. An upper-level dummy horizontal electrode 29U may be formed over an uppermost horizontal conductive line 29. The dummy horizontal electrodes 29L and 29U may each have a non-surrounding shape (e.g., see FIG. 13C).

The horizontal conductive lines 29 may surround second portions of the narrow sheets 13N at the same horizontal level on the nano sheet dielectric layer 25.

After the horizontal conductive lines 29 are formed, a second linear surrounding recess 29V may be defined to open third portions of the narrow sheets 13N. The second linear surrounding recess 29V may be a space where second and etch stop spacers are to be formed. The second linear surrounding recess 29V may surround the third portions of the narrow sheets 13N at the same horizontal level on the nano sheet dielectric layer 25.

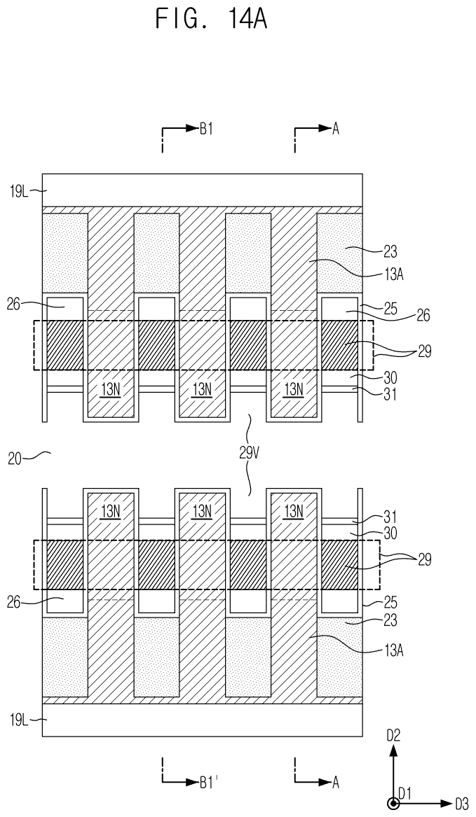

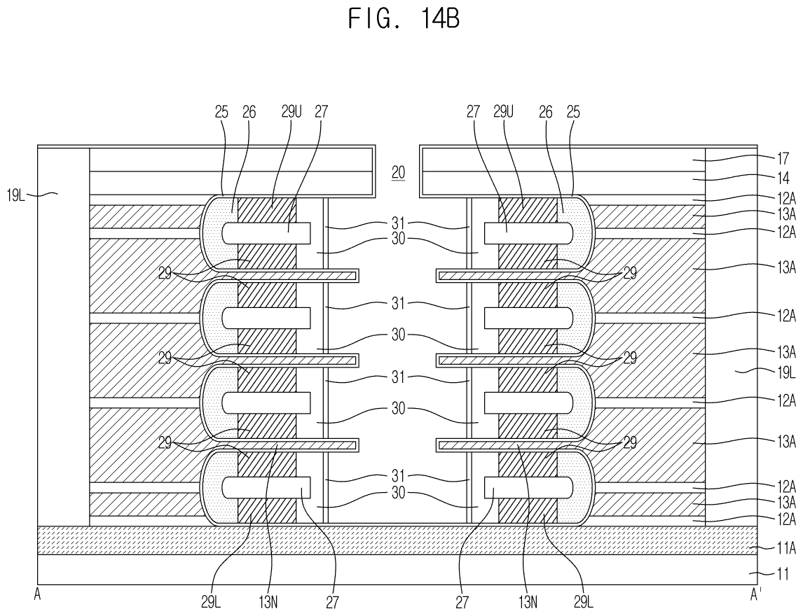

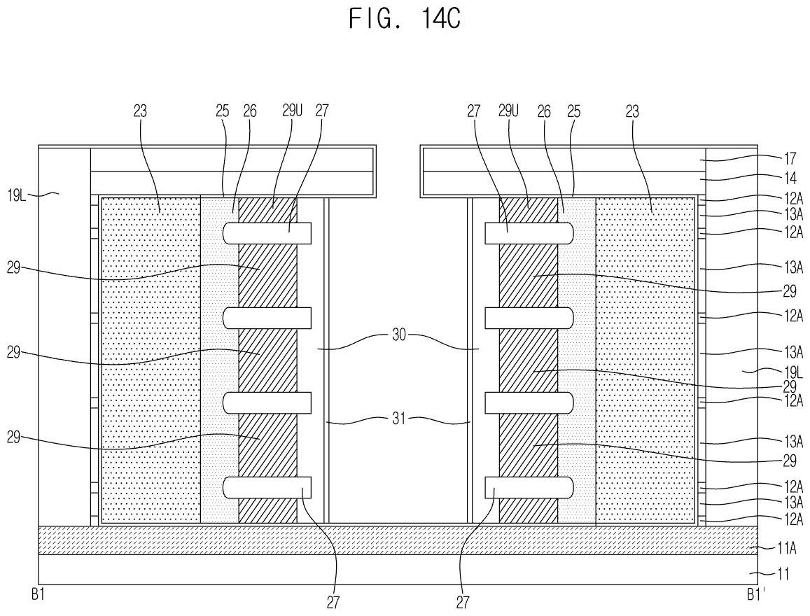

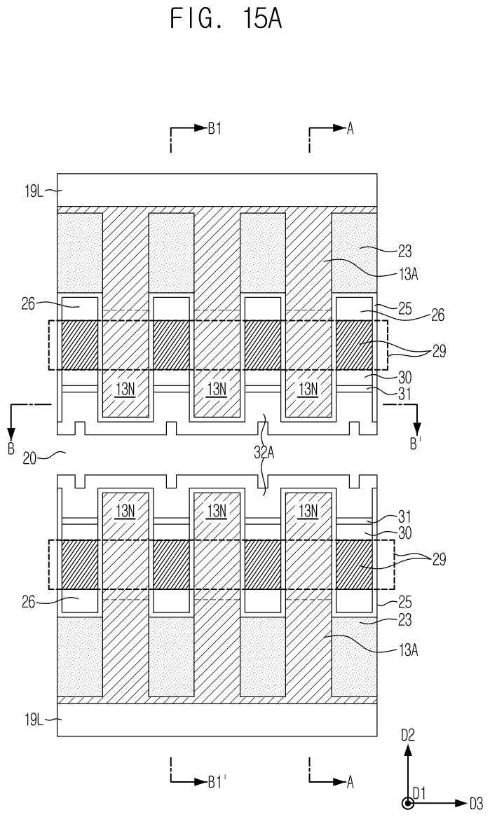

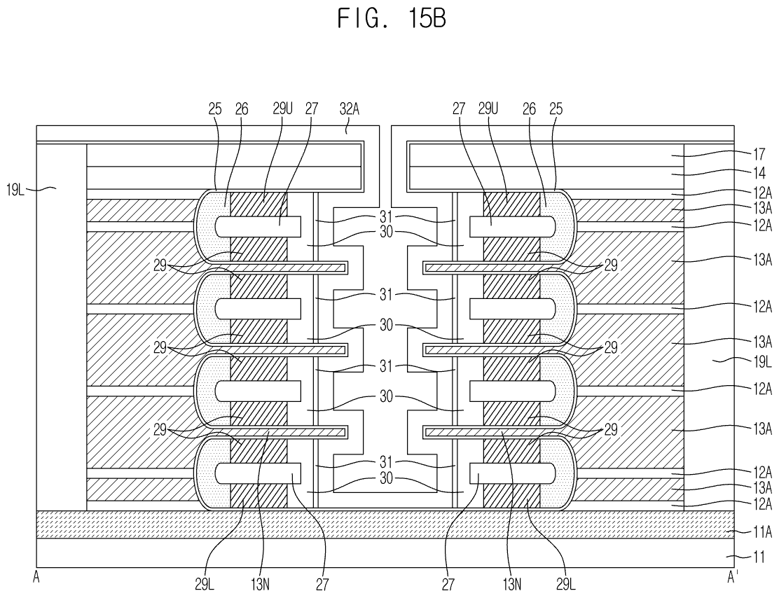

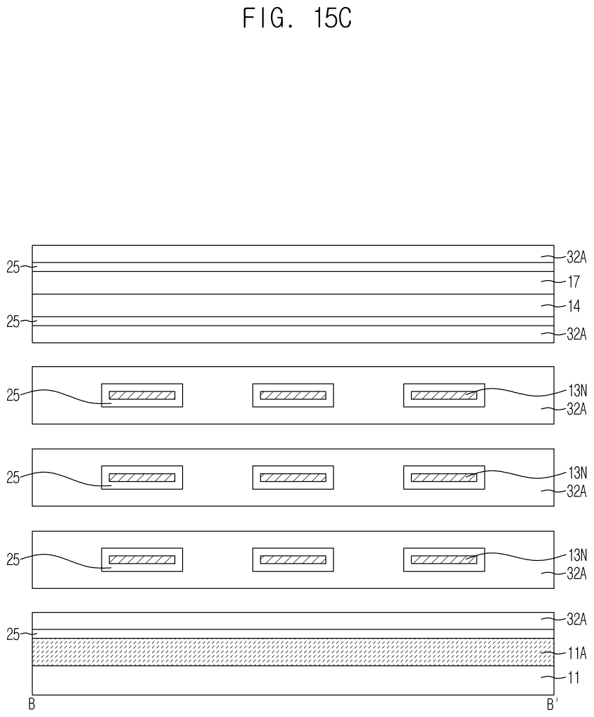

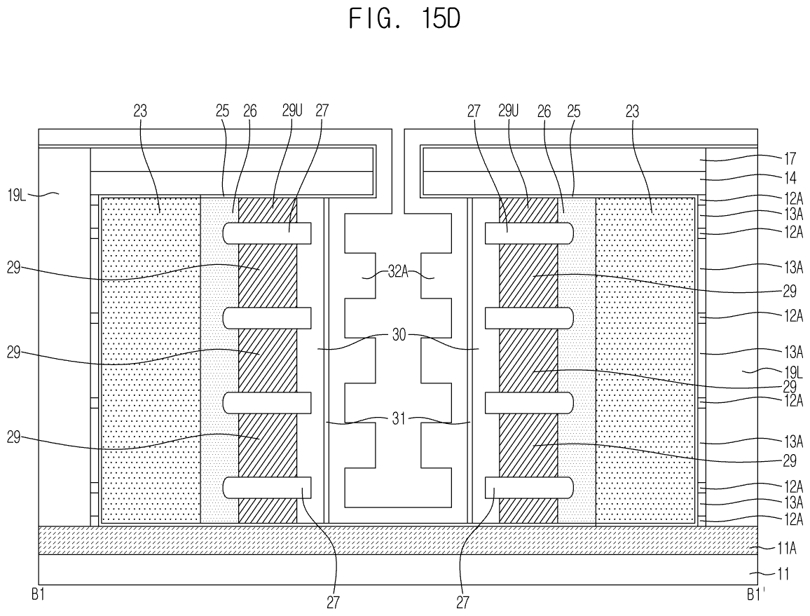

FIG. 14A is a plan view illustrating the structure at the narrow sheet level to describe a method for forming a second spacer 30 and an etch stop spacer 31. FIG. 14B is a cross-sectional view of the structure taken along line A-A′ illustrated in FIG. 14A. FIG. 14C is a cross-sectional view of the structure taken along line B1-B1′ illustrated in FIG. 14A.

Referring to FIGS. 14A to 14C, a plurality of spacer materials may be formed in the second linear surrounding recess 29V.

The second spacer 30 may correspond to spacer SP2 in FIG. 1B, and thus may be formed on one side of each of the horizontal conductive lines 29. The second spacer 30 may include silicon oxide, silicon nitride, silicon carbon oxide, an embedded air gap, or a combination thereof. The second spacer 30 may contact one side of each of the horizontal conductive lines 29 and cover edge portions of the second inter-cell dielectric layers 27. The second spacer 30 may surround all surfaces of the narrow sheets 13N on the nano sheet dielectric layer 25.

Subsequently, the etch stop spacer 31 may be formed on the second spacer 30. The etch stop spacer 31 may be selectively grown from a surface of the second spacer 30. The etch stop spacer 31 may include a different material from the first and second spacers 26 and 30. The etch stop spacer 31 may have an etch selectivity with respect to the first and second spacers 26 and 30. The etch stop spacer 31 may be a material selectively grown from the second spacer 30. The etch stop spacer 31 may include silicon carbon oxide (SiOC). The silicon carbon oxide may be selectively grown from a surface of silicon nitride.

FIG. 15A is a plan view illustrating the structure at the narrow sheet level to describe a method for forming a first sacrificial spacer layer 32A. FIG. 15B is a cross-sectional view of the structure taken along line A-A′ illustrated in FIG. 15A. FIG. 15C is a cross-sectional view of the structure taken along line B-B′ illustrated in FIG. 15A. FIG. 15D is a cross-sectional view of the structure taken along line B1-B1′ illustrated in FIG. 15A.

Referring to FIGS. 15A to 15D, the first sacrificial spacer layer 32A may be formed on the etch stop spacer 31. The first sacrificial spacer layer 32A may include polysilicon. The first sacrificial spacer layer 32A may surround the narrow sheets 13N at the same horizontal level on the nano sheet dielectric layer 25.

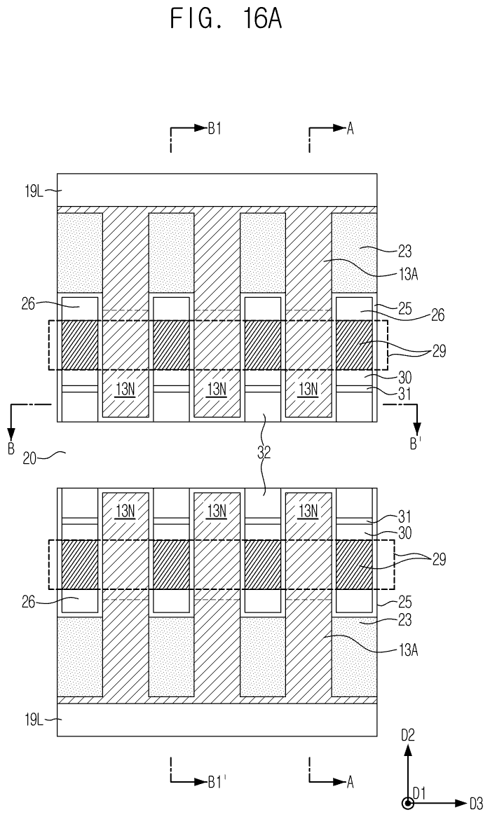

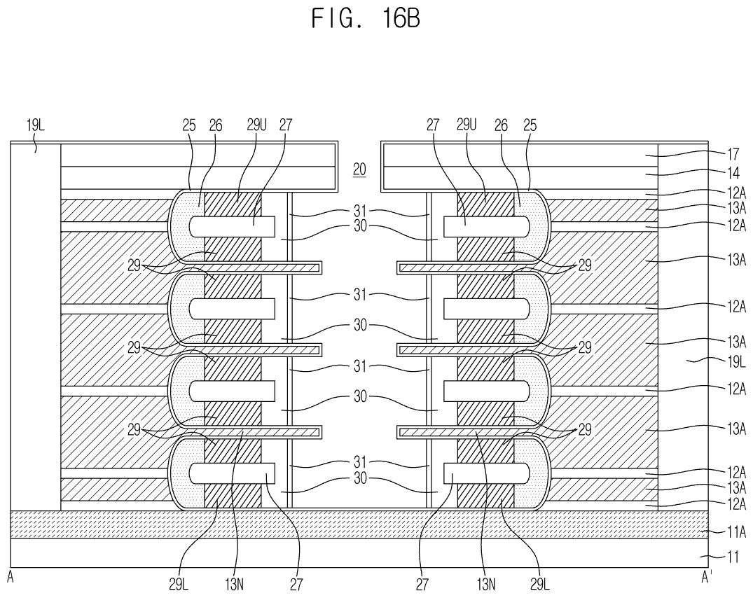

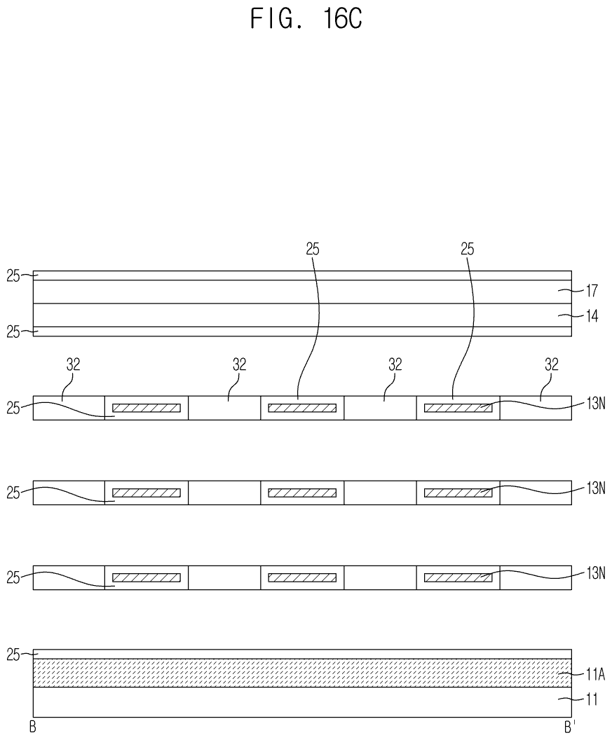

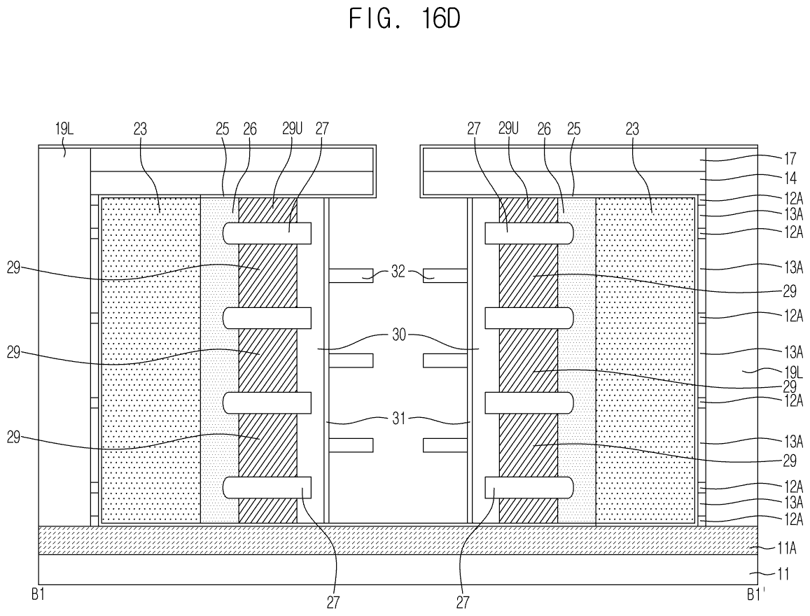

FIG. 16A is a plan view illustrating the structure at the narrow sheet level to describe a method for forming a first sacrificial spacer 32. FIG. 16B is a cross-sectional view of the structure taken along line A-A′ illustrated in FIG. 16A. FIG. 16C is a cross-sectional view of the structure taken along line B-B′ illustrated in FIG. 16A. FIG. 16D is a cross-sectional view of the structure taken along line B1-B1′ illustrated in FIG. 16A.

Referring to FIGS. 16A to 16D, the first sacrificial spacer layer 32A may be cut, and the first sacrificial spacer 32 may be formed between the narrow sheets 13N at the same horizontal level. The first sacrificial spacer 32 may serve to secure a bridge margin while a subsequent sacrificial growth layer is formed.

FIG. 17A is a plan view illustrating the structure at the narrow sheet level to describe a method for forming a second sacrificial spacer 33. FIG. 17B is a cross-sectional view of the structure taken along line A-A′ illustrated in FIG. 17A. FIG. 17C is a cross-sectional view of the structure taken along line B-B′ illustrated in FIG. 17A. FIG. 17D is a cross-sectional view of the structure taken along line B1-B1′ illustrated in FIG. 17A.

Referring to FIGS. 17A to 17D, the second sacrificial spacer 33 may be formed on the first sacrificial spacer 32. The second sacrificial spacer 33 may expose portions of the first sacrificial spacer 32. The second sacrificial spacer 33 may contact the etch stop spacer 31. Subsequently, the first sacrificial spacer 32 may be removed using the second sacrificial spacer 33 as a barrier. Accordingly, inter-sheet gaps 32G may be formed between the narrow sheets 13N at the same horizontal level.

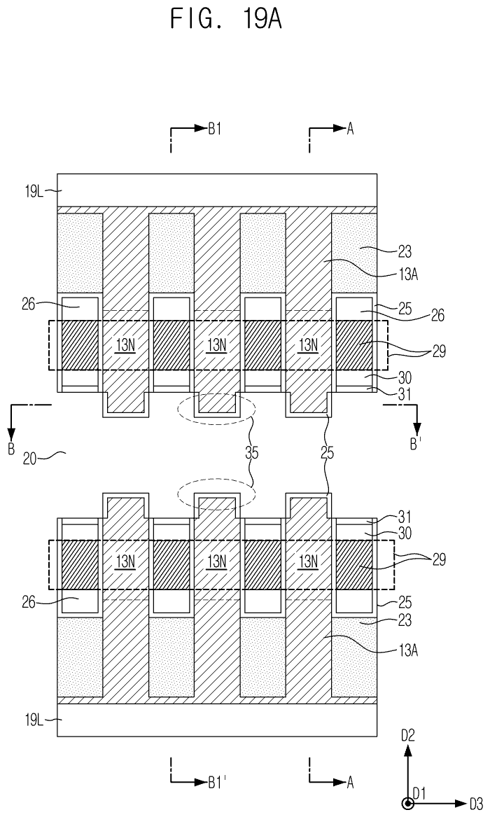

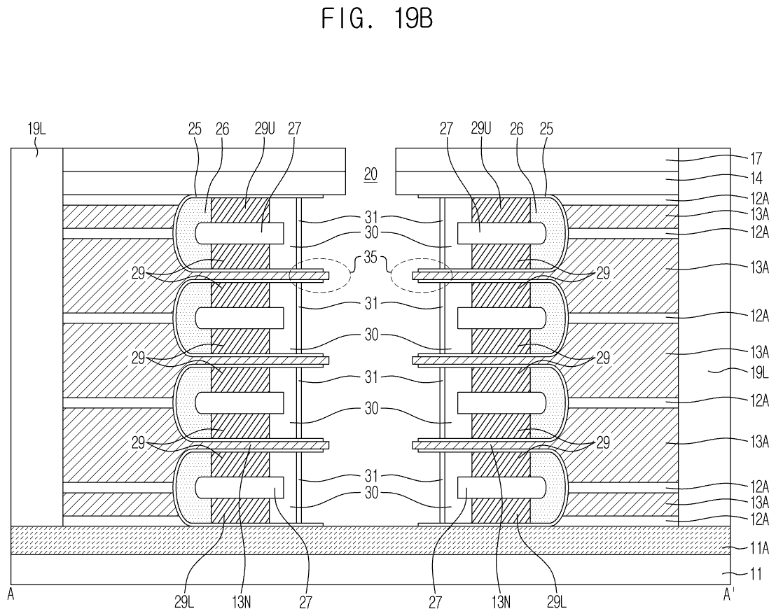

FIG. 18A is a plan view illustrating the structure at the narrow sheet level to describe a method for exposing edges of the narrow sheets 13N. FIG. 18B is a cross-sectional view of the structure taken along line A-A′ illustrated in FIG. 18A. FIG. 18C is a cross-sectional view of the structure taken along line B-B′ illustrated in FIG. 18A.

Referring to FIGS. 18A to 18C, the nano sheet dielectric layer 25 may be recessed using the second sacrificial spacer 33 as a barrier. Accordingly, the edges of the narrow sheets 13N may be exposed, as indicated by reference numeral “34”.

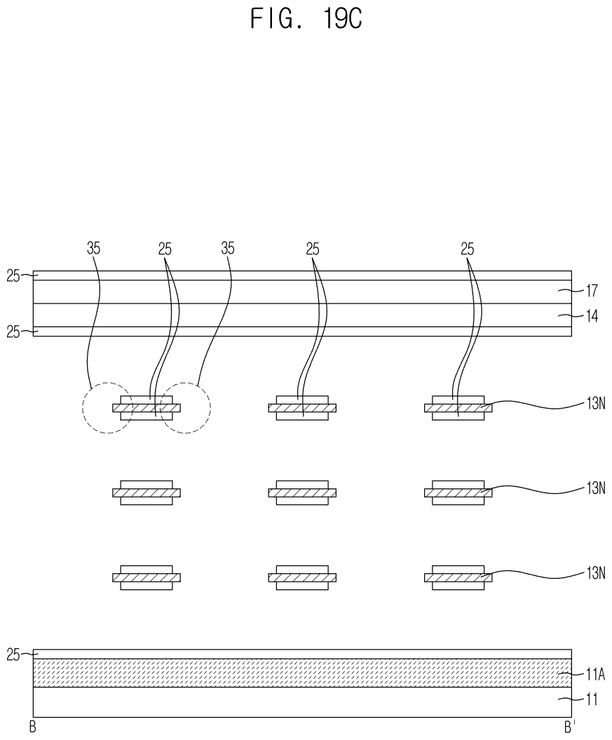

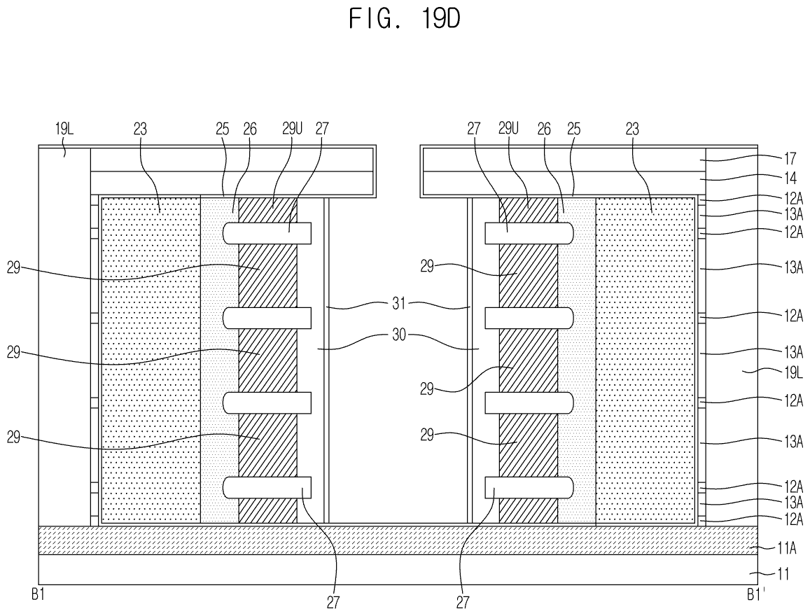

FIG. 19A is a plan view illustrating the structure at the narrow sheet level to describe a method for exposing the edges of the narrow sheets 13N. FIG. 19B is a cross-sectional view of the structure taken along line A-A′ illustrated in FIG. 19A. FIG. 19C is a cross-sectional view of the structure taken along line B-B′ illustrated in FIG. 19A. FIG. 19D is a cross-sectional view of the structure taken along line B1-B1′ illustrated in FIG. 19A.

Referring to FIGS. 19A to 19D, the second sacrificial spacers 33 may be selectively removed. Accordingly, the etch stop spacer 31 may be exposed, and as indicated by reference numeral “35”, the edges of the narrow sheets 13N and portions of the nano sheet dielectric layer 25 may be exposed. The etch stop spacer 31 may serve as an etch barrier while the second sacrificial spacers 33 are removed.

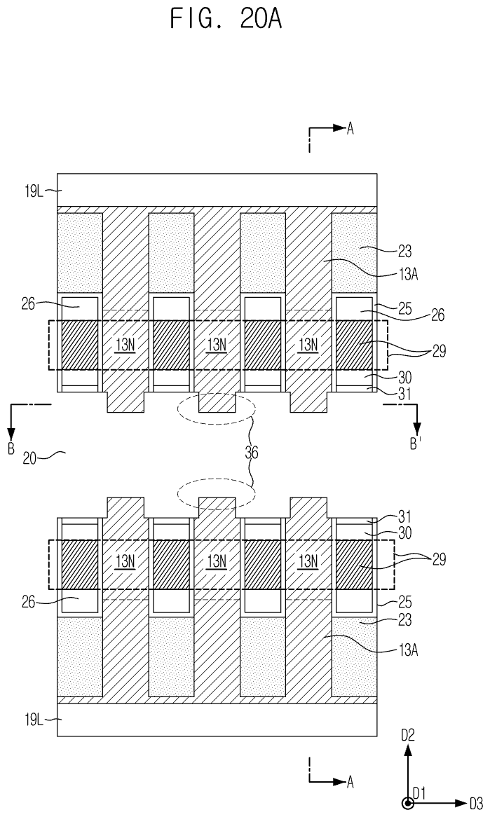

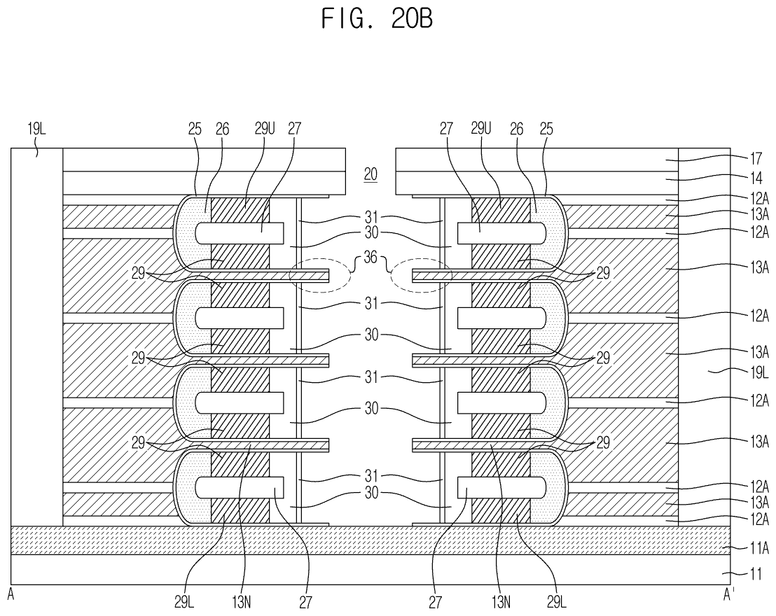

FIG. 20A is a plan view illustrating the structure at the narrow sheet level to describe a method for cutting edges of the narrow sheets 13N. FIG. 20B is a cross-sectional view of the structure taken along line A-A′ illustrated in FIG. 20A. FIG. 20C is a cross-sectional view of the structure taken along line B-B′ illustrated in FIG. 20A.

Referring to FIGS. 20A to 20C, the edges of the narrow sheets 13N may be cut (refer to reference numeral “36”), so that the edges of the narrow sheets 13N are even with edges of nano sheet dielectric layers 25. Horizontal lengths of the narrow sheets 13N in the third direction D3 may therefore be reduced.

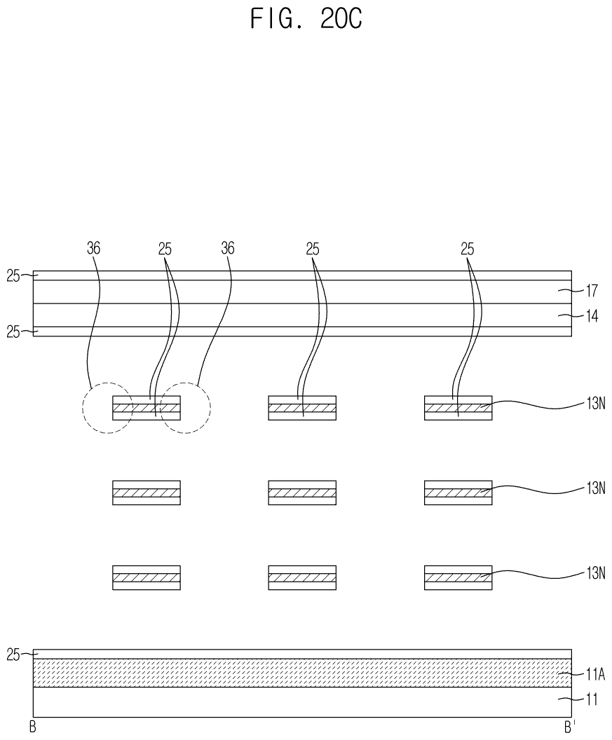

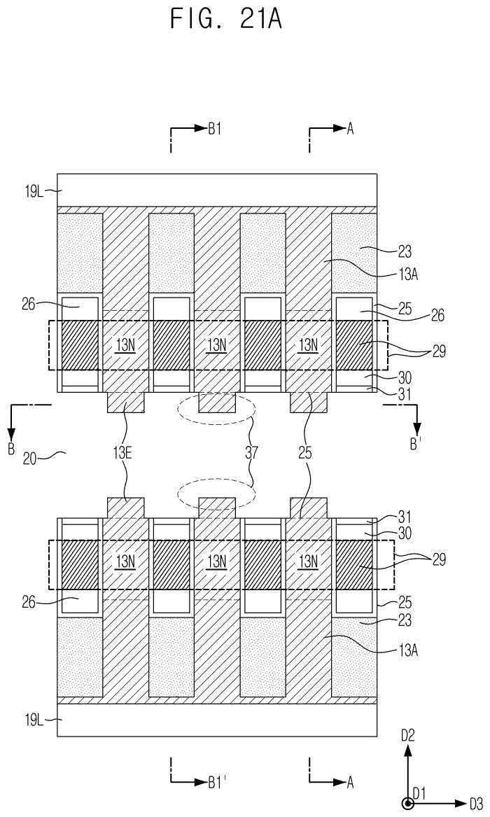

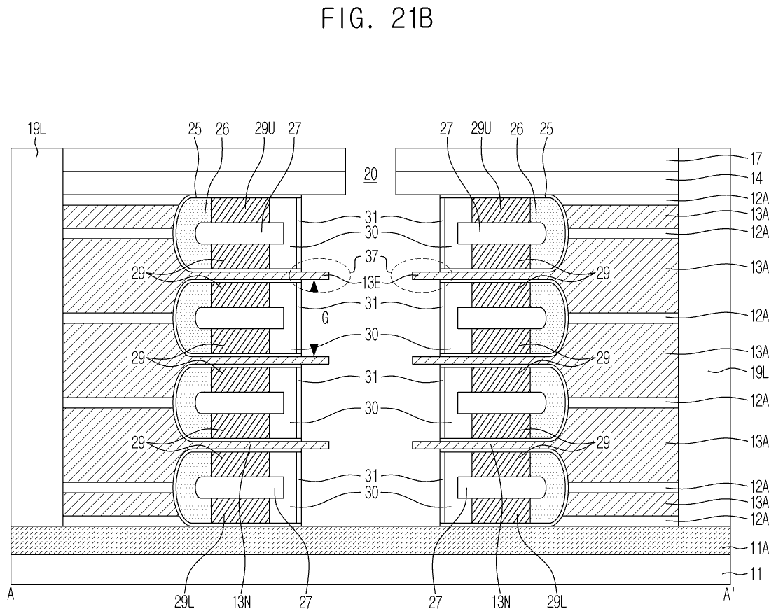

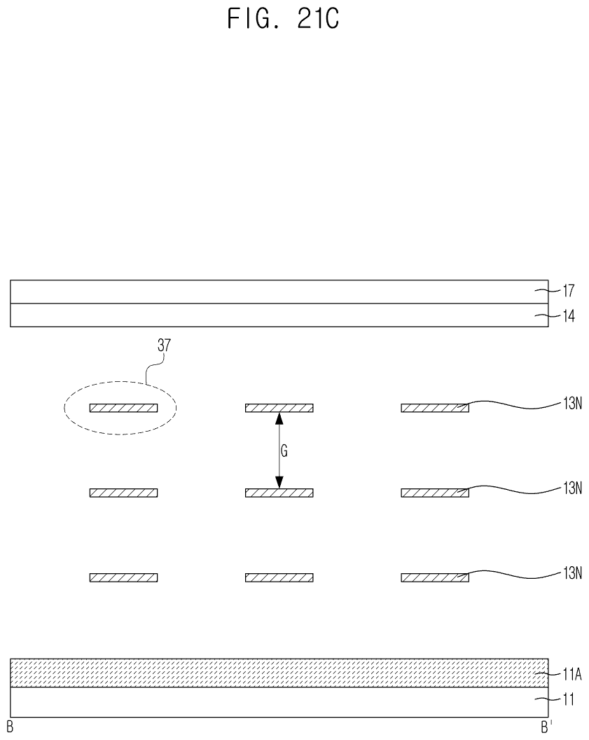

FIG. 21A is a plan view illustrating the structure at the narrow sheet level to describe a method for partially recessing the nano sheet dielectric layer 25. FIG. 21B is a cross-sectional view of the structure taken along line A-A′ illustrated in FIG. 20A. FIG. 21C is a cross-sectional view of the structure taken along line B-B′ illustrated in FIG. 21A.

Referring to FIGS. 21A to 21C, portions of the nano sheet dielectric layer 25 overlapping narrow sheets 13N may be horizontally recessed. Accordingly, edge portions of the narrow sheets 13N, for example, protruding edges 13E of the narrow sheets 13N, may be exposed (refer to reference numeral “37”). The narrow sheets 13N may be vertically spaced apart from each other by a gap G.

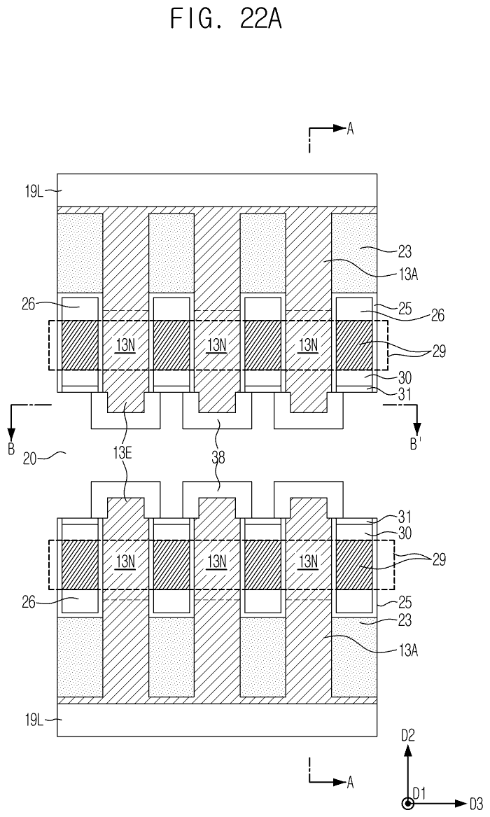

FIG. 22A is a plan view illustrating the structure at the narrow sheet level to describe a method for forming sacrificial growth layers 38. FIG. 22B is a cross-sectional view of the structure taken along line A-A′ illustrated in FIG. 22A. FIG. 22C is a cross-sectional view of the structure taken along line B-B′ illustrated in FIG. 22A.

Referring to FIGS. 22A to 22C, the sacrificial growth layers 38 may be formed on the protruding edges 13E of the narrow sheets 13N. The sacrificial growth layers 38 may be formed by selective epitaxial growth (SEG). The sacrificial growth layers 38 may cover all surfaces of protruding edges 13E of the narrow sheets 13N. The sacrificial growth layers 38 may each have a geometrical shape, e.g., a pyramidal shape. The sacrificial growth layers 38 may each include a silicon germanium epitaxial layer. The sacrificial growth layers 38 may include convex profiles 38A, and voids 38B may be formed between the sacrificial growth layers 38 that are disposed vertically.

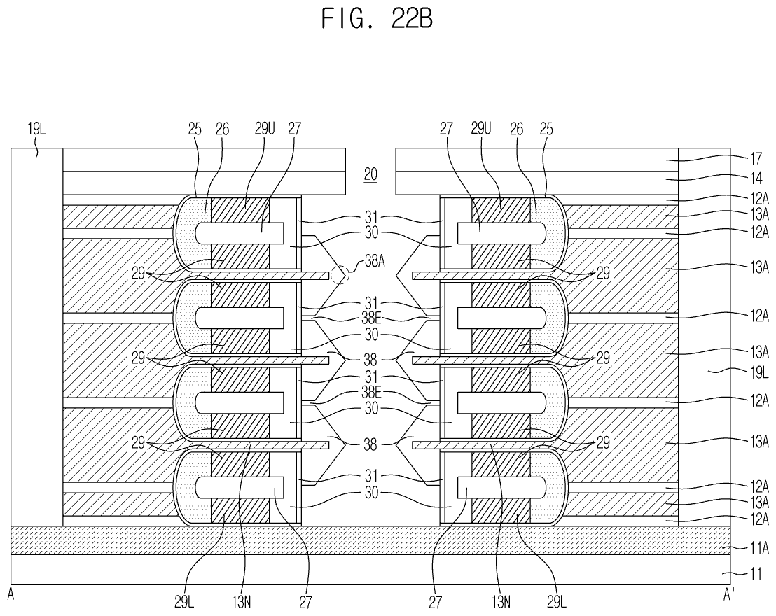

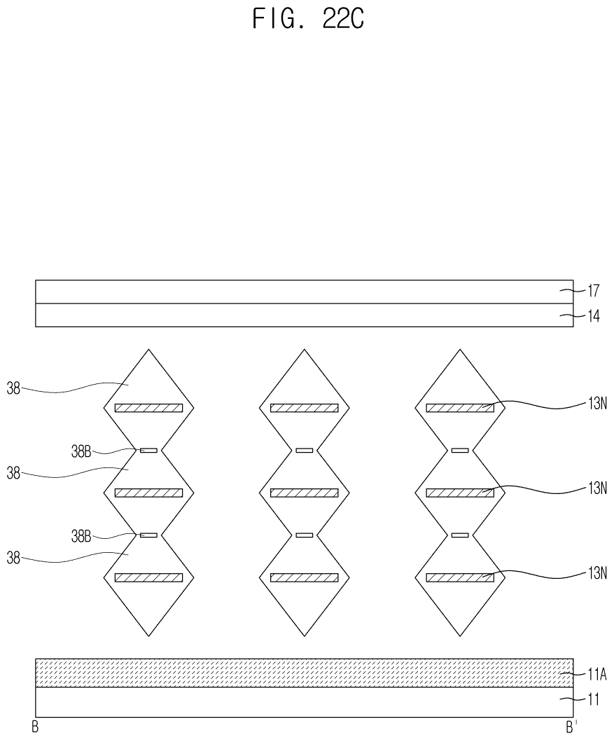

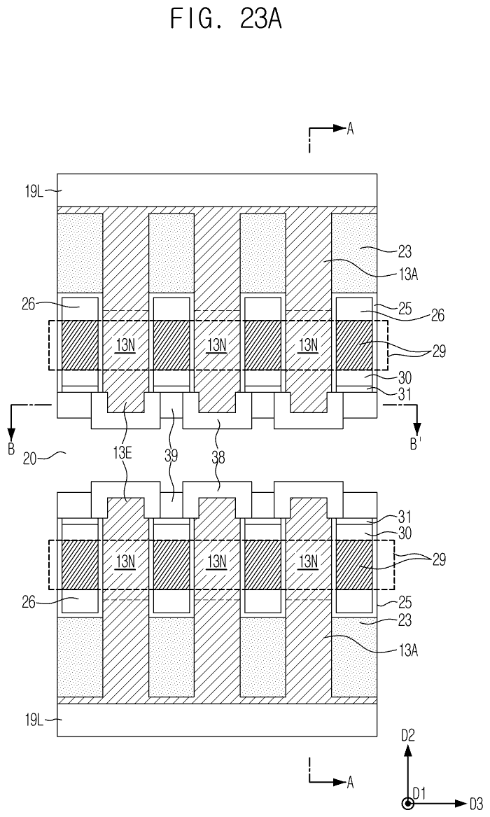

FIG. 23A is a plan view illustrating the structure at the narrow sheet level to describe a method for forming supporters 39. FIG. 23B is a cross-sectional view of the structure taken along line A-A′ illustrated in FIG. 23A. FIG. 23C is a cross-sectional view of the structure taken along line B-B′ illustrated in FIG. 23A.

Referring to FIGS. 23A to 23C, deposition and etch processes of a support material may be performed on the sacrificial growth layers 38. Accordingly, supporters 39 for supporting the sacrificial growth layers 38 may be formed. The supporters 39 may be disposed adjacent to each other and may be spaced apart from each other in the second direction D2. The supporters 39 may each include a dielectric material. For example, the supporters 39 may each include silicon nitride. The supporters 39 may have an integral structure of supporting the sacrificial growth layers 38. The supporters 39 may include void fillers 39A filling the voids 38B formed between the sacrificial growth layers 38. The supporters 39 may expose the convex profiles 38A of the sacrificial growth layers 38.

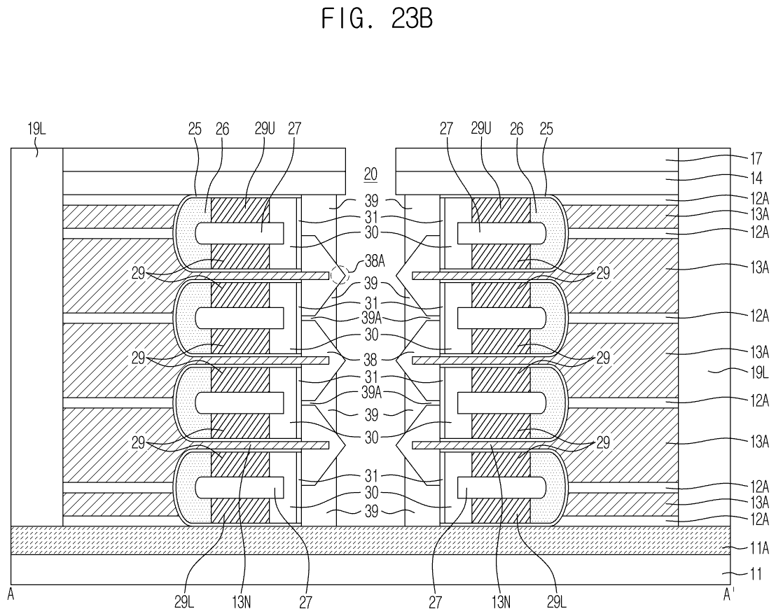

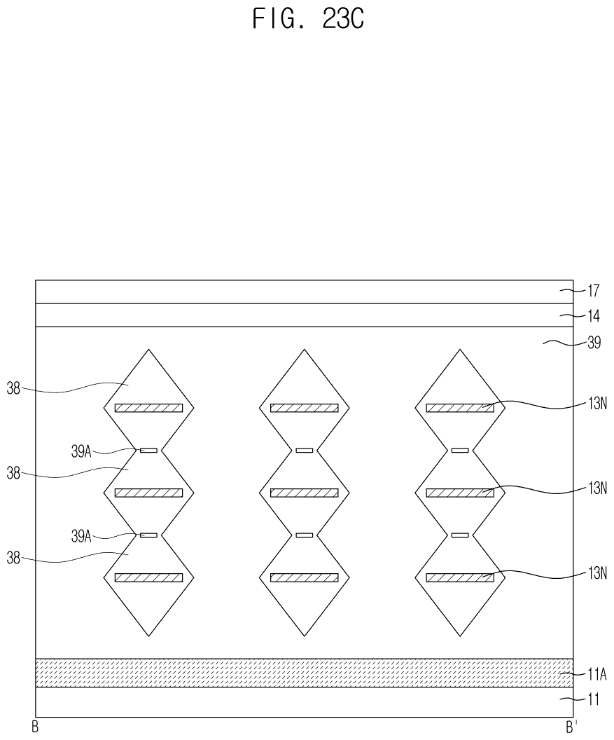

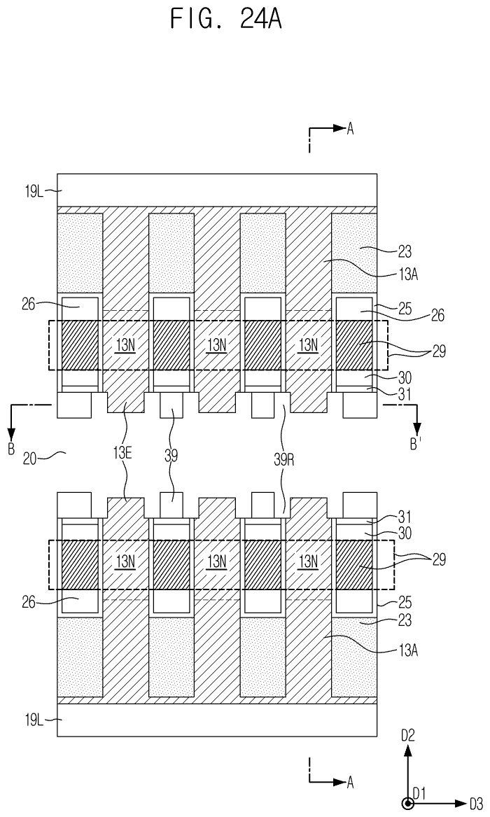

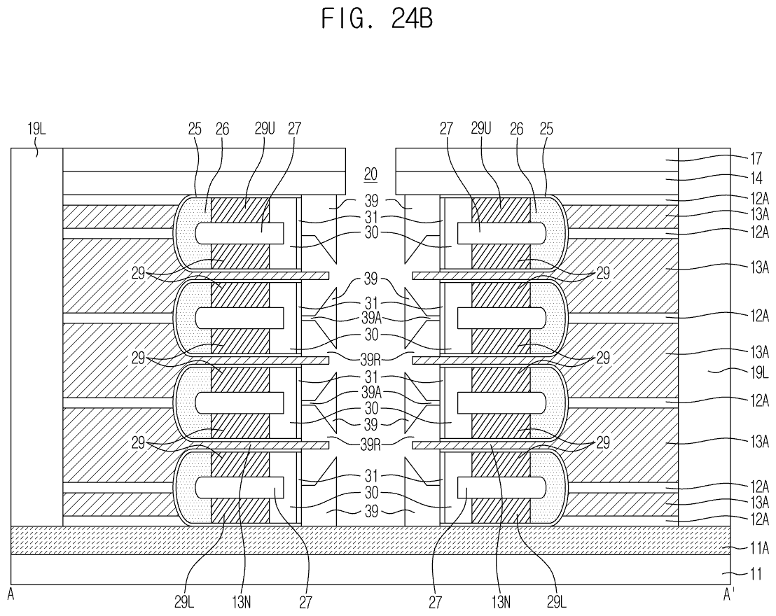

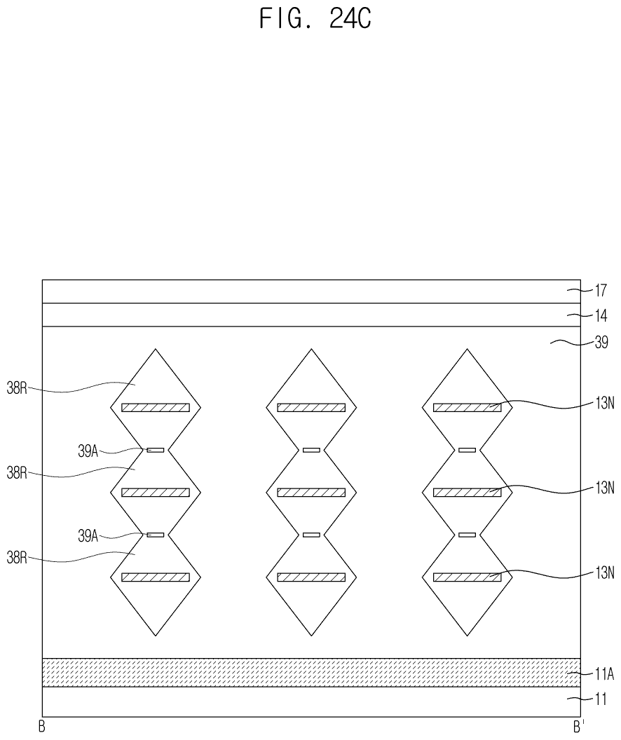

FIG. 24A is a plan view illustrating the structure at the narrow sheet level to describe a method for forming initial supporter recesses 39R. FIG. 24B is a cross-sectional view of the structure taken along line A-A′ illustrated in FIG. 24A. FIG. 24C is a cross-sectional view of the structure taken along line B-B′ illustrated in FIG. 24A.

Referring to FIGS. 24A to 24C, the sacrificial growth layers 38 may be removed to form the initial supporter recesses 39R. The initial supporter recesses 39R may vertically extend in the first direction D1 and be spaced apart from each other in the second direction D2. The initial supporter recesses 39R may expose the protruding edges 13E of the narrow sheets 13N disposed vertically. The void fillers 39A may be exposed by the initial supporter recesses 39R.

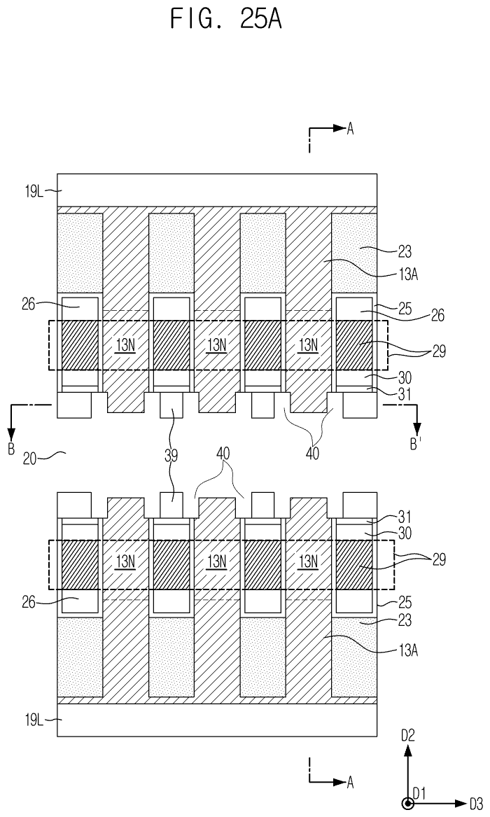

FIG. 25A is a plan view illustrating the structure at the narrow sheet level to describe a method for removing the void fillers 39A. FIG. 25B is a cross-sectional view of the structure taken along line A-A′ illustrated in FIG. 25A. FIG. 25C is a cross-sectional view of the structure taken along line B-B′ illustrated in FIG. 25A.

Referring to FIGS. 25A to 25C, the void fillers 39A may be removed through the initial supporter recesses 39R. The volume of the initial supporter recesses 39R may be expanded while the void fillers 39A are removed. The expanded initial supporter recesses may become supporter recesses 40. The supporter recesses 40 may vertically extend in the first direction D1 and be spaced apart from each other in the second direction D2. The supporter recesses 40 may expose the protruding edges 13E of the narrow sheets 13N disposed vertically.

FIG. 26A is a plan view illustrating the structure at the narrow sheet level to describe a method for cutting the edges of the narrow sheets 13N. FIG. 26B is a cross-sectional view of the structure taken along line A-A′ illustrated in FIG. 26A. FIG. 26C is a cross-sectional view of the structure taken along line B-B′ illustrated in FIG. 26A.

Referring to FIGS. 26A to 26C, the protruding edges 13E of the narrow sheets 13N may be cut through the supporter recesses 40. Accordingly, the protruding edges 13E of the narrow sheets 13N may not be disposed in the supporter recesses 40. The supporter recesses 40 may have a structure in which pyramid-shaped recesses are merged.

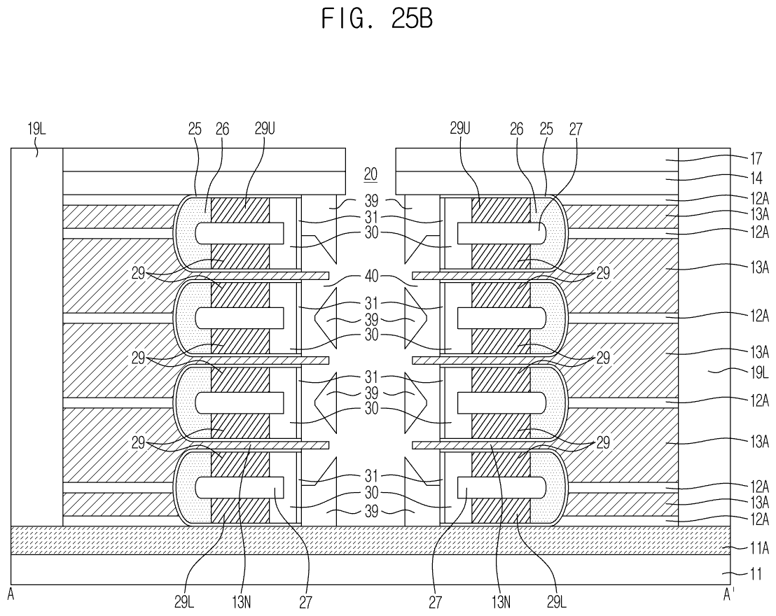

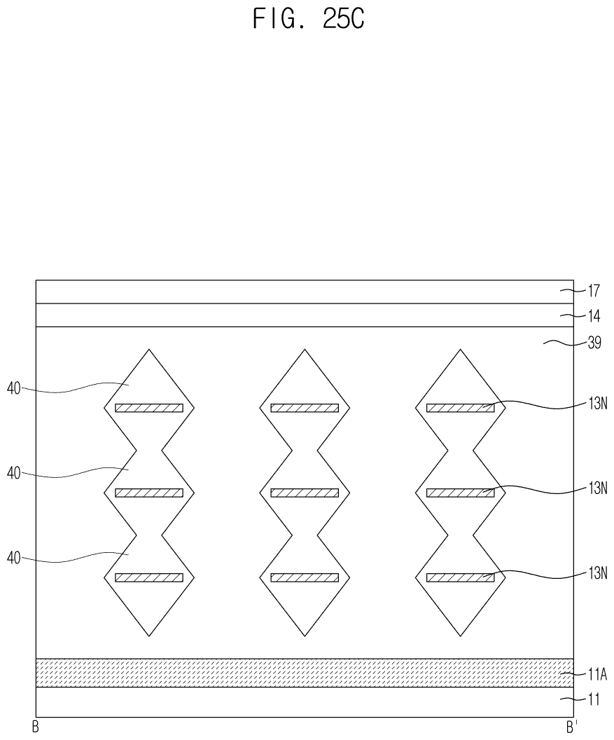

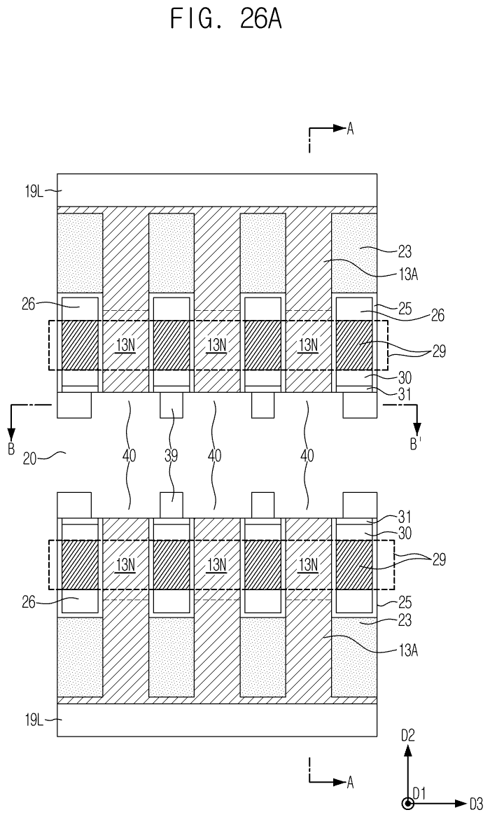

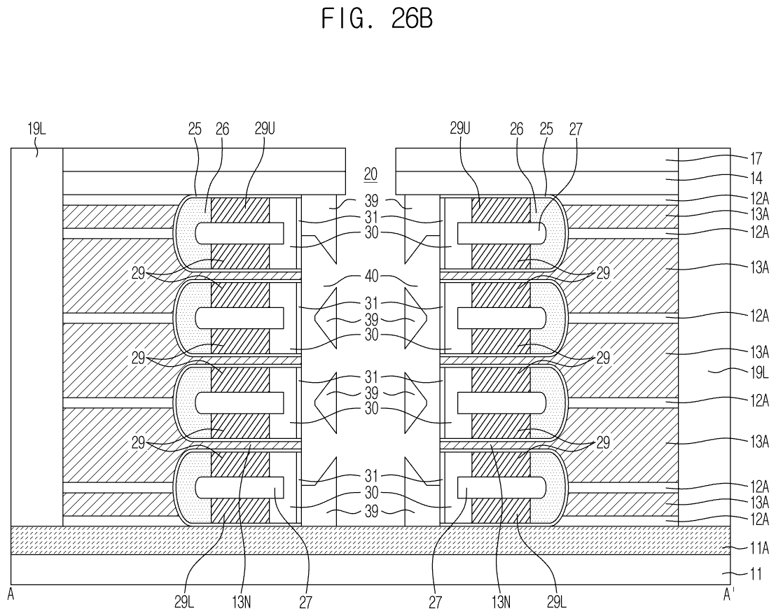

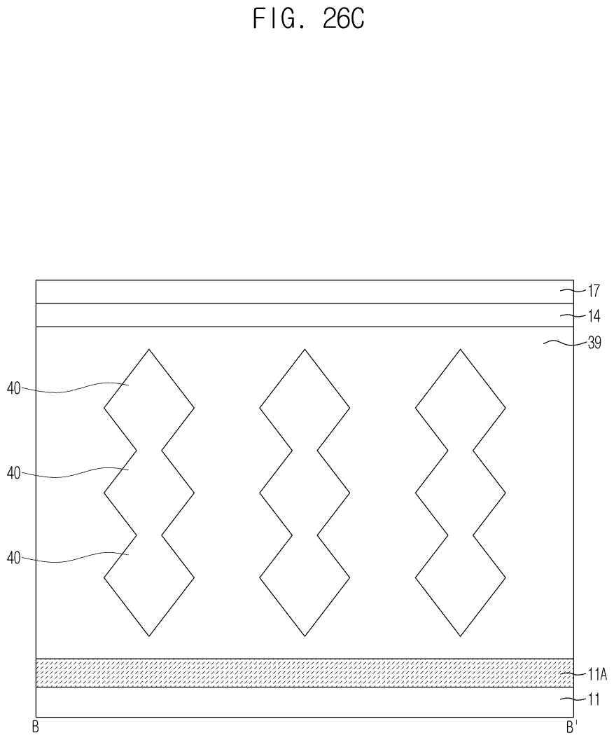

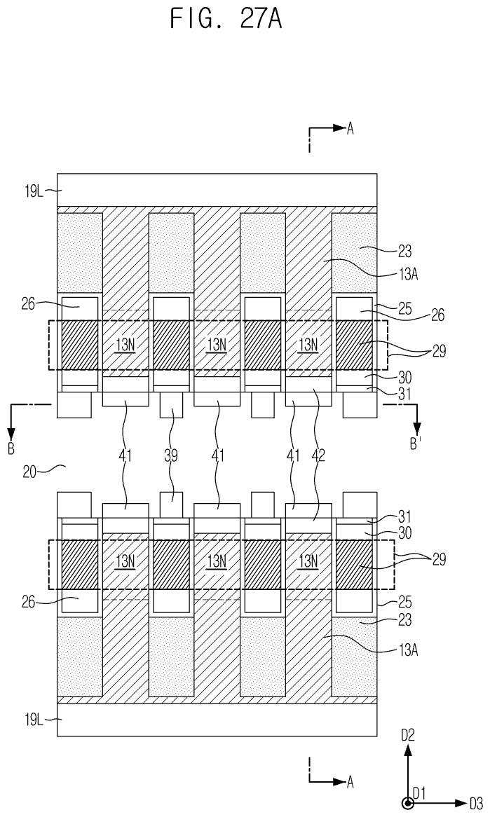

FIG. 27A is a plan view illustrating the structure at the narrow sheet level to describe a method for forming first contact nodes 41, e.g., first contact node BLC shown in FIG. 1B. FIG. 27B is a cross-sectional view illustrating the structure taken along line A-A′ illustrated in FIG. 27A. FIG. 27C is a cross-sectional view of the structure taken along line B-B′ illustrated in FIG. 27A.

Referring to FIGS. 27A to 27C, the first contact nodes 41 may be formed on one side surface of each of the narrow sheets 13N. Forming the first contact nodes 41 may include selective epitaxial growth (SEG). For example, a semiconductive material may be grown from the narrow sheets 13N through the selective epitaxial growth (SEG). The first contact nodes 41 may each include SEG Si. Because the narrow sheets 13N each include monocrystalline silicon, a silicon layer may be epitaxially grown along crystal surfaces of the side surfaces of the narrow sheets 13N. The first contact nodes 41 may be formed on the narrow sheets 13N in the supporter recesses 40. The first contact nodes 41 may each have a pyramid shape. The first contact nodes 41 may be spaced apart from each other so that no short occurs between adjacent memory cells.

The first contact nodes 41 may each include a dopant. When a silicon layer is grown using the selective epitaxial growth (SEG), dopants may be doped in situ. Accordingly, the first contact nodes 41 may each be a doped epitaxial layer. The first contact nodes 41 may each include an N-type dopant as the dopant. The N-type dopant may include phosphorus, arsenic, antimony, or a combination thereof. The first contact nodes 41 may include a phosphorus-doped silicon epitaxial layer formed by the selective epitaxial growth (SEG), i.e., a doped SEG SiP.

Each of first doped regions 42 may be formed in one side of each of the narrow sheets 13N. A heat treatment process may be performed to form the first doped regions 42, and thus dopants may be diffused from the first contact nodes 41.

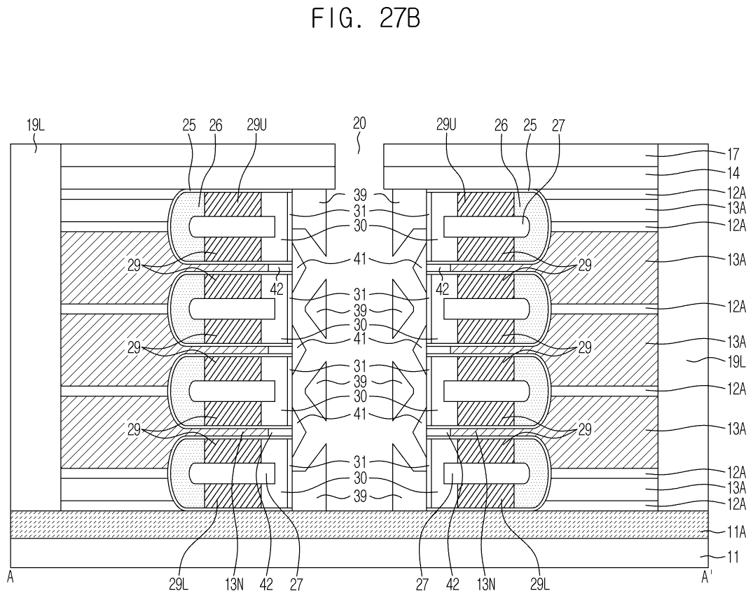

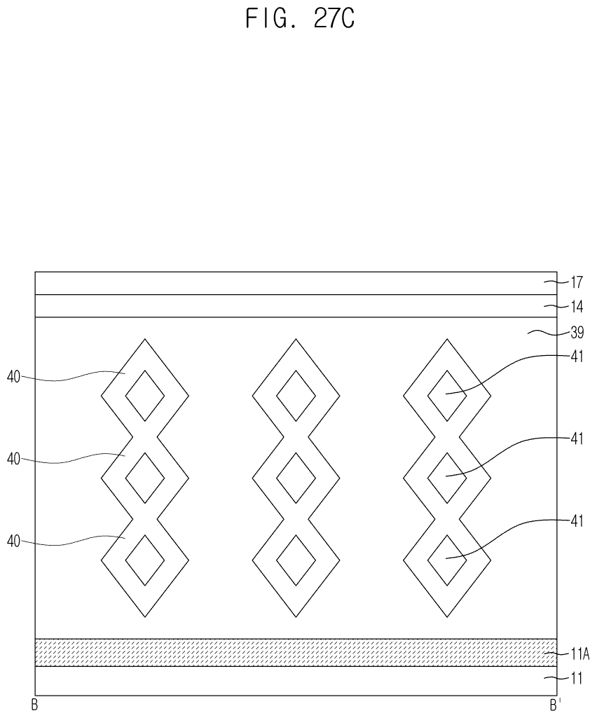

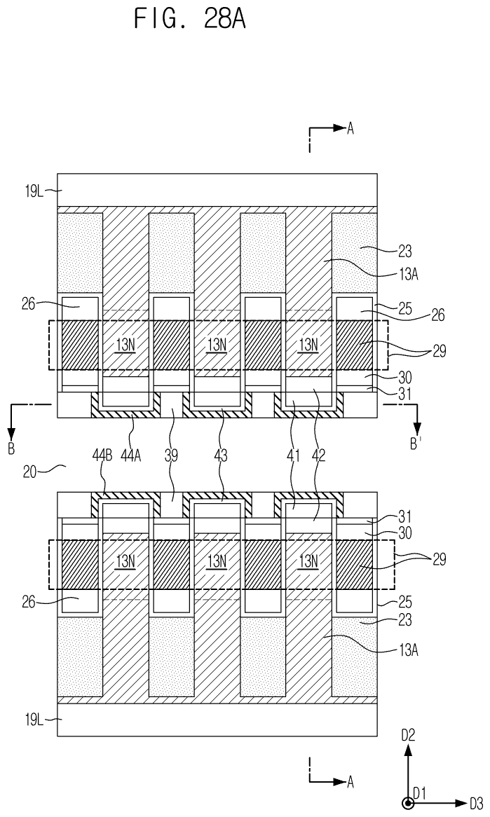

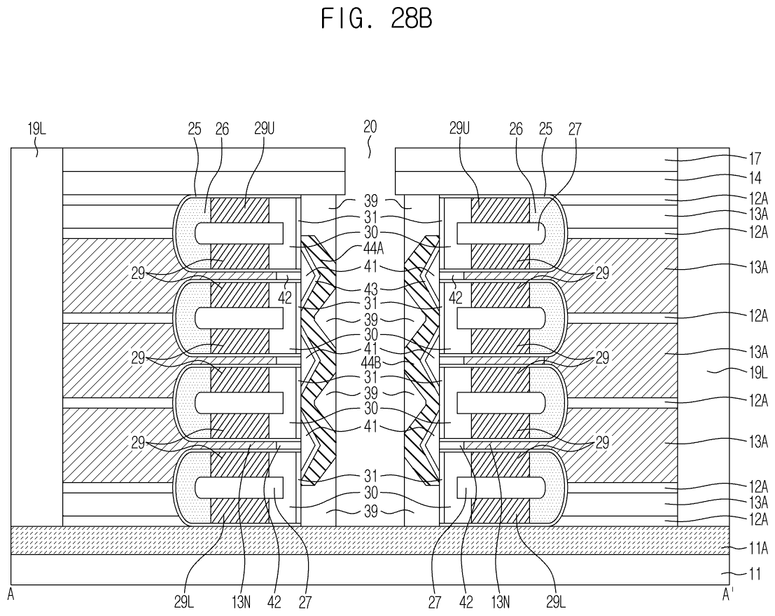

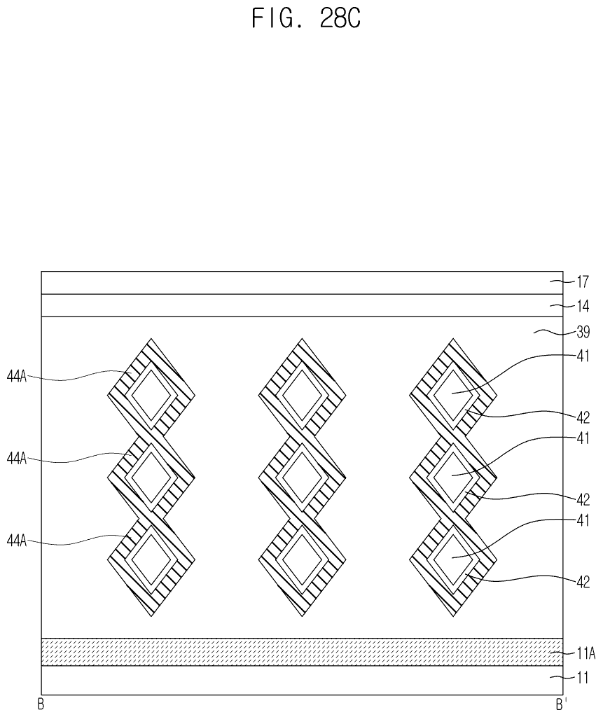

FIG. 28A is a plan view illustrating the structure at the narrow sheet level to describe a method for forming vertical conductive lines 44A and 44B. FIG. 28B is a cross-sectional view illustrating the structure taken along line A-A′ illustrated in FIG. 28A. FIG. 28C is a cross-sectional view of the structure taken along line B-B′ illustrated in FIG. 28A.

Referring to FIGS. 28A to 28C, ohmic contact layers 43 may be formed on the first contact nodes 41 (see also FIG. 27B). The ohmic contact layers 43 may each include metal silicide. Forming the ohmic contact layers 43 may include depositing a metal-based layer on the first contact nodes 41 and performing a heat treatment process for a silicide reaction of the metal-based layer and the first contact nodes 41. The ohmic contact layers 43 may have a pyramid shape conformally surrounding the first contact nodes 41.

Subsequently, the vertical conductive lines 44A and 44B may be formed on the ohmic contact layers 43. The vertical conductive lines may be used to form the first conductive (bit) lines BL (e.g., see FIG. 1B) and may include a first vertical conductive line 44A and a second vertical conductive line 44B that are horizontally spaced apart from each other. The first and second vertical conductive lines 44A and 44B may be coupled in common to the first contact nodes 41 through the ohmic contact layers 43. The first and second vertical conductive lines 44A and 44B may be coupled in common to the narrow sheets 13N disposed in the first direction D1. The first and second vertical conductive lines 44A and 44B may vertically extend in the first direction D1. The first and second vertical conductive lines 44A and 44B may each include a metal-based material. The first and second vertical conductive lines 44A and 44B may each include titanium nitride, tungsten, or a combination thereof.

Deposition and blanket etch-back processes may be performed on a vertical conductive line material to form the first and second vertical conductive lines 44A and 44B.

Bottom portions of the first and second vertical conductive lines 44A and 44B may contact the stopper layer 11A. A bridge between the substrate 11 and the first and second vertical conductive lines 44A and 44B may be prevented by the stopper layer 11A. The bottom portions of the first and second vertical conductive lines 44A and 44B may be mutually discontinuous. The first and second vertical conductive lines 44A and 44B may fill the supporter recesses 40 while covering the ohmic contact layers 43.

The supporters 39 may surround the first and second vertical conductive lines 44A and 44B.

As described above, the supporters 39 may include the supporter recesses 40. The first contact nodes 41, the ohmic contact layers 43 and the first and second vertical conductive lines 44A and 44B may fill the supporter recesses 40. The pyramid-shaped first contact nodes 41 may be electrically coupled to the narrow sheets 13N, and the ohmic contact layers 43 may surround the first contact nodes 41.

The first and second vertical conductive lines 44A and 44B may include a combination of pyramid-shaped convex portions. The pyramid-shaped convex portions of the first and second vertical conductive lines 44A and 44B may surround the first contact nodes 41. The ohmic contact layers 43 may be disposed between the pyramid-shaped convex portions of the first and second vertical conductive lines 44A and 44B and the first contact nodes 41. The first vertical conductive lines 44A disposed adjacent to each other in the third direction D3 may be spaced apart from each other by the supporter 39. The second vertical conductive lines 44B disposed adjacent to each other in the third direction D3 may be spaced apart from each other by the supporter 39.

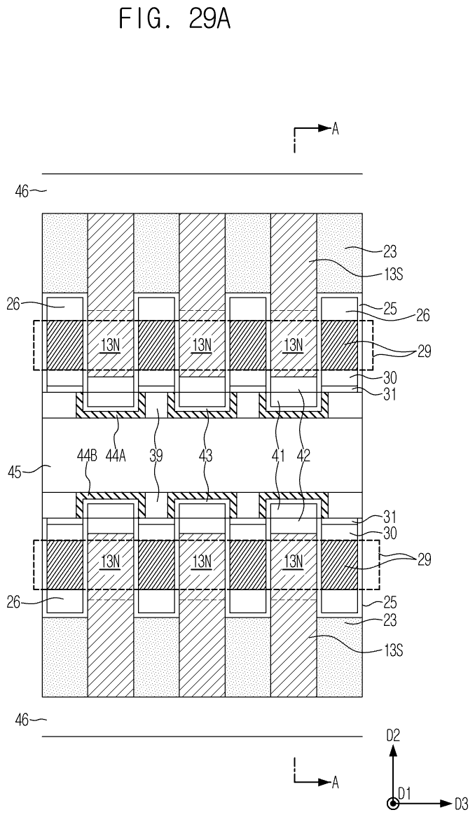

FIG. 29A is a plan view illustrating the structure at the narrow sheet level to describe a method for forming second linear openings 46. FIG. 29B is a cross-sectional view of the structure taken along line A-A′ illustrated in FIG. 29A.

Referring to FIGS. 29A and 29B, an inter-array dielectric layer 45 may be formed to fill the first linear opening 20 on the first and second vertical conductive lines 44A and 44B. The inter-array dielectric layer 45 may vertically extend in the first direction D1 and horizontally extend in the third direction D3. The first and second vertical conductive lines 44A and 44B disposed adjacent to each other in the second direction D2 may be isolated by the inter-array dielectric layer 45. The inter-array dielectric layer 45 may include a dielectric material. The inter-array dielectric layer 45 may include silicon oxide, silicon nitride, an air gap, or a combination thereof.

Subsequently, the second linear sacrificial layer 19L may be removed. Accordingly, the second linear openings 46 may be formed.

After the second linear openings 46 are formed, the first mold layers 12A may be selectively recessed through the second linear openings 46. A difference in etch selectivity between the first mold layers 12A and the original body portions 13A may be used to selectively recess the first mold layers 12A. The first mold layers 12A may be removed using a wet etch process or a dry etch process. For example, when the first mold layers 12A include silicon germanium layers and the original body portions 13A include monocrystalline silicon layers, the silicon germanium layers may be etched using an etchant or etch gas having a selectivity with respect to the monocrystalline silicon layers.

Subsequently, the original body portions 13A may be recessed. The wet etch process or the dry etch process may be used to recess the original body portions 13A. Vertical thicknesses of the original body portions 13A may be reduced, as indicated by reference numeral “13S”. Hereinafter, the original body portions having the reduced vertical thicknesses are referred to as “recessed body portions 13S”.

Each of inter-body recesses 47 may be formed between the recessed body portions 13S that are vertically disposed.

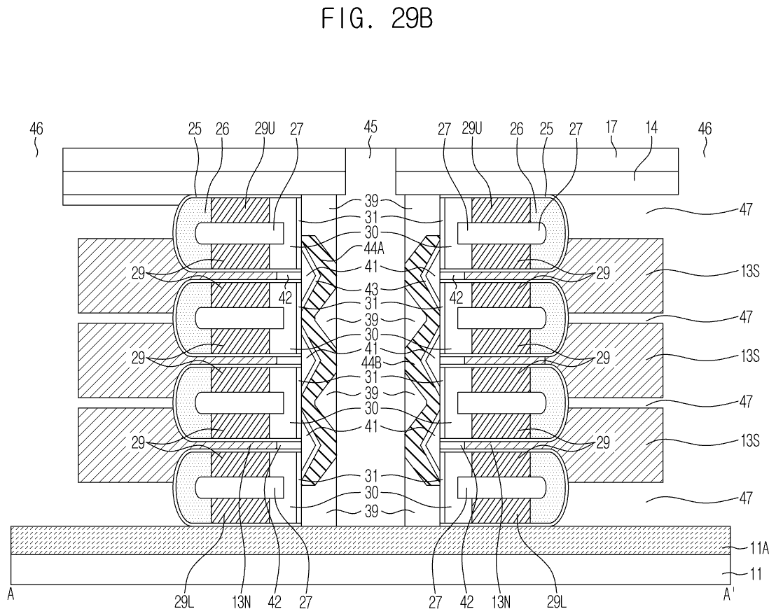

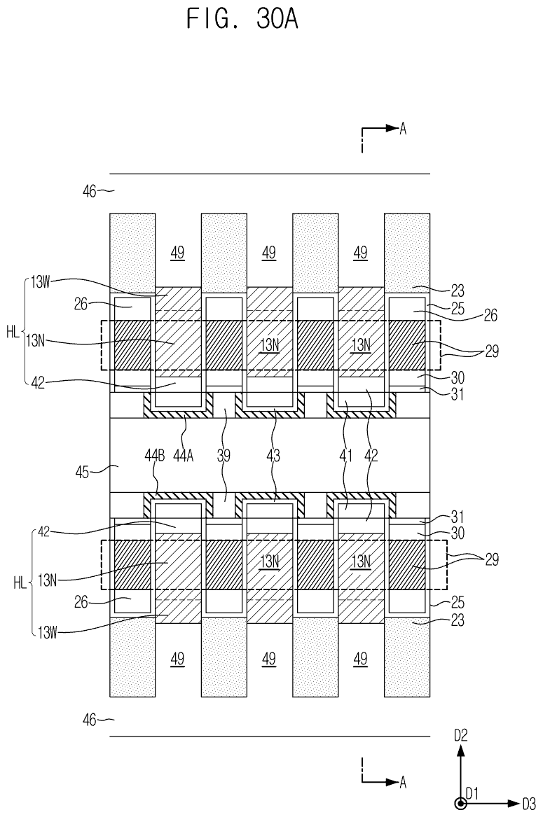

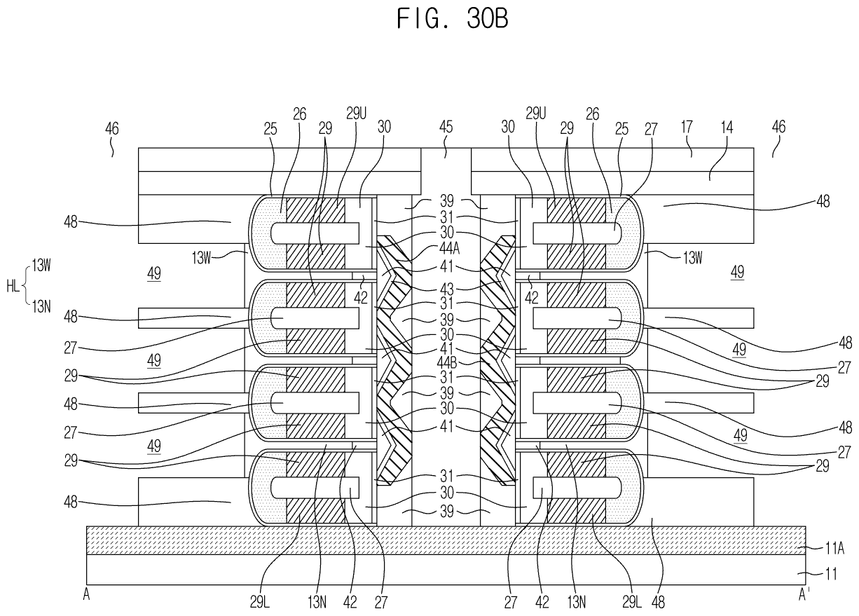

FIG. 30A is a plan view illustrating the structure at the narrow sheet level to describe a method for forming nano sheets HL. FIG. 30B is a cross-sectional view of the structure taken along line A-A′ illustrated in FIG. 30A.

Referring to FIGS. 30A and 30B, third inter-cell dielectric layers 48 may be formed to fill the inter-body recesses 47. The third inter-cell dielectric layers 48 may each include silicon oxide.

After the third inter-cell dielectric layers 48 are formed, storage openings 49 may be formed by horizontal recessing of the recessed body portions 13S. The storage openings 49 may be referred to as “capacitor openings”, into which the data storage element CAP may be formed, as shown, for example, in FIG. 1B. The nano sheets HL may be formed by the horizontal recessing of the recessed body portions 13S.

Each of the nano sheets HL may include the narrow sheet 13N and a wide sheet 13W, as shown in FIG. 1B. The wide sheet 13W of the nano sheet HL may refer to the recessed body portion 13S remaining after the recessing. An average vertical height of the wide sheet 13W of the nano sheet HL in the first direction D1 may be greater than an average vertical height of the narrow sheet 13N. A thickness of the wide sheet 13W of the nano sheet HL may gradually increase in the second direction D2. A horizontal length of the wide sheet 13W in the second direction D2 may be less than a horizontal length of the narrow sheet 13N. The wide sheet 13W of the nano sheet HL may have a fan-like shape. The wide sheet 13W may be referred to as a “fan-shaped sheet”, and the narrow sheet 13N may be referred to as a “flat plate-shaped sheet”.

To form each of the nano sheets HL to include the wide sheet 13W, the recessed body portions 13S may be isotropically or anisotropically etched. One side of the wide sheet 13W, i.e., the side exposed by each of the storage openings 49, may have a flat shape. The one side of the wide sheet 13W may have various shapes.

Each of the nano sheets HL may include a first edge and a second edge. The first edge may refer to a portion electrically coupled to the first and second vertical conductive lines 44A and 44B, the first contact node 41 and the ohmic contact layer 43, and the second edge may refer to a portion exposed by each of the storage openings 49.

Each of the storage openings 49 may be disposed between the third inter-cell dielectric layers 48.

In some embodiments, the horizontal recessing of the recessed body portions 13S for forming the wide sheets 13W may stop at a boundary area between the narrow sheet 13N and the wide sheet 13W.

Referring to FIGS. 5A to 30B, the narrow sheets 13N may be formed by recessing the first portions of the second mold layers 13, and the wide sheets 13W may be formed by recessing the second portions of the second mold layers 13. The wide sheets 13W may be horizontally continuous from the narrow sheets 13N.

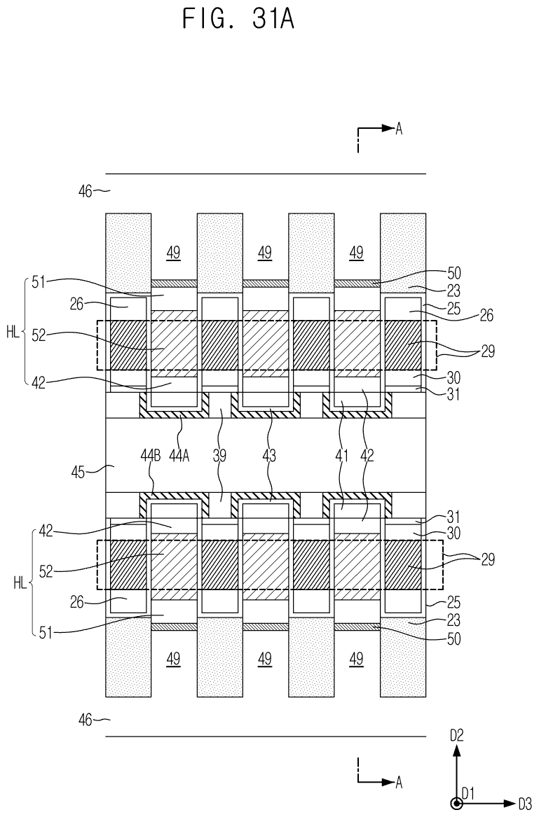

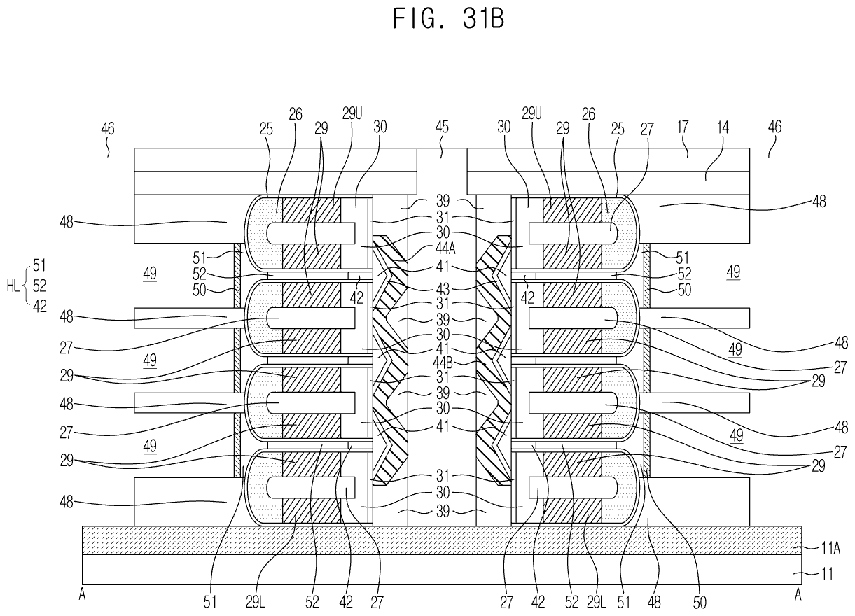

FIG. 31A is a plan view illustrating the structure at a nano sheet level to describe a method for forming second contact nodes 50, e.g., second contact node SNC in FIG. 1B. FIG. 31B is a cross-sectional view of the structure taken along line A-A′ illustrated in FIG. 31A.

Referring to FIGS. 31A and 31B, a pre-cleaning process may be performed on one side of each of the nano sheets HL, that is, the surface of each of the wide sheets 13W.

Subsequently, the second contact nodes 50 may be formed on one side of the nano sheets HL, that is, the wide sheets 13W. Forming the second contact nodes 50 may include selective epitaxial growth (SEG). For example, a semiconductor material may be grown from the side surfaces of the wide sheets 13W through the selective epitaxial growth (SEG). The second contact nodes 50 may each include SEG Si. Because the wide sheets 13W each include monocrystalline silicon, a silicon layer may be epitaxially grown along crystal surfaces of the side surfaces of the wide sheets 13W.

The second contact nodes 50 may each include a dopant. When the silicon layer is grown using the selective epitaxial growth (SEG), dopants may be doped in situ. Accordingly, the second contact nodes 50 may each be a doped epitaxial layer. The second contact nodes 50 may each include an N-type dopant as the dopant. The N-type dopant may include phosphorus, arsenic, antimony, or a combination thereof. The second contact nodes 50 may include a phosphorus-doped silicon epitaxial layer formed by the selective epitaxial growth (SEG), i.e., a doped SEG SiP.

Because the second contact nodes 50 are formed using the selective epitaxial growth (SEG), void-free or seam-free second contact nodes 50 may be formed. Because the second contact nodes 50 are formed using the selective epitaxial growth (SEG), a process for forming the second contact nodes 50 may be simplified.

Each of the second contact nodes 50 may be disposed between the third inter-cell dielectric layers 48 that are vertically stacked.

Second doped (source/drain) regions 51 may be formed in the wide sheets 13W of the nano sheets HL. A heat treatment process may be performed to form the second doped regions 51, and thus dopants may be diffused from the second contact nodes 50.

Each of the nano sheets HL may include the first doped region 42, the second doped region 51, and a channel 52, e.g., first doped region SR, second doped region DR, and channel CH in FIG. 1B. The channel 52 may be defined between the first doped region 42 and the second doped region 51. The first doped region 42 and the channel 52 may be formed in each of the narrow sheets 13N, and the second doped region 51 may be formed in each of the wide sheets 13W. A portion of each of the second doped regions 51 may extend into the narrow sheet 13N. One side of each of the second doped regions 51 of the nano sheets HL may be coupled to the channel 52, and the other side of each of the second doped regions 51 of the nano sheets HL may be coupled to the second contact node 50.

In some embodiments, an ohmic contact layer including metal silicide may be further formed after the second contact nodes 50 are formed.

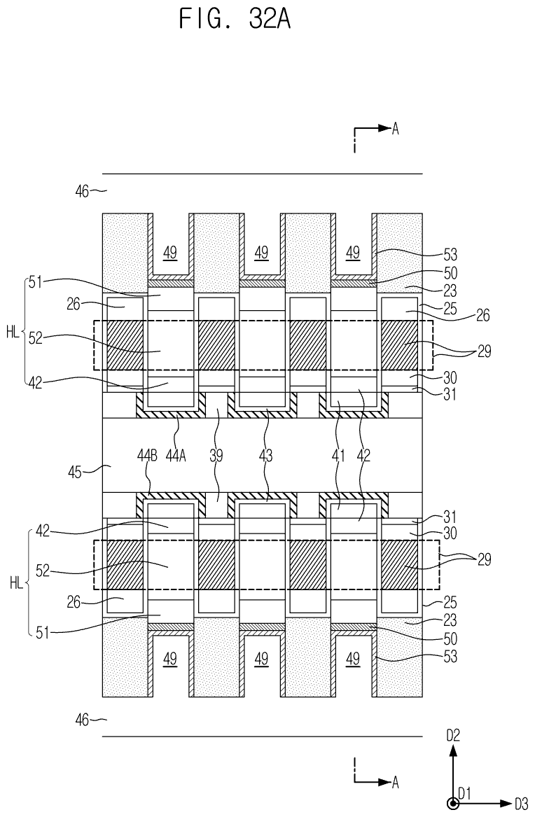

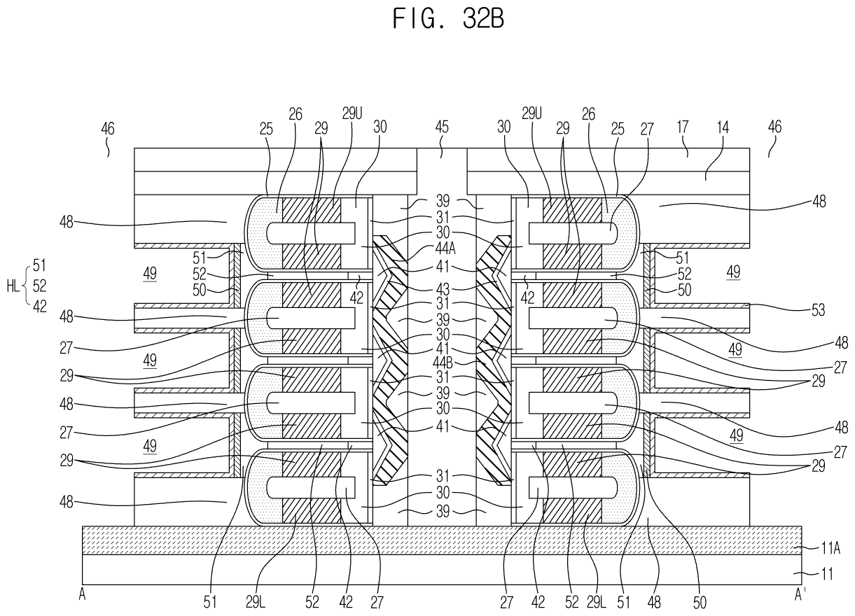

FIG. 32A is a plan view illustrating the structure at the nano sheet level to describe a method for forming first electrodes 53 of the data storage element CAP. FIG. 32B is a cross-sectional view of the structure taken along line A-A′ illustrated in FIG. 32A.

Referring to FIGS. 32A and 32B, the first electrodes 53 of the data storage element CAP (e.g., see FIG. 1B) may be formed on the second contact nodes 50. The first electrodes 53 may each have, for example, a horizontally-oriented cylindrical shape. Each of the first electrodes 53 may be disposed in a corresponding one of the storage openings 49. The first electrodes 53 disposed adjacent to each other in the second direction D2 may be spaced apart from each other by the second linear openings 46. The first electrodes 53 disposed adjacent to each other in the third direction D3 may be spaced apart from each other by the first inter-cell dielectric layers 23. The first electrodes 53 disposed adjacent to each other in the first direction D1 may be spaced apart from each other by the third inter-cell dielectric layers 48. Forming the first electrodes 53 may include depositing a metal material, gap-filling a sacrificial material, and isolating the metal material in a vertical/horizontal direction. The sacrificial material may include oxide or polysilicon.

Each of the first electrodes 53 may include an inner space and a plurality of outer surfaces, and the inner space of the first electrode 53 may be provided to accommodate a second electrode and may include a plurality of inner surfaces. The outer surfaces of the first electrode 53 may include a vertical outer surface and a plurality of horizontal outer surfaces. The vertical outer surface of the first electrode 53 may vertically extend in the first direction D1, and the horizontal outer surfaces of the first electrode 53 may horizontally extend in the second direction D2 or the third direction D3. The inner space of the first electrode 53 may be a three-dimensional space. The first electrode 53 may, for example, have a cylindrical shape.

Among the outer surfaces of the first electrode 53, the vertical outer surface may be electrically coupled to the nano sheet HL and the second contact node 50.

The first electrode 53 may include metal, noble metal, metal nitride, conductive metal oxide, conductive noble metal oxide, metal carbide, metal silicide, or a combination thereof. For example, the first electrode 53 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, or a combination thereof.

FIG. 33A is a plan view illustrating the structure at the narrow sheet level to describe a method for partially recessing the third inter-cell dielectric layers 48. FIG. 33B is a cross-sectional view of the structure taken along line A-A′ illustrated in FIG. 33A.

Referring to FIGS. 33A and 33B, portions of the third inter-cell dielectric layers 48 may be horizontally recessed (refer to reference numeral “54”). Accordingly, outer walls of the first electrodes 53 may be partially exposed. The first electrodes 53 may each have, for example, a semi-cylindrical shape. Horizontal recess depths of the third inter-cell dielectric layers 48 may be depths that do not expose the second contact nodes 50. The semi-cylindrical shape of each of the first electrodes 53 may include cylindrical inner surfaces and semi-cylindrical outer surfaces.

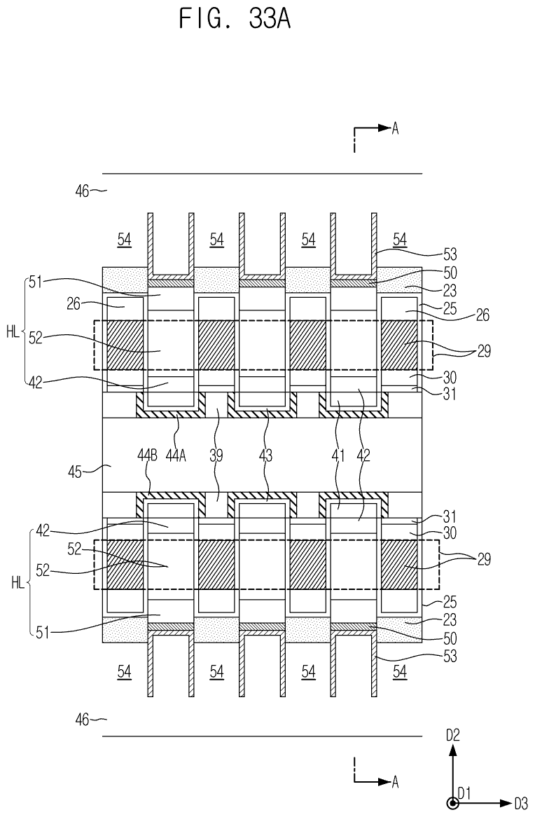

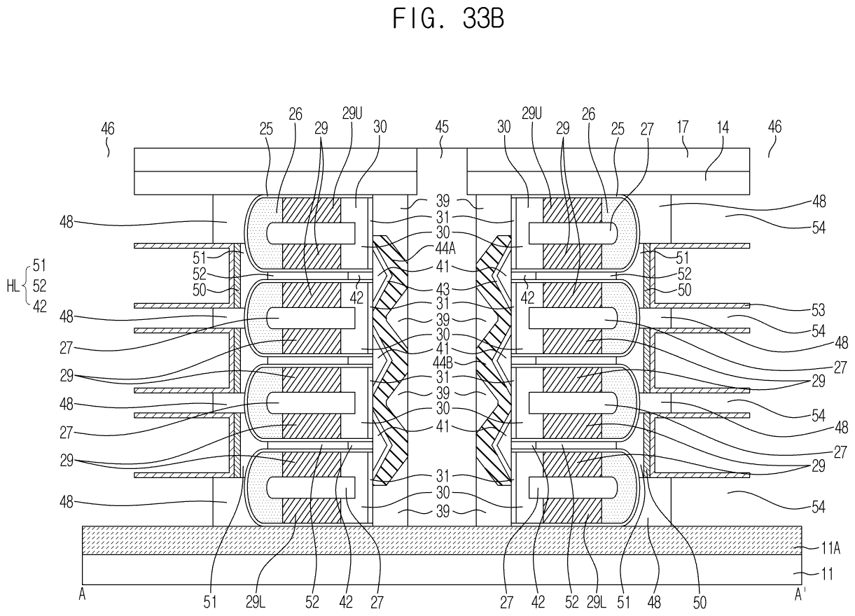

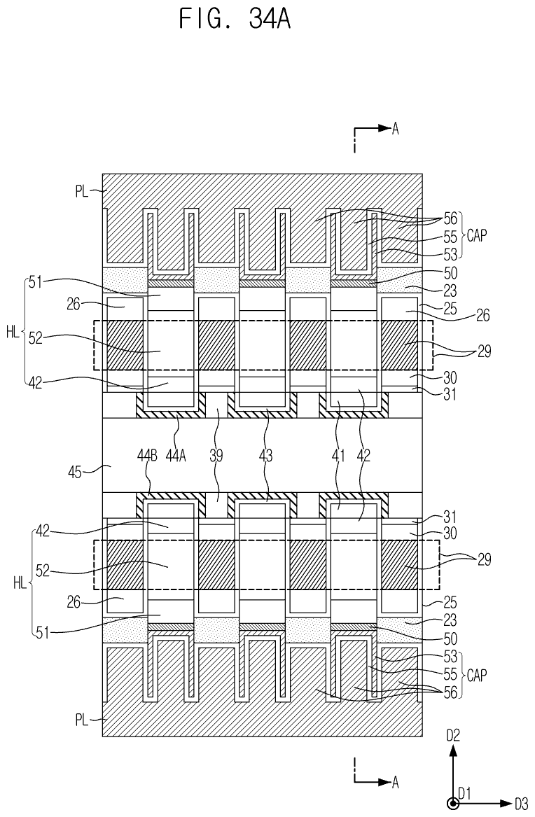

FIG. 34A is a plan view illustrating the structure at the narrow sheet level to describe a method for forming second electrodes 56 of the data storage elements CAP. FIG. 34B is a cross-sectional view of the structure taken along line A-A′ illustrated in FIG. 34A.

Referring to FIGS. 34A and 34B, a dielectric layer 55 and the second electrode 56 may be sequentially formed on each of the first electrodes 53. The first electrode 53, the dielectric layer 55 and the second electrode 56 may correspond to the data storage element CAP shown in FIG. 1B. The second electrodes 56 of the data storage elements CAP may be merged with one another and form a common plate PL.

The dielectric layer 55 and the second electrode 56 may be disposed on the cylindrical inner surfaces of the first electrode 53. A portion of the dielectric layer 55 and a portion of the second electrode 56 may extend to be disposed on the semi-cylindrical outer surfaces of the first electrode 53. The second electrode 56 may vertically extend in the first direction D1.

The dielectric layer 55 may be referred to as a “capacitor dielectric layer” or a “memory layer”. The dielectric layer 55 may include silicon oxide, silicon nitride, a high-k material, a ferroelectric material, an antiferroelectric material, a perovskite material, or a combination thereof. The dielectric layer 55 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). The dielectric layer 55 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, a HZHZ (HfO₂/ZrO₂/HfO₂/ZrO₂) stack, or an AHZAHZA (Al₂O₃/HfO₂/ZrO₂/Al₂O₃/HfO₂/ZrO₂/Al₂O₃) stack.

The second electrode 56 may include metal, noble metal, metal nitride, conductive metal oxide, conductive noble metal oxide, metal carbide, metal silicide, or a combination thereof. For example, the second electrode 56 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, or a combination thereof. The second electrode 56 may also include a combination of a metal-based material and a silicon-based material. For example, the second electrode 56 may have a structure in which titanium nitride, tungsten and polysilicon are sequentially stacked.

In some embodiments, a lower interface control layer may be further formed between the first electrode 53 and the dielectric layer 55 to alleviate leakage current. An upper interface control layer may be formed between the second electrode 56 and the dielectric layer 55. The lower and upper interface control layers may each include titanium oxide (TiO₂), tantalum oxide (Ta₂O₅), niobium (Nb), niobium oxide (Nb₂O₅), niobium nitride (NbN), niobium oxynitride (NbON), or a combination thereof. The lower and upper interface control layers may each include a single layer structure or a double layer structure. For example, the upper interface control layer may include a stack of titanium oxide (TiO₂) and niobium oxide (Nb₂O₅).

In some embodiments, the recessing of the first and third inter-cell dielectric layers 23 and 48 of FIG. 33B may be omitted. Subsequently, referring to FIG. 34B, the dielectric layer 55 and the second electrode 56 may be formed. Accordingly, the data storage element CAP having a concave shape may be formed.

According to the above-described embodiment, the first and second vertical conductive (bit) lines 44A and 44B may be formed by being self-aligned with the supporters 36 without high aspect ratio etch. Accordingly, a memory cell array including memory cells having the same dimension may be formed.

In addition, according to the above-described embodiment, costs may be reduced because the high aspect ratio etch is not performed to form the first and second vertical conductive lines 44A and 44B.

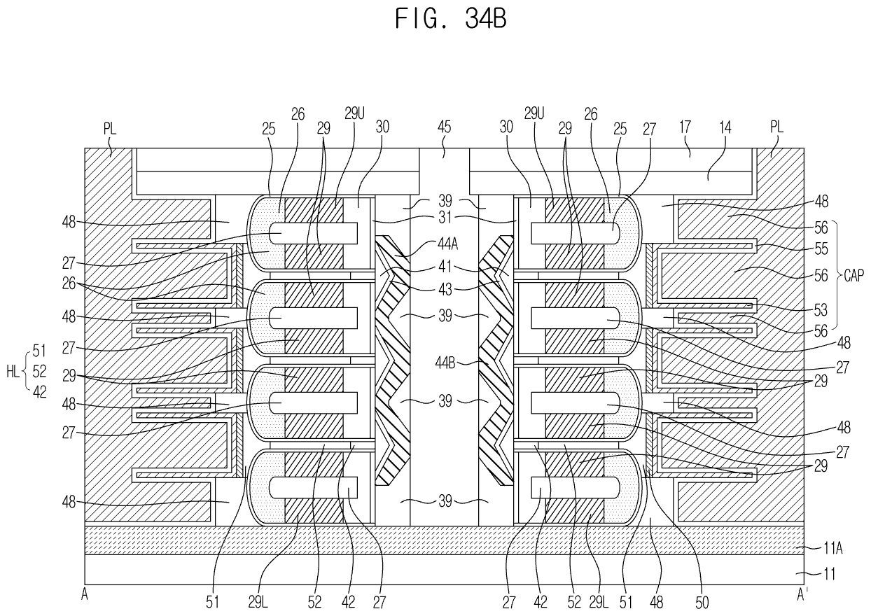

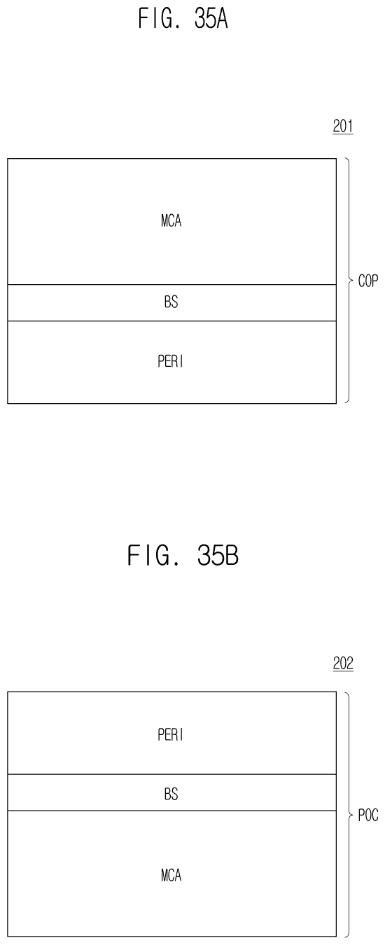

FIGS. 35A and 35B are schematic cross-sectional views of a semiconductor device 201 in accordance with embodiments of the present disclosure.

Referring to FIG. 35A, the semiconductor device 201 may include a memory cell array MCA, a peripheral circuit portion PERI, and a bonding interface BS. The memory cell array MCA may include any of the embodiments of the memory cell arrays including the memory cells MC previously described. The bonding interface BS may be disposed between the memory cell array MCA and the peripheral circuit portion PERI. In the semiconductor device 201, the memory cell array MCA may be disposed at a level higher than the peripheral circuit portion PERI. The semiconductor device 201 may be referred to as a “Cell array Over Peri (COP) structure” or a “Peri Under Cell array (PUC) structure”. The memory cell array MCA may include a substrate on which back grinding is performed and an array of memory cells. For example, as described with reference to FIGS. 34A and 34B, after the data storage element CAP is formed, the substrate 11 may be flipped over through a wafer flip, and then the substrate 11 may be partially back-ground.

Referring to FIG. 35B, a semiconductor device 202 may include a memory cell array MCA, a peripheral circuit portion PERI, and a bonding interface BS. The memory cell array MCA may include any of the embodiments of the memory cell arrays including the memory cells MC recited herein. The bonding interface BS may be disposed between the memory cell array MCA and the peripheral circuit portion PERI. In the semiconductor device 202, the memory cell array MCA may be disposed at a level lower than the peripheral circuit portion PERI. The semiconductor device 202 may be referred to as a “Peri Over Cell array (POC) structure” or a “Cell array Under Peri (CUP) structure”. Forming the peripheral circuit portion PERI may include forming a plurality of control circuits on a peripheral circuit substrate and forming multi-level interconnection on the control circuits.

In FIG. 35A and FIG. 35B, the bonding interface BS may include pad bonding, hybrid bonding, oxide-to-oxide bonding, metal-to-metal bonding, or a combination thereof. The hybrid bonding may refer to a combination of the pad bonding and the oxide-to-oxide bonding. The pad bonding may include forming a cell bonding pad for a memory cell array, forming a peripheral circuit bonding pad for a peripheral circuit portion, performing a wafer flip so that the cell bonding pad and the peripheral circuit bonding pad face each other, and performing wafer bonding.

The semiconductor device 201 illustrated in FIG. 35A may perform the wafer flip on the substrate on which the memory cell array is formed so that the cell bonding pad and the peripheral circuit bonding pad face each other, after the cell bonding pad and the peripheral circuit bonding pad are formed. The semiconductor device 202 illustrated in FIG. 35B may perform the wafer flip on the substrate on which the peripheral circuit portion is formed so that the cell bonding pad and the peripheral circuit bonding pad face each other, after the cell bonding pad and the peripheral circuit bonding pad are formed.

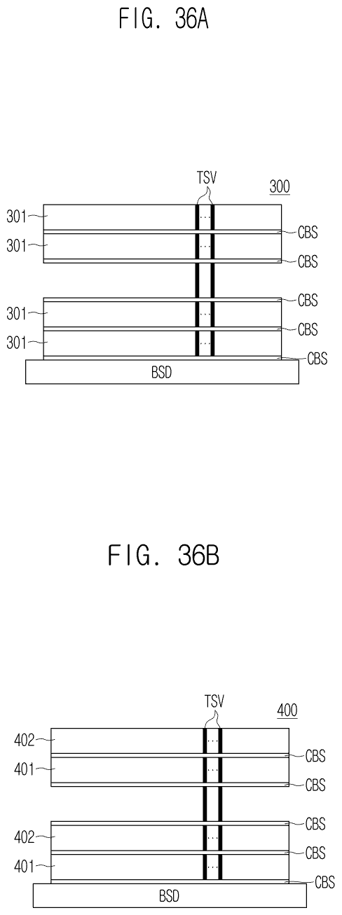

FIGS. 36A and 36B illustrate various views illustrating a stack assembly in accordance with an embodiment of the present disclosure.

Referring to FIG. 36A, a stack assembly 300 may include an assembly of semiconductor dies. For example, the stack assembly 300 may include a first semiconductor die BSD and a plurality of second semiconductor dies 301. The first semiconductor die BSD may include logic circuits. Each of the second semiconductor dies 301 may include memory cell arrays according to embodiments described above.

Each of the second semiconductor dies 301 may include structures in which a memory cell array and a peripheral circuit portion are stacked, for example, the semiconductor device 201 illustrated in FIG. 35A or the semiconductor device 202 illustrated in FIG. 35B. The logic circuits of the first semiconductor die BSD may be different from the peripheral circuit portions of the second semiconductor dies 301.

The second semiconductor dies 301 may be electrically coupled to each other through silicon vias TSV and bonding interfaces CBS. The first semiconductor die BSD and a lowermost second semiconductor die 301 may be electrically coupled to each other through the bonding interface CBS. The second semiconductor dies 301 may be referred to as “core dies”, “semiconductor chips”, or “memory chips”. The second semiconductor dies 301 may have chip levels or wafer levels.

The bonding interface CBS may include micro-bump, pad bonding, hybrid bonding, oxide-to-oxide bonding, metal-to-metal bonding, or a combination thereof.

In some embodiments, the second semiconductor dies 301 may be wafer-flipped and back-ground to form the bonding interfaces CBS.

Referring to FIG. 36B, a stack assembly 400 may include an assembly of semiconductor dies. For example, the stack assembly 400 may include a first semiconductor die BSD, a plurality of second semiconductor dies 401, and a plurality of third semiconductor dies 402. The plurality of second semiconductor dies 401 and the plurality of third semiconductor dies 402 may be disposed in an alternating arrangement. The first semiconductor die BSD may include logic circuits. Each of the second semiconductor dies 401 and each of the third semiconductor dies 402 may include memory cell arrays according to embodiments described above. The second semiconductor dies 401 and the third semiconductor dies 402 may have different structures.

Each of the second semiconductor dies 401 may include structures in which a memory cell array and a peripheral circuit portion are stacked, for example, the semiconductor device 201 illustrated in FIG. 35A. Each of the third semiconductor dies 402 may include structures in which a memory cell array and a peripheral circuit portion are stacked, for example, the semiconductor device 202 illustrated in FIG. 35B.

In some embodiments, each of the second semiconductor dies 401 may include the semiconductor device 202 illustrated in FIG. 35B, and each of the third semiconductor dies 402 may include the semiconductor device 201 illustrated in FIG. 35A.

The logic circuits of the first semiconductor die BSD may be different from the peripheral circuit portions of the second and third semiconductor dies 401 and 402. The second and third semiconductor dies 401 and 402 may be electrically coupled to each other through silicon vias TSV and bonding interfaces CBS. The first semiconductor die BSD and a lowermost second semiconductor die 401 may be electrically coupled to each other through the bonding interface CBS. The second and third semiconductor dies 401 and 402 may be referred to as “core dies”, “semiconductor chips”, or “memory chips”. The second and third semiconductor dies 401 and 402 may have chip levels or wafer levels.

The bonding interface CBS may include micro-bump, pad bonding, hybrid bonding, oxide-to-oxide bonding, metal-to-metal bonding, or a combination thereof.

In some embodiments, wafer-flip and back-grinding processes may be performed to form the bonding interface CBS. For example, the second semiconductor dies 401 and/or the third semiconductor dies 402 may be wafer-flipped and back-ground.

The stack assemblies 300 and 400 illustrated in FIGS. 36A and 36B may be high bandwidth memories.

According to various embodiments of the present disclosure, vertical conductive lines may be formed by being self-aligned with supporters without high aspect ratio etch.

According to various embodiments of the present disclosure, a memory cell array including memory cells having the same dimension may be formed.

According to various embodiments of the present disclosure, costs may be reduced because high aspect ratio etch is not performed to form vertical conductive lines.

While the embodiments of the present disclosure has been illustrated and described with respect to specific embodiments and drawings, the disclosed embodiments are not intended to be restrictive. Further, it is noted that the embodiments may be achieved in various ways through substitution, change, and modification, as those skilled in the art will recognize in light of the present disclosure, without departing from the spirit and/or scope of the present disclosure and the following claims. Furthermore, the embodiments may be combined to form additional embodiments.

What is claimed is:

1. A semiconductor device comprising:
a horizontal arrangement of switching elements including nano sheets and horizontal conductive lines surrounding the nano sheets;
pyramid-shaped first contact nodes formed on first edges of the nano sheets in the horizontal arrangement;
vertical conductive lines including pyramid portions surrounding the pyramid-shaped first contact nodes, each of the vertical conductive lines being coupled to a corresponding one of the nano sheets in the horizontal arrangement;
data storage elements each coupled to a corresponding one of second edges of the nano sheets in the horizontal arrangement; and
a supporter surrounding the vertical conductive lines.

2. The semiconductor device of claim 1, wherein:
the supporter includes a plurality of supporter recesses, and
the pyramid portions of the vertical conductive lines have a structure of filling the supporter recesses.

3. The semiconductor device of claim 1, wherein the supporter includes a low-k material, silicon carbon oxide, silicon nitride, an air gap, or a combination thereof.

4. The semiconductor device of claim 1, further comprising:
a first spacer disposed between the data storage elements and the horizontal conductive lines and surrounding the nano sheets;
a second spacer disposed between the vertical conductive lines and the horizontal conductive lines and surrounding the nano sheets; and
an etch stop spacer disposed between the vertical conductive lines and the horizontal conductive lines and surrounding the nano sheets.

5. The semiconductor device of claim 4, wherein the etch stop spacer includes a different material from the first and second spacers.

6. The semiconductor device of claim 1, wherein each of the first contact nodes includes a selective epitaxial growth layer.

7. The semiconductor device of claim 1, wherein each of the first contact nodes includes a doped silicon epitaxial layer.

8. The semiconductor device of claim 1, further comprising ohmic contact layers disposed between the vertical conductive lines and the first contact nodes and having a pyramid shape covering the first contact nodes.

9. The semiconductor device of claim 1, wherein each of the nano sheets includes:
first and second doped regions horizontally spaced apart from each other; and
a channel formed between the first doped region and the second doped region.

10. The semiconductor device of claim 1, wherein each of the nano sheets includes monocrystalline silicon, an oxide semiconductor material, a two-dimensional material, or a combination thereof.

11. The semiconductor device of claim 1, further comprising second contact nodes formed between the second edges of the nano sheets and the data storage elements.

12. The semiconductor device of claim 11, wherein each of the second contact nodes includes a selective epitaxial growth layer.

13. The semiconductor device of claim 1, wherein each of the nano sheets includes:
a narrow sheet coupled to a corresponding one of the vertical conductive lines; and
a wide sheet coupled to a corresponding one of the data storage elements and having a thickness that gradually increases from the narrow sheet toward the data storage elements.

14. A method for fabricating a semiconductor device, the method comprising:
forming a stopper layer over a substrate;
forming horizontal and vertical arrangements of narrow sheets over the stopper layer;
forming a supporter including supporter recesses that simultaneously expose edges of the narrow sheets in the vertical arrangement and expose the edges of the narrow sheets, respectively, in the horizontal arrangement;
forming horizontal and vertical arrangements of first contact nodes each coupled to a corresponding one of the edges of the narrow sheets in the horizontal and vertical arrangements; and
forming vertical conductive lines coupled in common to the first contact nodes in the vertical arrangement, each of the vertical conductive lines being coupled to a corresponding one of the first contact nodes in the horizontal arrangement and disposed in the supporter recesses.

15. The method of claim 14, wherein the forming of the supporter including the supporter recesses includes:
forming protruding edges of the narrow sheets in the horizontal and vertical arrangements;
forming sacrificial growth layers covering the protruding edges of the narrow sheets in the horizontal and vertical arrangements;
forming a supporter partially covering the sacrificial growth layers and exposing portions of the sacrificial growth layers;
forming the supporter recesses by removing the sacrificial growth layers; and
cutting the protruding edges of the narrow sheets in the horizontal and vertical arrangements.

16. The method of claim 15, wherein the forming of the sacrificial growth layers includes forming selective epitaxial growth of a silicon germanium layer.

17. The method of claim 15, wherein the forming of the protruding edges of the narrow sheets in the horizontal and vertical arrangements includes:
forming an etch stop spacer covering upper and lower surfaces of the narrow sheets in the horizontal and vertical arrangements;
forming first sacrificial spacers disposed between the narrow sheets in the horizontal arrangement;
forming second sacrificial spacers covering upper and lower surfaces of the edges of the narrow sheets in the horizontal and vertical arrangements on the etch stop spacer and the first sacrificial spacers;
removing the first sacrificial spacers using the second sacrificial spacers as a barrier;
removing the second sacrificial spacers to form the protruding edges of the narrow sheets in the horizontal and vertical arrangements.

18. The method of claim 17, wherein:
each of the first sacrificial spacers includes polysilicon, and
each of the second sacrificial spacers includes silicon nitride.

19. The method of claim 14, wherein the supporter includes a low-k material, silicon carbon oxide, silicon nitride, an air gap, or a combination thereof.

20. The method of claim 14, further comprising forming, before the forming of the vertical conductive lines, ohmic contact layers on the first contact nodes.

21. The method of claim 14, further comprising:
forming a first spacer surrounding first portions of the narrow sheets in the horizontal and vertical arrangements;
forming a horizontal conductive line surrounding second portions of the narrow sheets in the horizontal arrangement on the first spacer; and
forming a second spacer surrounding third portions of the narrow sheets in the horizontal arrangement on the horizontal conductive lines.

22. The method of claim 21, wherein the horizontal conductive lines include a gate all around structure surrounding the narrow sheets in the horizontal arrangement.

23. The method of claim 14, wherein the forming of the horizontal and vertical arrangements of the narrow sheets over the stopper layer includes:
forming horizontal and vertical arrangements of nano sheet target layers over the stopper layer; and
selectively recessing first portions of the nano sheet target layers to form the horizontal and vertical arrangements of the narrow sheets.

24. The method of claim 23, further comprising after the forming of the vertical conductive lines:
selectively recessing second portions of the nano sheet target layers to form horizontal and vertical arrangements of wide sheets;
selectively forming second contact nodes from side surfaces of the wide sheets; and
forming data storage elements each coupled to a corresponding one of the second contact nodes.
